(19) United States
(12) Patent Application Publication
(10) Pub. No.: US 2024/0215446 A1
(43) Pub. Date: Jun. 27, 2024

(54) LIGHT EMITTING DEVICE AND POLYCYCLIC COMPOUND FOR THE SAME

(71) Applicant: Samsung Display Co., Ltd., Yongin-si (KR)

(72) Inventors: Ryuhei FURUE, Yokohama (JP); Yoshiro SUGITA, Yokohama (JP)

(73) Assignee: Samsung Display Co., Ltd., Yongin-si (KR)

(21) Appl. No.: 18/469,628

(22) Filed: Sep. 19, 2023

(30) Foreign Application Priority Data
Dec. 13, 2022 (KR) 10-2022-0173950

(51) Int. Cl. H10K 85/60; C09K 11/06

(52) U.S. Cl. CPC H10K 85/658; C09K 11/06; H10K 85/6572; C07B 2200/05; H10K 2101/20

(57) ABSTRACT

Embodiments provide a light emitting device that includes a first electrode, a second electrode facing the first electrode, and at least one functional layer disposed between the first electrode and the second electrode, wherein the at least one functional layer includes a first compound represented by Formula 1, and at least one of a second compound represented by Formula HT and a third compound represented by Formula ET, and wherein Formula 1, Formula HT, and Formula ET are each explained in the specification.

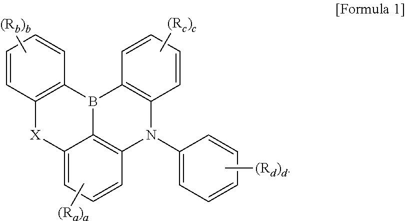

### CROSS-REFERENCE TO RELATED APPLICATION(S)

This application claims priority to and benefits of Korean Patent Application No. 10-2022-0173950 under 35 U.S.C. § 119, filed on Dec. 13, 2022 in the Korean Intellectual Property Office, the entire contents of which are incorporated herein by reference.

### BACKGROUND

### 1. Technical Field

The disclosure relates to a polycyclic compound and a light emitting device including the same.

### 2. Description of the Related Art

Active development continues for an organic electroluminescence display apparatus as an image display apparatus. The organic electroluminescence display apparatus includes a so-called self-luminescent light emitting device in which holes and electrons respectively injected from a first electrode and a second electrode recombine in an emission layer, so that a luminescent material in the emission layer emits light to achieve display.

In the application of a light emitting device to a display apparatus, there is a demand for a light emitting device having low driving voltage, high luminous efficiency, and a long service life, and continuous development is required on materials for a light emitting device that are capable of stably achieving such characteristics.

In order to implement an organic electroluminescence device with high luminous efficiency, technologies on phosphorescence emission which uses energy in a triplet state or on delayed fluorescence emission which uses the generating phenomenon of singlet excitons by the collision of triplet excitons (triplet-triplet annihilation, TTA) are being developed. Development is currently directed to a material for thermally activated delayed fluorescence (TADF) emission which uses delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting device in which luminous efficiency and a device service life are improved.

The disclosure also provides a polycyclic compound capable of improving luminous efficiency and a device service life of a light emitting device.

An embodiment provides a light emitting device which may include: a first electrode; a second electrode facing the first electrode; and at least one functional layer disposed between the first electrode and the second electrode, wherein the at least one functional layer may include a first compound represented by Formula 1, and at least one of a second compound represented by Formula HT and a third compound represented by Formula ET:

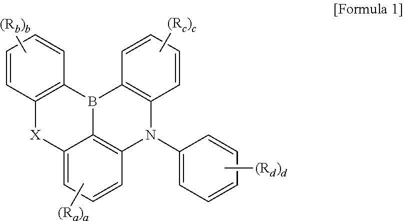

In Formula 1, X may be O, S, or N(Ar); Ar may be a substituted or unsubstituted aryl group having 6 to 60 ring-forming carbon atoms; a may be an integer from 1 to 3; b and c may each independently be an integer from 1 to 4; d may be an integer from 1 to 5; at least one of Rₐ to R_{d} may each independently be a group represented by Formula 2; and the remainder of Rₐ to R_{d} may each independently be a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or may be bonded to an adjacent group to form a ring.

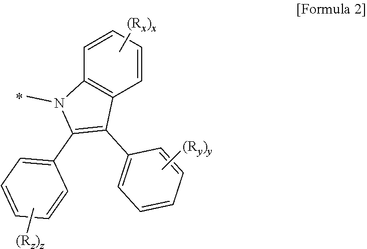

In Formula 2, Rₓ to R_{z} may each independently be a hydrogen atom, a deuterium atom, or a substituted or unsubstituted alkyl group having 1 to 60 carbon atoms; x may be an integer from 0 to 4; y and z may each independently be an integer from 0 to 5, and at least one hydrogen atom in Formula 1 and Formula 2 may be optionally substituted with a deuterium atom.

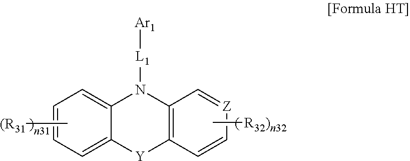

In Formula HT, L₁ maybe a direct linkage, a substituted or unsubstituted arylene group having 6 to 30 ring-forming carbon atoms, or a substituted or unsubstituted heteroarylene group having 2 to 30 ring-forming carbon atoms; Ar₁ may be a substituted or unsubstituted aryl group having 6 to 30 ring-forming carbon atoms or a substituted or unsubstituted heteroaryl group having 2 to 30 ring-forming carbon atoms; Y may be a direct linkage, C(R_{y1})(R_{y2}), or Si(R_{y3})(R_{y4}); Z may be C(R_{z}) or N; R_{y1} to R_{y4}, R₃₁, R₃₂, and R_{z} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; n31 may be an integer from 0 to 4; and n32 may be an integer from 0 to 3.

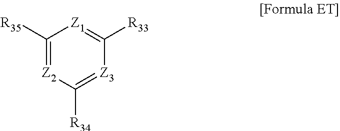

In Formula ET, Z₁ to Z₃ may each independently be N or C(R₃₆); at least one of Z₁ to Z₃ may each be N; and R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring.

In an embodiment, the at least one functional layer may further include a fourth compound represented by Formula PS:

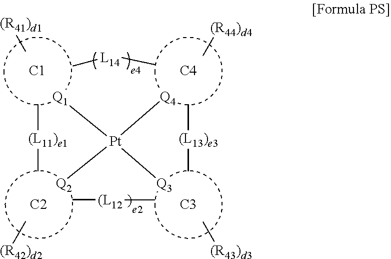

In Formula PS, Q₁ to Q₄ may each independently be C or N; C1 to C4 may each independently be a substituted or unsubstituted hydrocarbon ring having 5 to 30 ring-forming carbon atoms or a substituted or unsubstituted heterocycle having 2 to 30 ring-forming carbon atoms; L₁₁ to L₁₄ may each independently be a direct linkage,

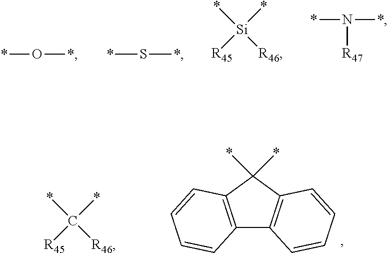

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, wherein in L₁₁ to L₁₄,

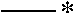 [SMILES: *C]

represents a bond to one of C1 to C4; e1 to e4 may each independently be 0 or 1; R₄₁ to R₄₉ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; and d1 to d4 may each independently be an integer from 0 to 4.

In an embodiment, the first compound may be represented by any one of Formula 1-1a to Formula 1-1f:

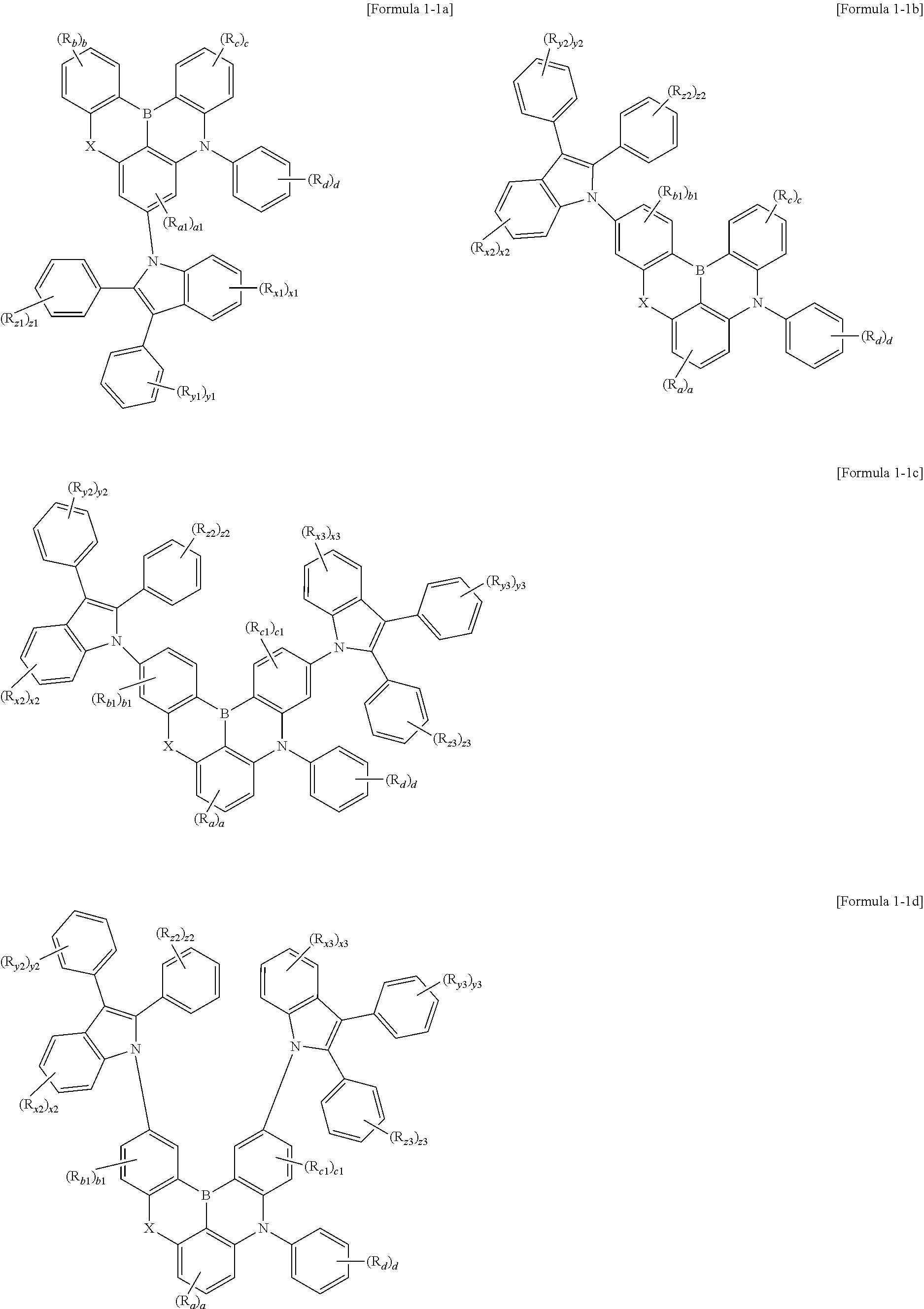

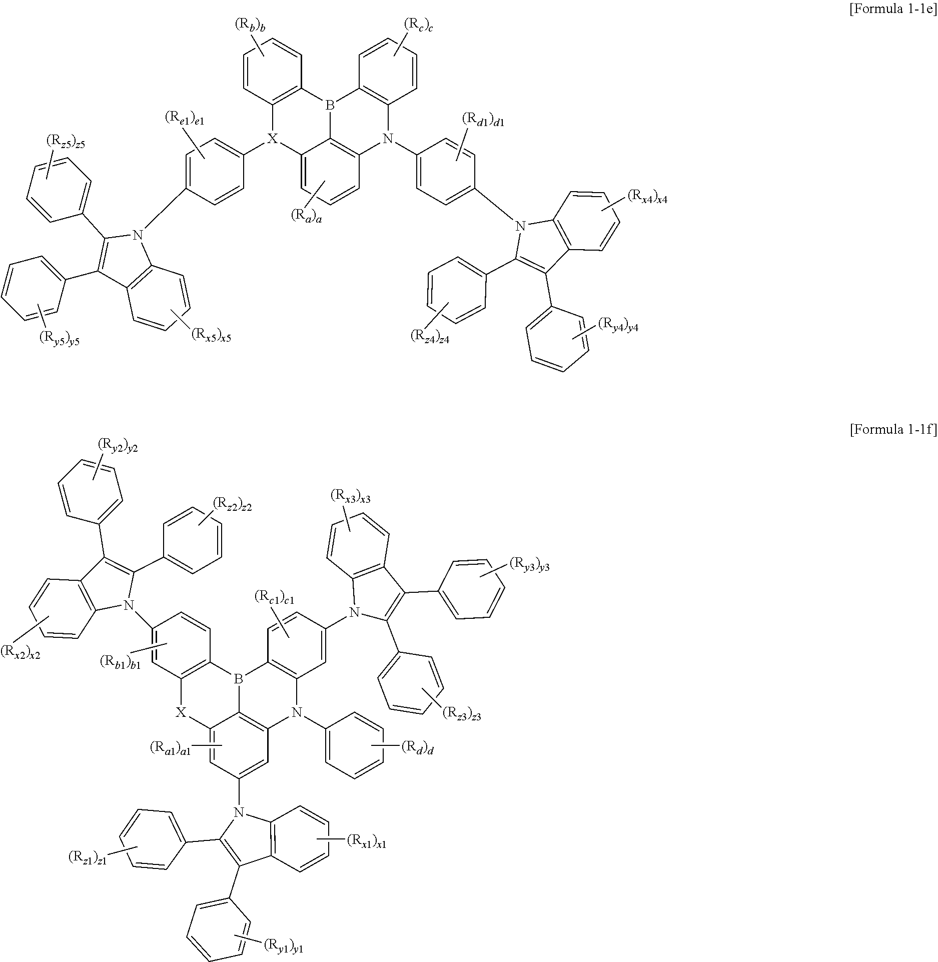

In Formula 1-1a to Formula 1-1f, Rₐ to R_{d}, Rₐ₁, R_{b1}, R_{c1}, R_{d1}, and Rₑ₁ may each independently be a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, a substituted or unsubstituted aryl group having 6 to 60 ring-forming carbon atoms, or may be bonded to an adjacent group to form a ring; a1 may be 1 or 2; b1 and c1 may each independently be an integer from 1 to 3; d1 and e1 may each independently be an integer from 1 to 4; Rₓ₁ to Rₓ₅, R_{y1} to R_{y5}, and R_{z1} to R_{z5} may each independently be a hydrogen atom, a deuterium atom, or a substituted or unsubstituted alkyl group having 1 to 60 carbon atoms; x1 to x5 may each independently be an integer from 0 to 4; y1 to y5 and z1 to z5 may each independently be an integer from 0 to 5; X and a to d are the same as defined in Formula 1; and at least one hydrogen atom in Formula 1-1a to Formula 1-1f may be optionally substituted with a deuterium atom.

In an embodiment, the first compound may be represented by Formula 1a or Formula 1b:

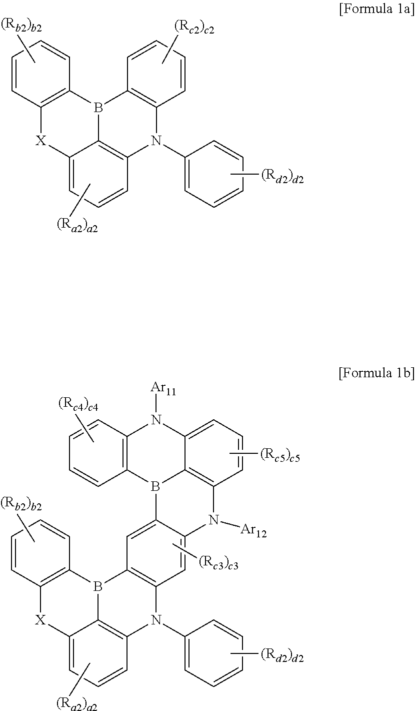

In Formula 1a and Formula 1b, a2 may be an integer from 1 to 3; b2 and c2 may each independently be an integer from 1 to 4; d2 may be an integer from 1 to 5; R_{c3} to R_{c5} may each independently be a hydrogen atom, or a group represented by Formula 2; c3 may be 1 or 2; c4 may be an integer from 1 to 4; c5 may be an integer from 1 to 3; Ar₁₁ and Ar₁₂ may each independently be a substituted or unsubstituted aryl group having 6 to 60 ring-forming carbon atoms; in Formula 1a, at least one of Rₐ₂, R_{b2}, R_{c2}, and R_{d2} may each independently be a group represented by Formula 2, and the remainder of Rₐ₂, R_{b2}, R_{c2}, and R_{d2} may each independently be a hydrogen atom, a deuterium atom, a substituted or unsubstituted alkyl group having 1 to 60 carbon atoms, or a substituted or unsubstituted aryl group having 6 to 60 ring-forming carbon atoms; in Formula 1b, at least one of Rₐ₂, R_{b2}, and R_{d2} may each independently be a group represented by Formula 2, and the remainder of Rₐ₂, R_{b2}, and R_{d2} may each independently be a hydrogen atom, a deuterium atom, a substituted or unsubstituted alkyl group having 1 to 60 carbon atoms, or a substituted or unsubstituted aryl group having 6 to 60 ring-forming carbon atoms; X is the same as defined in Formula 1; and at least one hydrogen atom in Formula 1a, Formula 1b, and Formula 2 may be optionally substituted with a deuterium atom.

In an embodiment, at least one of Rₐ to R_{d} may each independently be a group represented by Formula 2; and the remainder of Rₐ to R_{d} may each independently be a hydrogen atom, a deuterium atom, a substituted or unsubstituted oxy group, a substituted or unsubstituted thio group, a substituted or unsubstituted boron group, a substituted or unsubstituted amine group, an unsubstituted methyl group, an unsubstituted t-butyl group, or an unsubstituted phenyl group, or may be bonded to an adjacent group to form a ring.

In an embodiment, Rₓ to R_{z} may each independently be a hydrogen atom, a deuterium atom, an unsubstituted methyl group, or an unsubstituted t-butyl group.

In an embodiment, the at least one functional layer may include at least one compound selected from Compound Group 1-1 and Compound Group 1-2, which are explained below.

In an embodiment, the at least one functional layer may include an emission layer, a hole transport region disposed between the first electrode and the emission layer, and an electron transport region disposed between the emission layer and the second electrode; and the emission layer may include the first compound, and at least one of the second compound and the third compound.

In an embodiment, the emission layer may emit delayed fluorescence.

In an embodiment, the emission layer may emit blue light.

In an embodiment, the at least one functional layer may include the first compound, the second compound, and the third compound.

In an embodiment, the at least one functional layer may include the first compound, the second compound, the third compound, and the fourth compound.

An embodiment provides a light emitting device which may include: a first electrode; a second electrode facing the first electrode; and an emission layer disposed between the first electrode and the second electrode, wherein the emission layer includes a polycyclic compound represented by Formula 1:

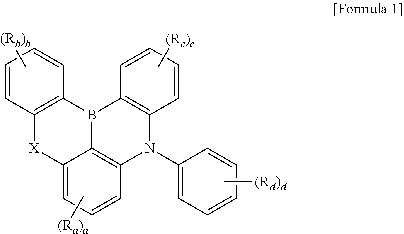

In Formula 1, X may be O, S, or N(Ar); Ar may be a substituted or unsubstituted aryl group having 6 to 60 ring-forming carbon atoms; a may be an integer from 1 to 3; b and c may each independently be an integer from 1 to 4; d may be an integer from 1 to 5; at least one of Rₐ to R_{d} may each independently be a group represented by Formula 3; and the remainder of Rₐ to R_{d} may each independently be a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or may be bonded to an adjacent group to form a ring.

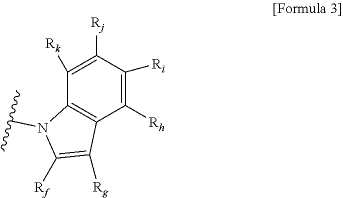

In Formula 3, two of R_{f} to Rₖ may each independently be a substituted or unsubstituted aryl group having 6 to 60 carbon atoms; the remainder of R_{f} to Rₖ may each independently be a hydrogen atom, a deuterium atom, or a substituted or unsubstituted alkyl group having 1 to 60 carbon atoms; and at least one hydrogen atom in Formula 1 and Formula 3 may be optionally substituted with a deuterium atom.

In an embodiment, the polycyclic compound may be represented by Formula 1-2a or Formula 1-2b:

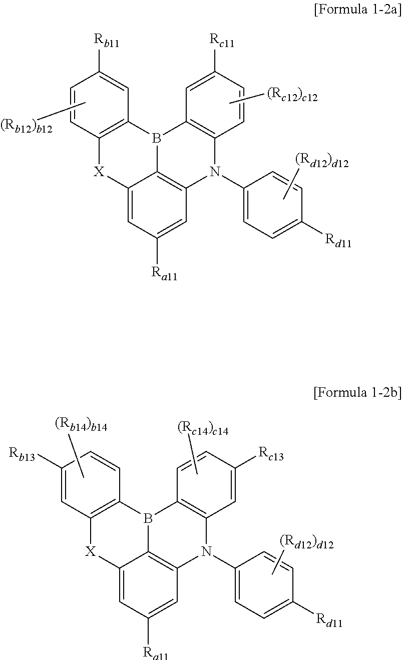

In Formula 1-2a and Formula 1-2b, R_{b12}, R_{b14}, R_{c12}, R_{c14}, and R_{d12} may each independently be a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or may be bonded to an adjacent group to form a ring; b12, b14, c12, and c14 may each independently be an integer from 1 to 3; d12 may be an integer from 1 to 4; X is the same as defined in Formula 1; in Formula 1-2a, at least one of Rₐ₁₁, R_{b11}, R_{c11}, or R_{d11} may each independently be a group represented by Formula 3, and the remainder of Rₐ₁₁, R_{b11}, R_{c11}, and R_{d11} may each independently be a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or may be bonded to an adjacent group to form a ring; in Formula 1-2b, at least one of Rₐ₁₁, R_{b13}, R_{c13}, or R_{d11} may each independently be a group represented by Formula 3, and the remainder of Rₐ₁₁, R_{b13}, R_{c13}, or R_{d11} may each independently be a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or may be bonded to an adjacent group to form a ring; and in Formula 3, R_{f} and R_{g} may each independently be a phenyl group unsubstituted or substituted with a deuterium atom, and Rₕ to Rₖ may each independently be a hydrogen atom, a deuterium atom, an unsubstituted methyl group, or an unsubstituted t-butyl group.

An embodiment provides a polycyclic compound which may be represented by Formula 1, which is explained herein.

In an embodiment, the polycyclic compound represented by Formula 1 may be represented by any one of Formula 1-1a to Formula 1-1f, which are explained herein.

In an embodiment, the polycyclic compound represented by Formula 1 may be represented by Formula 1a or Formula 1b, which are explained herein.

In an embodiment, in the polycyclic compound represented by Formula 1, at least one of Rₐ to R_{d} may each independently be a group represented by Formula 2, which is explained herein; and the remainder of Rₐ to R_{d} may each independently be a hydrogen atom, a deuterium atom, a substituted or unsubstituted oxy group, a substituted or unsubstituted thio group, a substituted or unsubstituted boron group, a substituted or unsubstituted amine group, an unsubstituted methyl group, an unsubstituted t-butyl group, or an unsubstituted phenyl group, or may be bonded to an adjacent group to form a ring.

In an embodiment, in the polycyclic compound represented by Formula 1, Rₓ to R_{z} may each independently be a hydrogen atom, a deuterium atom, an unsubstituted methyl group, or an unsubstituted t-butyl group.

In an embodiment, the polycyclic compound represented by Formula 1 may be selected from Compound Group 1-1 and Compound Group 1-2, which are explained below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display apparatus according to an embodiment;

FIG. 2 is a schematic cross-sectional view of a display apparatus according to an embodiment;

FIG. 3 is a schematic cross-sectional view of a light emitting device according to an embodiment;

FIG. 4 is a schematic cross-sectional view of a light emitting device according to an embodiment;

FIG. 5 is a schematic cross-sectional view of a light emitting device according to an embodiment;

FIG. 6 is a schematic cross-sectional view of a light emitting device according to an embodiment;

FIG. 7 is a schematic cross-sectional view of a display apparatus according to an embodiment;

FIG. 8 is a schematic cross-sectional view of a display apparatus according to an embodiment;

FIG. 9 is a schematic cross-sectional view of a display apparatus according to an embodiment;

FIG. 10 is a schematic cross-sectional view of a display apparatus according to an embodiment; and

FIG. 11 is a schematic perspective view of an electronic apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, +10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is unsubstituted or substituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the phrase “bonded to an adjacent group to form a ring,” may be interpreted as a group that is bonded to an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, an alkenyl group may be a hydrocarbon group including at least one carbon-carbon double bond in the middle or at a terminus of an alkyl group having 2 or more carbon atoms. An alkenyl group may be linear or branched. The number of carbon atoms in an alkenyl group is not specifically limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group including at least one carbon-carbon triple bond in the middle or at a terminus of an alkyl group having 2 or more carbon atoms. An alkynyl group may be linear or branched. Although the number of carbon atoms in an alkynyl group is not specifically limited, it may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the compounds shown below. However, embodiments are not limited thereto.

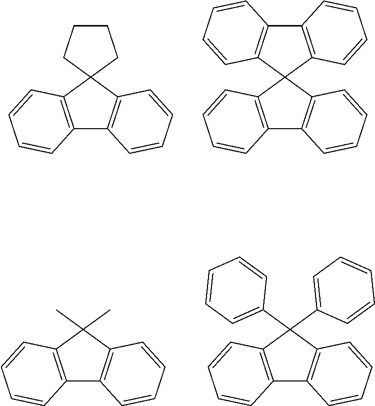

In the specification, a heterocyclic group may be any functional group or substituent derived from a ring containing at least one of B, O, N, P, S, Si, or Se as a heteroatom. A heterocyclic group may be an aliphatic heterocyclic group or an aromatic heterocyclic group. An aromatic heterocyclic group may be a heteroaryl group. An aliphatic heterocycle and an aromatic heterocycle may each independently be monocyclic or polycyclic. If a heterocyclic group includes two or more heteroatoms, the two or more heteroatoms may be the same as or different from each other.

In the specification, an aliphatic heterocyclic group may include at least one of B, O, N, P, Si, or S as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, or S as a heteroatom. If a heteroaryl group contains two or more heteroatoms, the two or more heteroatoms may be the same as or different from each other. A heteroaryl group may be monocyclic or polycyclic. The number of ring-forming carbon atoms in a heteroaryl group may be 2 to 60, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in an amino group is not specifically limited, but may be 1 to 30. An amino group may be an alkyl amino group, an aryl amino group, or a heteroaryl amino group. Examples of an amino group may include a methylamino group, a dimethylamino group, a phenylamino group, a diphenylamino group, a naphthylamino group, a 9-methyl-anthracenylamino group, a triphenylamino group, etc., but embodiments are not limited thereto.

In the specification, the number of carbon atoms in a carbonyl group is not specifically limited, but may be 1 to 40, 1 to 30, or 1 to 20. For example, a carbonyl group may have one of the following structures, but embodiments are not limited thereto.

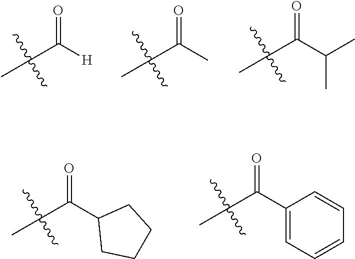

In the specification, the number of carbon atoms in a sulfinyl group or in a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or to an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or to an aryl group as defined above. An oxy group may be an alkoxy group or an aryl oxy group. An alkoxy group may be linear, branched, or cyclic. The number of carbon atoms in an alkoxy group is not specifically limited, but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or to an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not specifically limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of the alkyl group as described above.

In the specification, an aryl group within an aryloxy group, an arylthio group, an arylsulfoxy group, an arylamino group, an arylboron group, an arylsilyl group, or an arylamine group may be the same as an example of the aryl group as described above.

In the specification, a direct linkage may be a single bond.

In the specification, the symbols

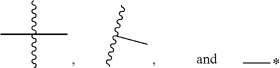

each represent a bond to a neighboring atom in a corresponding formula.

Hereinafter, embodiments will be described with reference to the accompanying drawings.

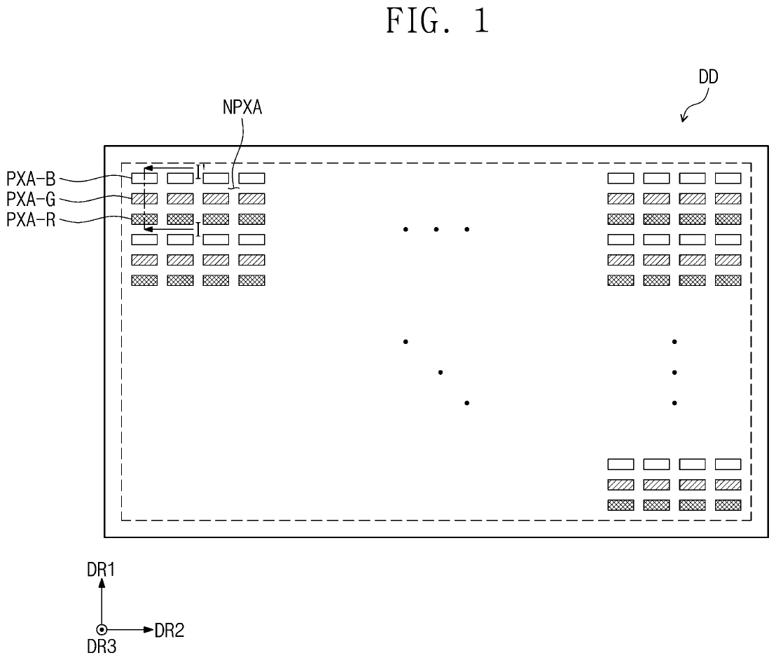

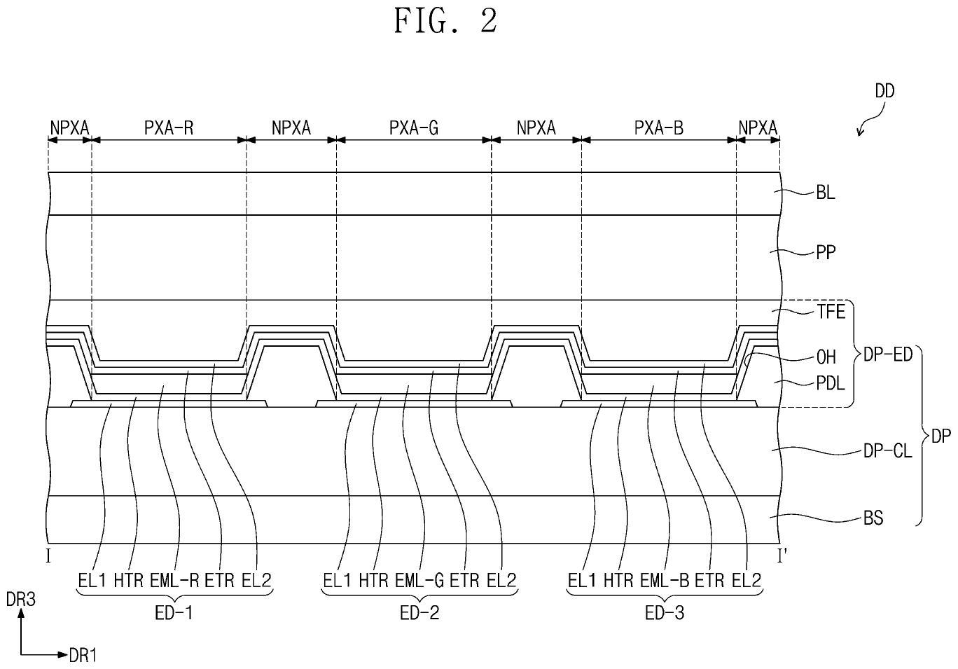

FIG. 1 is a schematic plan view of a display apparatus DD according to an embodiment. FIG. 2 is a schematic cross-sectional view of a display apparatus DD according to an embodiment. FIG. 2 is a schematic cross-sectional view illustrating a part corresponding to line I-I′ in FIG. 1.

The display apparatus DD may include a display panel DP and an optical layer PP disposed on the display panel DP. The display panel DP includes light emitting devices ED-1, ED-2, and ED-3. The display apparatus DD may include multiples of each of the light emitting devices ED-1, ED-2, and ED-3. The optical layer PP may be disposed on the display panel DP and may control light that is reflected at the display panel DP from an external light. The optical layer PP may include, for example, a polarization layer or a color filter layer. Although not shown in the drawings, in an embodiment, the optical layer PP may be omitted from the display apparatus DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display apparatus DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light emitting devices ED-1, ED-2, and ED-3 disposed between portions of the pixel defining film PDL, and an encapsulation layer TFE disposed on the light emitting devices ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). Each of the transistors (not shown) may include a control electrode, an input electrode, and an output electrode. For example, the circuit layer DP-CL may include a switching transistor and a driving transistor for driving the light emitting devices ED-1, ED-2, and ED-3 of the display device layer DP-ED.

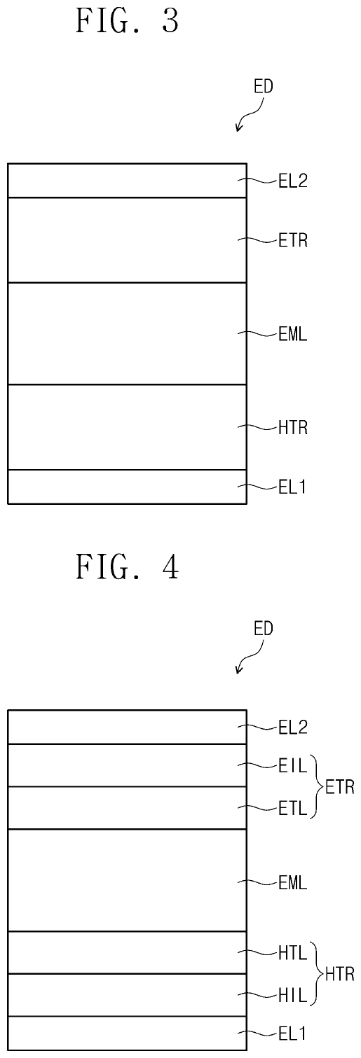

The light emitting devices ED-1, ED-2, and ED-3 may each have a structure of a light emitting device ED of an embodiment according to any of FIGS. 3 to 6, which will be described later. The light emitting devices ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting devices ED-1, ED-2, and ED-3 are disposed in openings OH defined in the pixel defining film PDL, and the hole transport region HTR, the electron transport region ETR, and the second electrode EL2 are each provided as a common layer for the light emitting devices ED-1, ED-2, and ED-3. However, embodiments are not limited thereto. Although not shown in FIG. 2, in an embodiment, the hole transport region HTR and the electron transport region ETR may each be provided by being patterned inside the openings OH defined in the pixel defining film PDL. For example, in an embodiment, the hole transport region HTR, the emission layers EML-R, EML-G, and EML-B, and the electron transport region ETR of the light emitting devices ED-1, ED-2, and ED-3 may each be provided by being patterned by an inkjet printing method.

The encapsulation layer TFE may cover the light emitting devices ED-1, ED-2, and ED-3. The encapsulation layer TFE may seal the display device layer DP-ED. The encapsulation layer TFE may be a thin film encapsulation layer. The encapsulation layer TFE may be a single layer or a stack of multiple layers. The encapsulation layer TFE may include at least one insulation layer. In an embodiment, the encapsulation layer TFE may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display apparatus DD may include non-light emitting regions NPXA and light emitting regions PXA-R, PXA-G, and PXA-B. The light emitting regions PXA-R, PXA-G, and PXA-B may each be a region which emits light respectively generated by the light emitting devices ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting regions NPXA may be regions between adjacent light emitting areas PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting devices ED-1, ED-2, and ED-3. The emission layers EML-R, EML-G, and EML-B of the light emitting devices ED-1, ED-2, and ED-3 may be disposed in the openings OH defined in the pixel defining film PDL and separated from each other.

The light emitting regions PXA-R, PXA-G, and PXA-B may be arranged into groups according to the color of light generated from the light emitting devices ED-1, ED-2, and ED-3. In the display apparatus DD according to an embodiment illustrated in FIGS. 1 and 2, three light emitting regions PXA-R, PXA-G, and PXA-B, which respectively emit red light, green light, and blue light, are illustrated. For example, the display apparatus DD may include a red light emitting region PXA-R, a green light emitting region PXA-G, and a blue light emitting region PXA-B, which are separated from each other.

In the display apparatus DD according to an embodiment, the light emitting devices ED-1, ED-2 and ED-3 may emit light having wavelengths that are different from each other. For example, in an embodiment, the display apparatus DD may include a first light emitting device ED-1 that emits red light, a second light emitting device ED-2 that emits green light, and a third light emitting device ED-3 that emits blue light. For example, the red light emitting region PXA-R, the green light emitting region PXA-G, and the blue light emitting region PXA-B of the display apparatus DD may respectively correspond to the first light emitting device ED-1, the second light emitting device ED-2, and the third light emitting device ED-3.

However, embodiments are not limited thereto, and the first to third light emitting devices ED-1, ED-2, and ED-3 may emit light in a same wavelength range or at least one light emitting device may emit light in a wavelength range that is different from the others. For example, the first to third light emitting devices ED-1, ED-2, and ED-3 may each emit blue light.

The light emitting regions PXA-R, PXA-G, and PXA-B in the display apparatus DD according to an embodiment may be arranged in a stripe configuration. Referring to FIG. 1, the red light emitting regions PXA-R, the green light emitting regions PXA-G, and the blue light emitting regions PXA-B may be respectively arranged in the second direction DR2. In another embodiment, the red light emitting region PXA-R, the green light emitting region PXA-G, and the blue light emitting region PXA-B may be alternately arranged in this order in the first direction DR1.

FIGS. 1 and 2 illustrate that the light emitting regions PXA-R, PXA-G, and PXA-B each have a similar area, but embodiments are not limited thereto. In an embodiment, the light emitting regions PXA-R, PXA-G, and PXA-B may have areas that are different from each other, according to a wavelength range of emitted light. For example, the areas of the light emitting regions PXA-R, PXA-G, and PXA-B may be areas in a plan view that are defined by the first direction DR1 and the second direction DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to display quality properties that are required for the display apparatus DD. For example, the light emitting regions PXA-R, PXA-G, and PXA-B may be provided in a pentile configuration (such as a PENTILE™ configuration) or in a diamond configuration (such as a Diamond Pixel™ configuration).

The areas of the light emitting regions PXA-R, PXA-G, and PXA-B may be different in size from each other. For example, in an embodiment, an area of the green light emitting region PXA-G may be smaller than an area of the blue light emitting region PXA-B, but embodiments are not limited thereto.

In the display apparatus DD according to an embodiment illustrated in FIG. 2, at least one of the first to third light emitting devices ED-1, ED-2, and ED-3 may include a polycyclic compound according to an embodiment, which will be described below.

Hereinafter, FIGS. 3 to 6 are each a schematic cross-sectional view of a light emitting device according to an embodiment. The light emitting devices ED according to embodiments may each include a first electrode EL1, a second electrode EL2 facing the first electrode EL1, and at least one functional layer disposed between the first electrode EL1 and the second electrode EL2. The light emitting device ED according to an embodiment may include a polycyclic compound according to an embodiment, which will be described below, in at least one functional layer. In the specification, the polycyclic compound according to an embodiment may be referred to as a first compound.

The light emitting devices ED may each include, as the at least one functional layer, a hole transport region HTR, an emission layer EML, and an electron transport region ETR, which may be stacked in that order from the first electrode EL1. Referring to FIG. 3, the light emitting device ED according to an embodiment may include a first electrode EL1, a hole transport region HTR, an emission layer EML, an electron transport region ETR, and a second electrode EL2, which are stacked in that order. In an embodiment, the light emitting device ED may include the polycyclic compound according to an embodiment, which will be described below, in the emission layer EML.

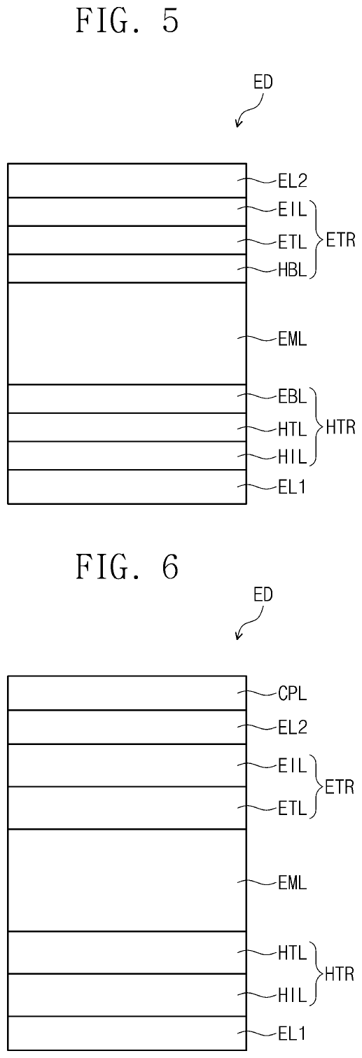

In comparison to FIG. 3, FIG. 4 illustrates a schematic cross-sectional view of a light emitting device ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 illustrates a schematic cross-sectional view of a light emitting device ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 illustrates a schematic cross-sectional view of a light emitting device ED according to an embodiment that includes a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO. However, embodiments are not limited thereto. The first electrode EL1 may include the above-described metal materials, combinations of at least two metal materials selected from the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), or an electron blocking layer EBL. A thickness of the hole transport region HTR may be, for example, in a range of about 50 Å to about 15,000 Å.

The hole transport region HTR may be a layer consisting of a single material, a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting device ED according to an embodiment, the hole transport region HTR may include a compound represented by Formula H-1:

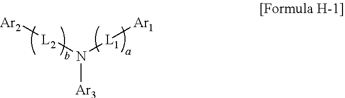

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In yet another embodiment, the compound represented by Formula H-1 may be a carbazole-based compound in which at least one of Ar₁ or Ar₂ includes a substituted or unsubstituted carbazole group, or may be a fluorene-based compound in which at least one of Ar₁ or Ar₂ includes a substituted or unsubstituted fluorene group.

The compound represented by Formula H-1 may be any compound selected from Compound Group H-1. However, the compounds listed in Compound Group H-1 are only examples, and the compounds represented by Formula H-1 are not limited to Compound Group H-1:

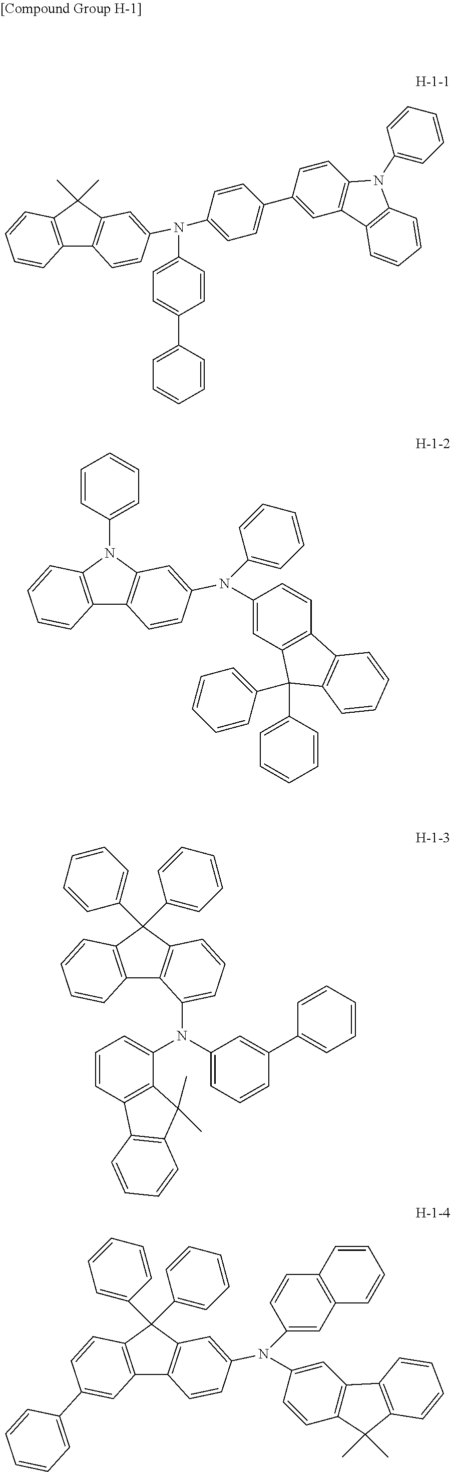 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

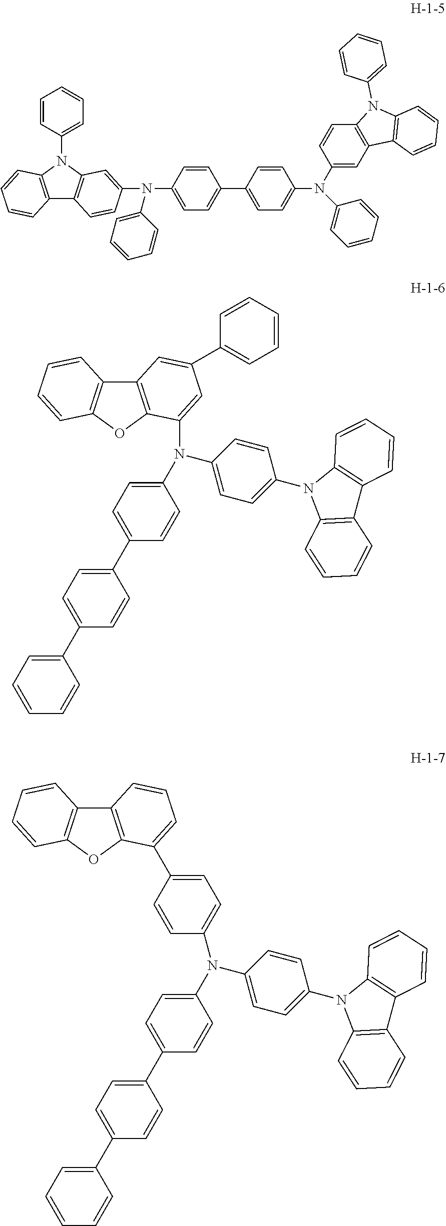 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

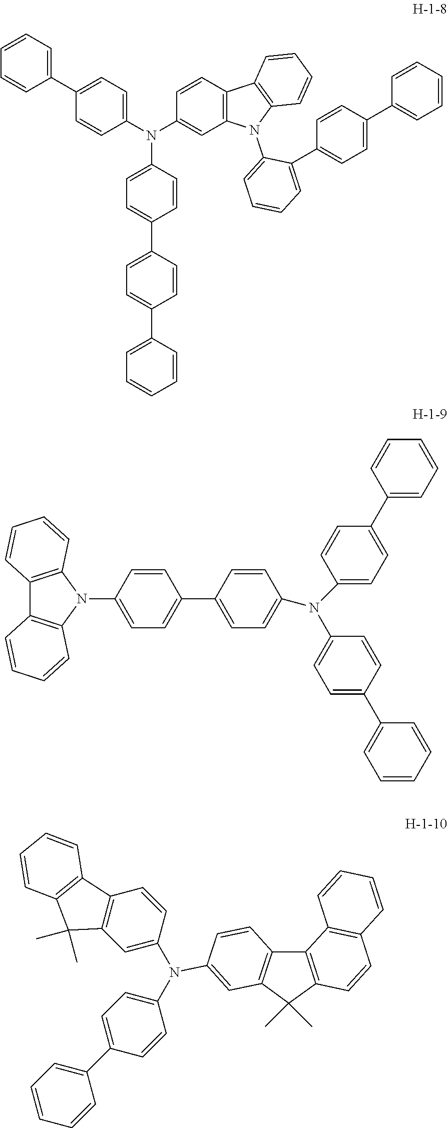 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

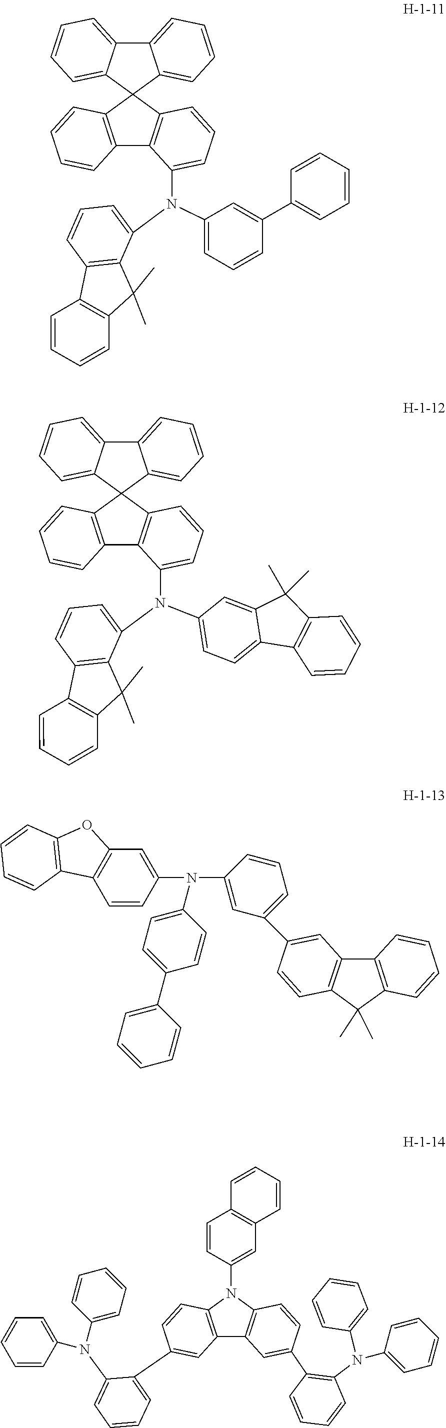 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1]

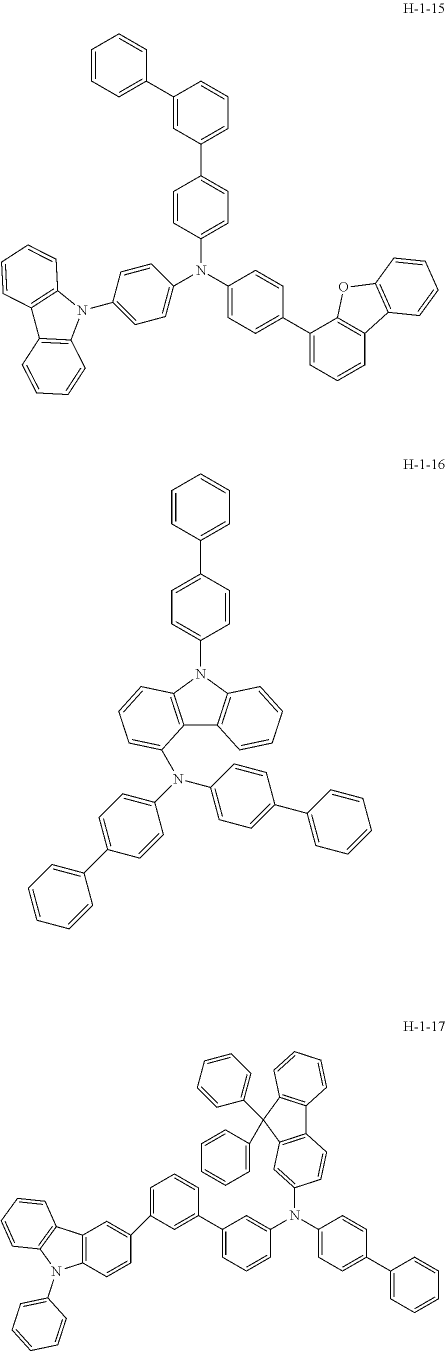 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

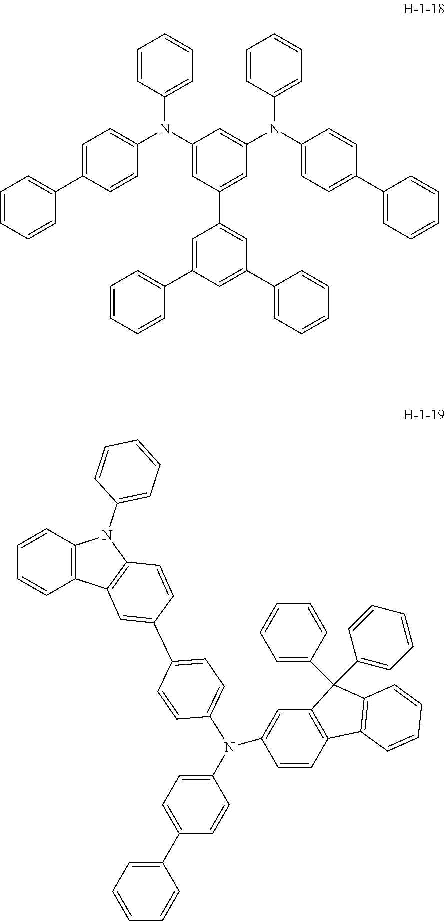 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N^{1′}-([1,1′-biphenyl]-4,4′-diyl)bis(N-phenyl-N4,N4-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrene sulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 250 Ato about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto.

For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) or an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material included in the buffer layer (not shown). The electron blocking layer EBL may block electron injection from an electron transport region ETR to a hole transport region HTR.

The emission layer EML may be provided on the hole transport region HTR. The emission layer EML may have a thickness in a range of about 100 Å to about 1,000 Å. For example, the emission layer EML may have a thickness in a range of about 100 Ato about 300 Å. The emission layer EML may be a layer consisting of a single material, a layer including different materials, or a structure including multiple layers including different materials.

In the light emitting device ED according to an embodiment, the emission layer EML may include a polycyclic compound according to an embodiment. In an embodiment, the emission layer EML may include the polycyclic compound as a dopant. The polycyclic compound may be a dopant material of the emission layer EML.

The polycyclic compound may include a polycyclic core in which multiple aromatic rings are fused via a boron atom, a nitrogen atom, and a heteroatom, and a phenyl group is bonded to the nitrogen atom.

The polycyclic compound may include a pentacyclic structure in which first to third aromatic rings are fused via a boron atom, a nitrogen atom, and a heteroatom. The heteroatom may be, for example, a nitrogen atom, a sulfur atom, or an oxygen atom. The first to third aromatic rings may each independently be a substituted or unsubstituted benzene ring.

In the polycyclic compound, substituents that are bonded to the pentacyclic structure may be bonded to an adjacent substituent to form a ring. A ring that is formed by the bonding of adjacent substituents may include three heteroatoms, and the three heteroatoms may each independently be a boron atom, a nitrogen atom, a sulfur atom, or an oxygen atom.

An indole group may be bonded to at least one of the three benzene rings of the polycyclic core or to the phenyl group bonded to the nitrogen atom. For example, an indole group that includes two phenyl substituents may be bonded to at least one of the three benzene rings of the polycyclic core or to the phenyl group bonded to the nitrogen atom.

In an embodiment, an emission layer EML may include a first compound represented by Formula 1. In the specification, the first compound corresponds to the polycyclic compound according to an embodiment.

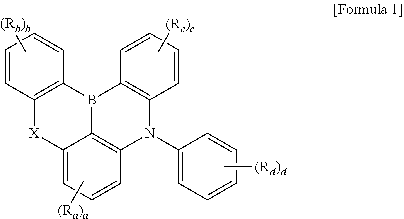

In Formula 1, X may be O, S, or N(Ar). For example, X may be O, X may be S, or X may be N(Ar).

In Formula 1, Ar may be a substituted or unsubstituted aryl group having 6 to 60 ring-forming carbon atoms. For example, Ar may be a substituted or unsubstituted phenyl group. For example, when Ar is a substituted phenyl group, Ar may be a phenyl group substituted with at least one of a deuterium atom, a phenyl group, a t-butyl group, or a substituent represented by Formula 2.

In Formula 1, a may be an integer from 1 to 3. When a is 2 or greater, at least two Rₐ groups may be the same as each other, or at least one group thereof may be different from the remainder.

In Formula 1, b and c may each independently be an integer from 1 to 4. Thus, b and c may be the same as or different from each other. When b is 2 or greater, at least two Rₑ groups may be the same as each other, or at least one group thereof may be different from the remainder. When c is 2 or greater, at least two R_{c} groups may be the same as each other, or at least one group thereof may be different from the remainder.

In Formula 1, d may be an integer from 1 to 5. When d is 2 or greater, at least two R_{d} groups may be the same as each other, or at least one group thereof may be different from the remainder.

In Formula 1, at least one of Rₐ to R_{d} may each independently be a group represented by Formula 2, and the remainder of Rₐ to R_{d} may each independently be a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or may be bonded to an adjacent group to form a ring.

For example, one of Rₐ to R_{d} may be a group represented by Formula 2, two of Rₐ to R_{d} may each independently be a group represented by Formula 2, or three of Rₐ to R_{d} may each independently be a group represented by Formula 2.

The remainder of Rₐ to R_{d} which are not a group represented by Formula 2 may be the same as each other, or at least one group thereof may be different from the remainder. For example, the remainder of Rₐ to R_{d} which are not represented by Formula 2 may each independently be a hydrogen atom, a deuterium atom, a substituted or unsubstituted oxy group, a substituted or unsubstituted thio group, a substituted or unsubstituted boron group, a substituted or unsubstituted amine group, an unsubstituted methyl group, an unsubstituted t-butyl group, or an unsubstituted phenyl group, or may be bonded to an adjacent group to form a ring.

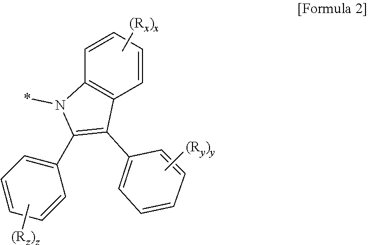

In Formula 2, Rₓ to R_{z} may each independently be a hydrogen atom, a deuterium atom, or a substituted or unsubstituted alkyl group having 1 to 60 carbon atoms. In Formula 2, Rₓ to R_{z} may be the same as each other, or at least one group thereof may be different from the remainder. For example, Rₓ to R_{z} may each independently be a hydrogen atom, a deuterium atom, an unsubstituted methyl group, or an unsubstituted t-butyl group.

In Formula 2, x may be an integer from 0 to 4. A case where x is 0 may be the same as a case where x is 4 and Rₓ groups are all hydrogen atoms. When x is 2 or greater, at least two Rₓ groups may be the same as each other, or at least one group thereof may be different from the remainder.

In Formula 2, y and z may each independently be an integer from 0 to 5. Thus, y and z may be the same as or different from each other. A case where y is 0 may be the same as a case where y is 5 and Ry groups are all hydrogen atoms. When x is 2 or greater, at least two Ry groups may be the same as each other, or at least one group thereof may be different from the remainder. A case where z is 0 may be the same as a case where z is 5 and R_{z} groups are all hydrogen atoms. When z is 2 or greater, at least two R_{z} groups may be the same as each other, or at least one group thereof may be different from the remainder.

In Formula 2,

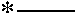 [SMILES: *C]

represents a bond to Formula 1. For example,

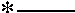 [SMILES: *C]

may represent a bond to a benzene ring of the polycyclic core in Formula 1 or to the phenyl group bonded to the nitrogen atom.

Accordingly the polycyclic core in Formula 1 may be represented by the following structure, and X in the structure below may be the same as defined in Formula 1.

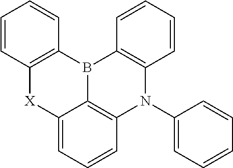

At least one hydrogen atom in Formula 1 and Formula 2 may be optionally substituted with a deuterium atom. For example, the polycyclic compound represented by Formula 1 may not include deuterium atoms, or some or all of the hydrogen atoms therein may be substituted with deuterium atoms. For example, when multiple R_{d} groups in Formula 1 are hydrogen atoms, the R_{d} groups may all be hydrogen atoms, or some or all of the R_{d} groups may be substituted with deuterium atoms. For example, when Rₓ groups, Ry groups, and R_{z} groups in Formula 2 are each hydrogen atoms, the Rₓ groups, Ry groups, and R_{z} groups may all be hydrogen atoms, or some or all of the Rₓ groups, Ry groups, and R_{z} groups may be substituted with deuterium atoms.

In an embodiment, the polycyclic compound may be represented by any one of Formula 1-1a to Formula 1-1f:

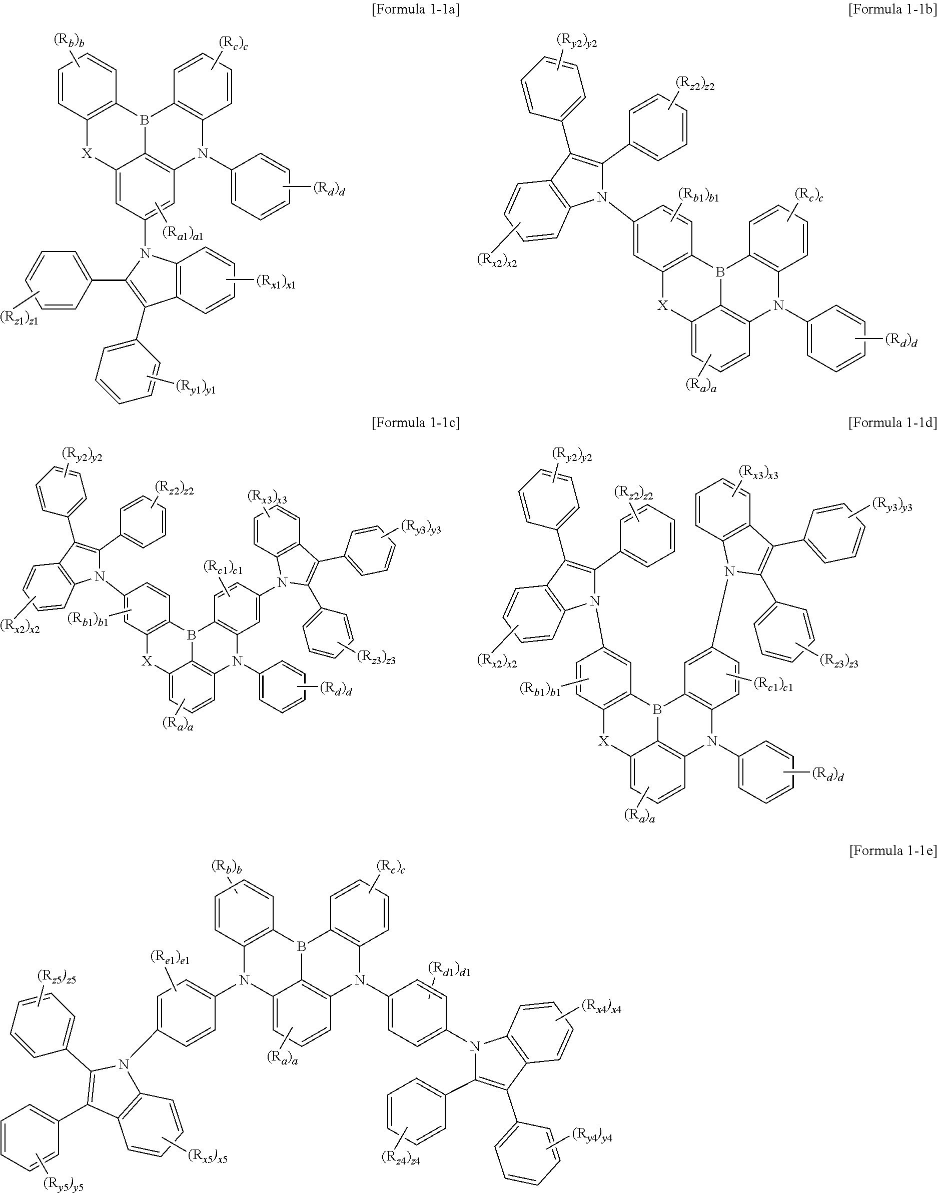

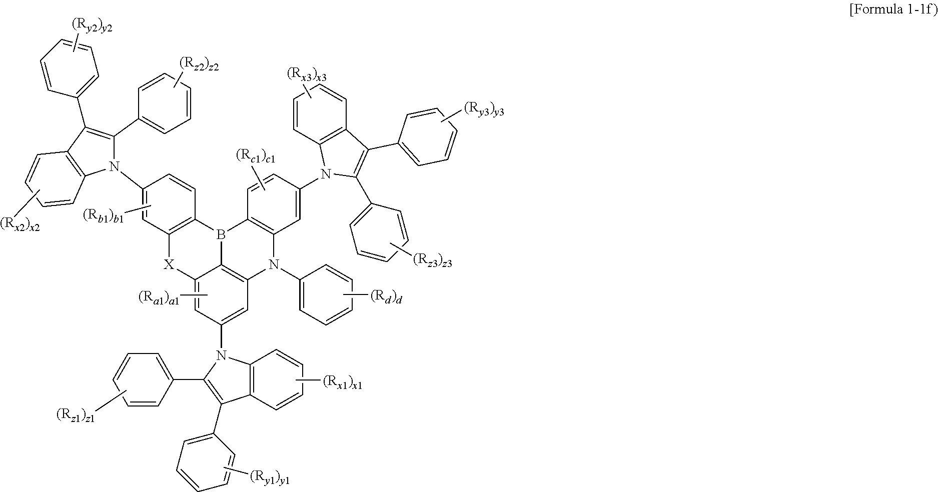

Formulae 1-1a to 1-1f each represents a case where the bonding position of one or more groups represented by Formula 2 to a benzene ring or a phenylene group in Formula 1 is further defined.

In Formulae 1-1a to 1-1f, Rₐ to R_{d}, Rₐ₁, R_{b1}, R_{c1}, R_{d1}, and Rₑ₁ may each independently be a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or may be bonded to an adjacent group to form a ring.

In Formulae 1-1a to 1-1f, a1 may be 1 or 2. When a1 is 2, two Rₐ₁ groups may be the same as or different from each other.

In Formulae 1-1a to 1-1f, b1 and c1 may each independently be an integer from 1 to 3. Thus, b1 and c1 may be the same as or different from each other. When b1 is 2 or greater, at least two R_{b1} groups may be the same as each other, or at least one group thereof may be different from the remainder. When c1 is 2 or greater, at least two R_{c1} groups maybe the same as each other, or at least one group thereof may be different from the remainder.

In Formulae 1-1a to 1-1f, d1 and e1 may each independently be an integer from 1 to 4. Thus, d1 and e1 may be the same as or different from each other. When d1 is 2 or greater, at least two Rₐ₁ groups may be the same as each other, or at least one group thereof may be different from the remainder. When e1 is 2 or greater, at least two Rₑ₁ groups maybe the same as each other, or at least one group thereof may be different from the remainder.

In Formulae 1-1a to 1-1f, Rₓ₁ to Rₓ₅, R_{y1} to R_{y5} and R_{z1} to R_{z5} may each independently be a hydrogen atom, a deuterium atom, or a substituted or unsubstituted alkyl group having 1 to 60 carbon atoms. Thus, Rₓ₁ to Rₓ₅, R_{y1} to R_{y5} and R_{z1} to R_{z5} may be the same as each other, or at least one group thereof may be different from the remainder. For example, Rₓ₁ to Rₓ₅, R_{y1} to R_{y5} and R_{z1} to R_{z5} may each independently be a hydrogen atom, a deuterium atom, an unsubstituted methyl group, or an unsubstituted t-butyl group.

In Formulae 1-1a to 1-1f, x1 to x5 may each independently be an integer from 0 to 4. Thus, x1 to x5 may be the same as each other, or at least one variable thereof may be different from the remainder. A case where x1 is 0 may be the same as a case where x1 is 4 and Rₓ₁ groups are all hydrogen atoms. When x1 is 2 or greater, at least two Rₓ₁ groups may be the same as each other, or at least one group thereof may be different from the remainder. A case where x2 is 0 may be the same as a case where x2 is 4 and Rₓ₂ groups are all hydrogen atoms. When x2 is 2 or greater, at least two Rₓ₂ groups may be the same as each other, or at least one group thereof may be different from the remainder. A case where x3 is 0 may be the same as a case where x3 is 4 and Rₓ₃ groups are all hydrogen atoms. When x3 is 2 or greater, at least two Rₓ₃ groups may be the same as each other, or at least one group thereof may be different from the remainder. A case where x4 is 0 may be the same as a case where x4 is 4 and Rₓ₄ groups are all hydrogen atoms. When x4 is 2 or greater, at least two Rₓ₄ groups may be the same as each other, or at least one group thereof may be different from the remainder. A case where x5 is 0 may be the same as a case where x5 is 4 and Rₓ₅ groups are all hydrogen atoms. When x5 is 2 or greater, at least two Rₓ₅ groups may be the same as each other, or at least one group thereof may be different from the remainder.

In Formulae 1-1a to 1-1f, y1 to y5 and z1 to z5 may each independently be an integer from 0 to 5. Thus, y1 to y5 and z1 to z5 may be the same as each other, or at least one variable thereof may be different from the remainder. A case where y1 is 0 may be the same as a case where y1 is 5 and R_{y1} groups are all hydrogen atoms. When y1 is 2 or greater, at least two R_{y1} groups may be the same as each other, or at least one group thereof may be different from the remainder. A case where y2 is 0 may be the same as a case where y2 is 5 and R_{y2} groups are all hydrogen atoms. When y2 is 2 or greater, at least two R_{y2} groups may be the same as each other, or at least one group thereof may be different from the remainder. A case where y3 is 0 may be the same as a case where y3 is 5 and R_{y3} groups are all hydrogen atoms. When y3 is 2 or greater, at least two R_{y3} groups may be the same as each other, or at least one group thereof may be different from the remainder. A case where y4 is 0 may be the same as a case where y4 is 5 and R_{y4} groups are all hydrogen atoms. When y4 is 2 or greater, at least two R_{y4} groups may be the same as each other, or at least one group thereof may be different from the remainder. A case where y5 is 0 may be the same as a case where y5 is 5 and R_{y5} groups are all hydrogen atoms. When y5 is 2 or greater, at least two R_{y5} groups may be the same as each other, or at least one group thereof may be different from the remainder.

A case where z1 is 0 may be the same as a case where z1 is 5 and R_{z1} groups are all hydrogen atoms. When z1 is 2 or greater, at least two R_{z1} groups may be the same as each other, or at least one group thereof may be different from the remainder. A case where z2 is 0 may be the same as a case where z2 is 5 and R_{z2} groups are all hydrogen atoms. When z2 is 2 or greater, at least two R_{z2} groups may be the same as each other, or at least one group thereof may be different from the remainder. A case where z3 is 0 may be the same as a case where z3 is 5 and R_{z3} groups are all hydrogen atoms. When z3 is 2 or greater, at least two R_{z3} groups may be the same as each other, or at least one group thereof may be different from the remainder. A case where z4 is 0 may be the same as a case where z4 is 5 and R_{z4} groups are all hydrogen atoms. When z4 is 2 or greater, at least two R_{z4} groups may be the same as each other, or at least one group thereof may be different from the remainder. A case where z5 is 0 may be the same as a case where z5 is 5 and R_{z5} groups are all hydrogen atoms. When z5 is 2 or greater, at least two R_{z5} groups may be the same as each other, or at least one group thereof may be different from the remainder.

In Formulae 1-1a to 1-1f, X and a to d may be the same as defined in Formula 1.

At least one hydrogen atom in Formula 1-1a to Formula 1-1f may be optionally substituted with a deuterium atom.

In an embodiment, the polycyclic compound may be represented by Formula 1a or Formula 1b:

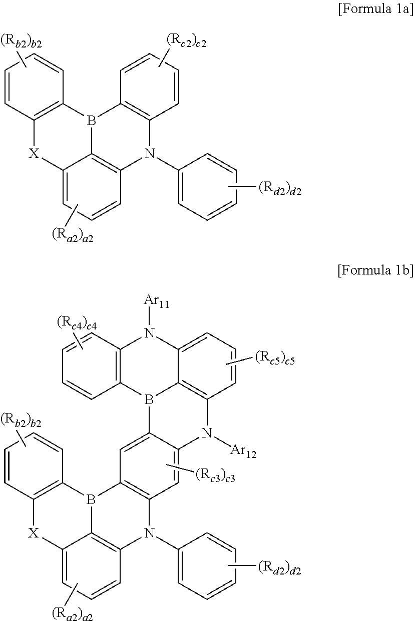

Formula 1a represents a case where adjacent substituents of the polycyclic core in Formula 1 are not bonded to each other to form a ring, and Formula 1b represents a case where adjacent substituents of the polycyclic core in Formula 1 are bonded to each other to form a ring.

In Formula 1a and Formula 1b, a2 may be an integer from 1 to 3. When a2 is 2 or greater, at least two Rₐ₂ groups may be the same as each other, or at least one group thereof may be different from the remainder.

In Formula 1a and Formula 1b, b2 and c2 may each independently be an integer from 1 to 4. Thus, b2 and c2 may be the same as or different from each other. When b2 is 2 or greater, at least two R_{b2} groups may be the same as each other, or at least one group thereof may be different from the remainder. When c2 is 2 or greater, at least two R_{c2} groups may be the same as each other, or at least one group thereof may be different from the remainder.

In Formula 1a and Formula 1b, d2 may be an integer from 1 to 5. When d2 is 2 or greater, at least two R_{d2} groups may be the same as each other, or at least one group thereof may be different from the remainder.

In Formula 1a and Formula 1b, R_{c3} to R_{c5} may each independently be a hydrogen atom, or a group represented by Formula 2. Thus, R_{c3} to R_{c5} may be the same as each other, or at least one group thereof may be different from the remainder. For example, R_{c3} to R_{c5} may all be hydrogen atoms, or R_{c3} and R_{c4} may each be a hydrogen atom, and R_{c5} may be a group represented by Formula 2.

In Formula 1a and Formula 1b, c3 may be 1 or 2. When c3 is 2, two R_{c3} groups may be the same as or different from each other.

In Formula 1a and Formula 1b, c4 may be an integer from 1 to 4. When c4 is 2 or greater, at least two R_{c4} groups may be the same as each other, or at least one group thereof may be different from the remainder.

In Formula 1a and Formula 1b, c5 may be an integer from 1 to 3. When c5 is 2 or greater, at least two R_{c5} groups may be the same as each other, or at least one group thereof may be different from the remainder.

In Formula 1a and Formula 1b, Ar₁₁ and Ar₁₂ may each independently be a substituted or unsubstituted aryl group having 6 to 60 ring-forming carbon atoms. Thus, Ar₁₁ and Ar₁₂ may be the same as or different from each other. For example, Ar₁₁ and Ar₁₂ may each independently be a substituted or unsubstituted phenyl group. For example, when Ar₁₁ and Ar₁₂ are each a substituted phenyl group, Ar₁₁ and Ar₁₂ may each independently be a phenyl group substituted with a deuterium atom or with a phenyl group.

In Formula 1a, at least one of Rₐ₂, R_{b2}, R_{c2}, and R_{d2} may each independently be a group represented by Formula 2, and the remainder of Rₐ₂, R_{b2}, R_{c2}, and Rₐ₂ may each independently be a hydrogen atom, a deuterium atom, a substituted or unsubstituted alkyl group having 1 to 60 carbon atoms, or a substituted or unsubstituted aryl group having 6 to 60 ring-forming carbon atoms.

For example, one of Rₐ₂, R_{b2}, R_{c2}, and R_{d2} may be a group represented by Formula 2; and two of Rₐ₂, R_{b2}, R_{c2}, and R_{d2} may each independently be a group represented by Formula 2; or three of Rₐ₂, R_{b2}, R_{c2}, and R_{d2} may each independently be a group represented by Formula 2.

The remainder of Rₐ₂, R_{b2}, R_{c2}, and R_{d2} which are not a group represented by Formula 2 may be the same as each other, or at least one group thereof may be different from the remainder. For example, the remainder of Rₐ₂, R_{b2}, R_{c2}, and R_{d2} which are not a group represented by Formula 2 may each independently be a hydrogen atom, a deuterium atom, an unsubstituted methyl group, an unsubstituted t-butyl group, or an unsubstituted phenyl group.

In Formula 1b, at least one of Rₐ₂, R_{b2}, and R_{d2} may each independently be a group represented by Formula 2, and the remainder of Rₐ₂, R_{b2}, and R_{d2} may each independently be a hydrogen atom, a deuterium atom, a substituted or unsubstituted alkyl group having 1 to 60 carbon atoms, or a substituted or unsubstituted aryl group having 6 to 60 ring-forming carbon atoms.

For example, one of Rₐ₂, R_{b2}, and R_{d2} may be a group represented by Formula 2.

The remainder of Rₐ₂, R_{b2}, and R_{d2} which are not a group represented by Formula 2 may be the same as each other, or at least one group thereof may be different from the remainder. For example, the remainder of Rₐ₂, R_{b2}, and R_{d2} which are not a group represented by Formula 2 may each independently be a hydrogen atom, a deuterium atom, an unsubstituted methyl group, an unsubstituted t-butyl group, or an unsubstituted phenyl group.

In Formula 1a and Formula 1b, X may be the same as defined in Formula 1.

At least one hydrogen atom in Formula 1a, Formula 1b, and Formula 2 may be optionally substituted with a deuterium atom.

In an embodiment, the light emitting device includes an emission layer disposed between the first electrode and the second electrode, and the emission layer includes the polycyclic compound represented by Formula 1.

In an embodiment, in Formula 1, at least one of Rₐ to R_{d} may each independently be a group represented by Formula 3, and the remainder of Rₐ to R_{d} may each independently be a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or may be bonded to an adjacent group to form a ring.

For example, one of Rₐ to R_{d} may be a group represented by Formula 3; two of Rₐ to R_{d} may each independently be a group represented by Formula 3; or three of Rₐ to R_{d} may each independently be a group represented by Formula 3.

The remainder of Rₐ to R_{d} which are not represented by Formula 3 may be the same as each other, or at least one group thereof may be different from the remainder. For example, the remainder of Rₐ to R_{d} which are not represented by Formula 3 may each independently be a hydrogen atom, a deuterium atom, a substituted or unsubstituted oxy group, a substituted or unsubstituted thio group, a substituted or unsubstituted boron group, a substituted or unsubstituted amine group, an unsubstituted methyl group, an unsubstituted t-butyl group, or an unsubstituted phenyl group, or may be bonded to an adjacent group to form a ring.

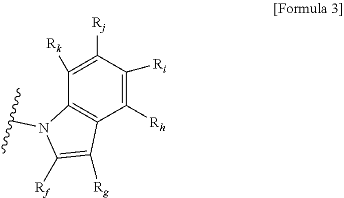

In Formula 3, two of R_{f} to Rₖ may each independently be a substituted or unsubstituted aryl group having 6 to 60 carbon atoms, and the remainder of R_{f} to Rₖ may each independently be a hydrogen atom, a deuterium atom, or a substituted or unsubstituted alkyl group having 1 to 60 carbon atoms. Thus, R_{f} to Rₖ may be the same as each other, or at least one group thereof may be different from the remainder.

For example, R_{f} and R_{g} may each independently be a substituted or unsubstituted phenyl group. For example, when R_{f} and R_{g} are each a substituted phenyl group, R_{f} and R_{g} may each be a phenyl group substituted with deuterium atoms. For example, Rₕ to Rₖ may each independently be a hydrogen atom, a deuterium atom, an unsubstituted methyl group, or an unsubstituted t-butyl group.

In Formula 3,

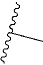

represents a bond to Formula 1. For example,

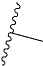

may represent a bond to a benzene ring of the polycyclic core in Formula 1 or to the phenyl group bonded to the nitrogen atom.

In an embodiment, the polycyclic compound may be represented by Formula 1-2a or Formula 1-2b:

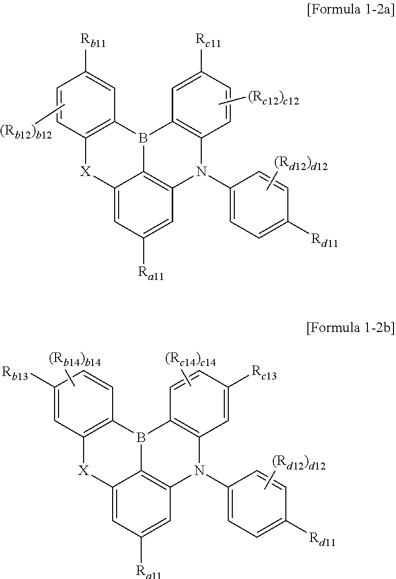

Formula 1-2a and Formula 1-2b each represent a case where the bonding position of one or more groups represented by Formula 3 to Formula 1 is further defined.

In Formula 1-2a and Formula 1-2b, R_{b12}, R_{b14}, R_{c12}, R_{c14}, and R_{d12} may each independently be a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or may be bonded to an adjacent group to form a ring. Thus, R_{b12}, R_{b14}, R_{c12}, R_{c14}, and R_{d12} may be the same as each other, or at least one group thereof may be different from the remainder. For example, R_{b12}, R_{b14}, R_{c12}, R_{c14}, and R_{d12} may each independently be a hydrogen atom, a deuterium atom, a substituted or unsubstituted oxy group, a substituted or unsubstituted thio group, a substituted or unsubstituted boron group, a substituted or unsubstituted amine group, an unsubstituted methyl group, an unsubstituted t-butyl group, or an unsubstituted phenyl group, or may be bonded to an adjacent group to form a ring.

In Formula 1-2a and Formula 1-2b, b12, b14, c12, and c14 may each independently be an integer from 1 to 3. Thus, b12, b14, c12, and c14 may be the same as each other, or at least one variable thereof may be different from the remainder. When b12 is 2 or greater, at least two R_{b12} groups may be the same as each other, or at least one group thereof may be different from the remainder. When b14 is 2 or greater, at least two R_{b14} groups may be the same as each other, or at least one group thereof may be different from the remainder. When c12 is 2 or greater, at least two R_{c12} groups may be the same as each other, or at least one group thereof maybe different from the remainder. When c14 is 2 or greater, at least two R_{c14} groups may be the same as each other, or at least one group thereof may be different from the remainder.

In Formula 1-2a and Formula 1-2b, d12 may be an integer from 1 to 4. When d12 is 2 or greater, at least two R_{d12} groups may be the same as each other, or at least one group thereof may be different from the remainder.

In Formula 1-2a and Formula 1-2b, X may be the same as defined in Formula 1.

In Formula 1-2a, at least one of Rₐ₁₁, R_{b11}, R_{c11}, and R_{d11} may each independently be a group represented by Formula 3, and the remainder of Rₐ₁₁, R_{b11}, R_{c11}, and R_{d11} may each independently be a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or may be bonded to an adjacent group to form a ring.

For example, one of Rₐ₁₁, R_{b11}, R_{c11}, and R_{d11} may be a group represented by Formula 3; or two of Rₐ₁₁, R_{b11}, R_{c11}, and R_{d11} may each independently be a group represented by Formula 3.

The remainder of Rₐ₁₁, R_{b11}, R_{c11}, and R_{d11} which are not a group represented by Formula 3 may each independently be the same as each other, or at least one group thereof may be different from the remainder. For example, the remainder of Rₐ₁₁, R_{b11}, R_{c11}, and R_{d11} which are not a group represented by Formula 3 may each independently be a hydrogen atom, a deuterium atom, a substituted or unsubstituted oxy group, a substituted or unsubstituted thio group, a substituted or unsubstituted boron group, a substituted or unsubstituted amine group, an unsubstituted methyl group, an unsubstituted t-butyl group, or an unsubstituted phenyl group, or may be bonded to an adjacent group to form a ring.

In Formula 1-2b, at least one of Rₐ₁₁, R_{b13}, R_{c13}, and R_{d11} may each independently be a group represented by Formula 3, and the remainder of Rₐ₁₁, R_{b13}, R_{c13}, and R_{d11} may each independently be a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or may be bonded to an adjacent group to form a ring.

For example, one of Rₐ₁₁, R_{b13}, R_{c13}, and R_{d11} may be a group represented by Formula 3; two of Rₐ₁₁, R_{b13}, R_{c13}, and R_{d11} may each independently be a group represented by Formula 3; or three of Rₐ₁₁, R_{b13}, R_{c13}, and R_{d11} may each independently be a group represented by Formula 3.

The remainder of Rₐ₁₁, R_{b13}, R_{c13}, and R_{d11} which are not a group represented by Formula 3 may be the same as each other, or at least one group thereof may be different from the remainder. For example, the remainder of Rₐ₁₁, R_{b13}, R_{c13}, and R_{d11} which are not a group represented by Formula 3 may each independently be a hydrogen atom, a deuterium atom, a substituted or unsubstituted oxy group, a substituted or unsubstituted thio group, a substituted or unsubstituted boron group, a substituted or unsubstituted amine group, an unsubstituted methyl group, an unsubstituted t-butyl group, or an unsubstituted phenyl group, or may be bonded to an adjacent group to form a ring.

In Formula 3, R_{f} and R_{g} may each independently be a phenyl group unsubstituted or substituted with a deuterium atom, and Rₕ to Rₖ may each independently be a hydrogen atom, a deuterium atom, an unsubstituted methyl group, or an unsubstituted t-butyl group.

In an embodiment, the polycyclic compound may be any compound selected from Compound Group 1-1 and Compound Group 1-2. In an embodiment, in light emitting device ED, the at least one functional layer may include at least one compound selected from Compound Group 1-1 and Compound Group 1-2: [Compound Group 1-1]

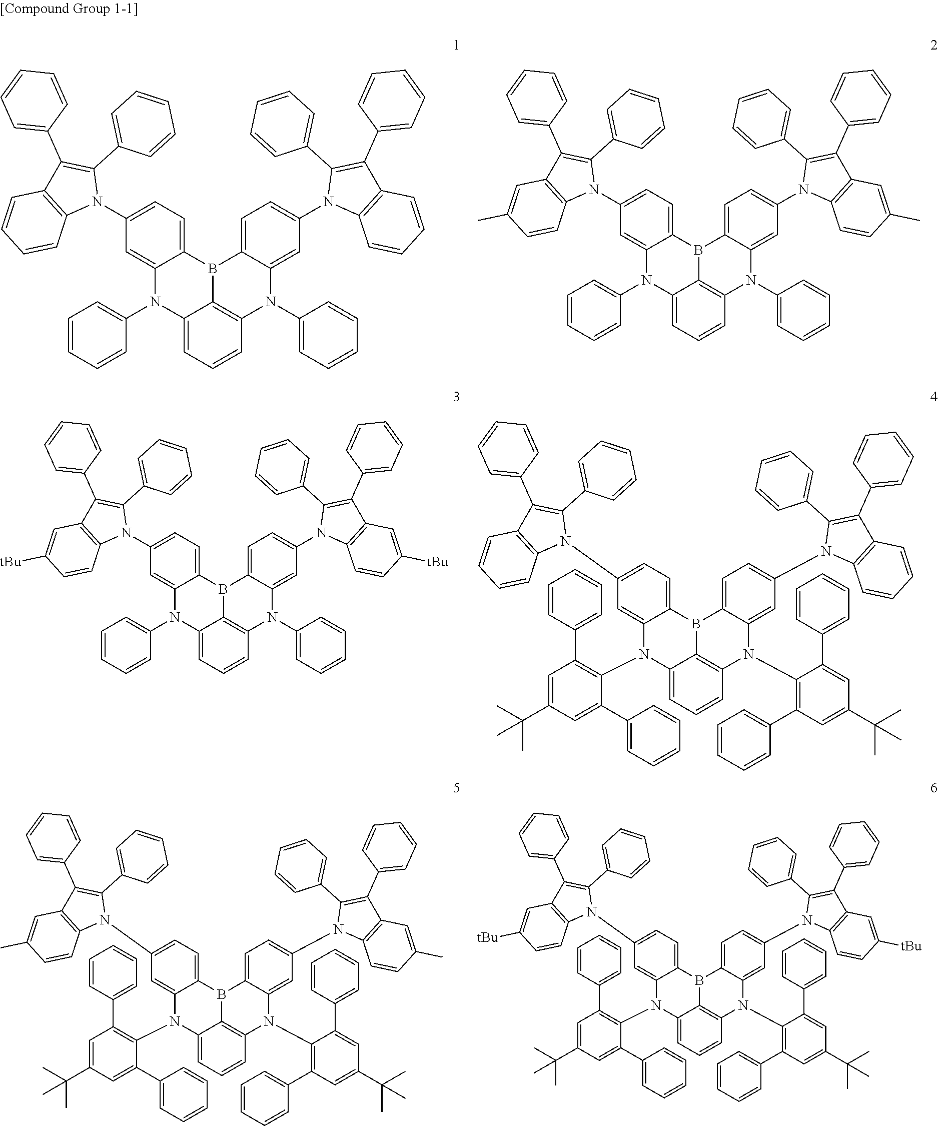

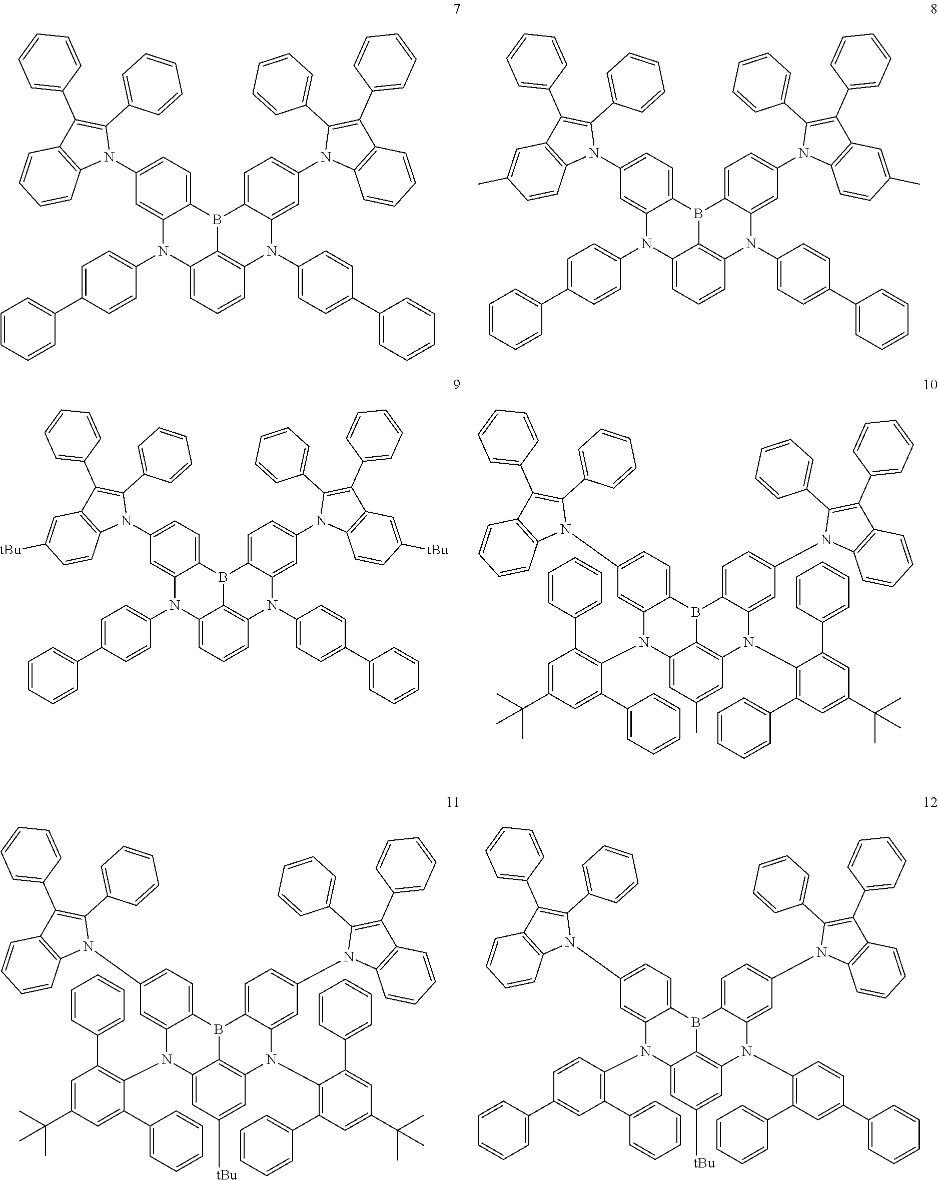

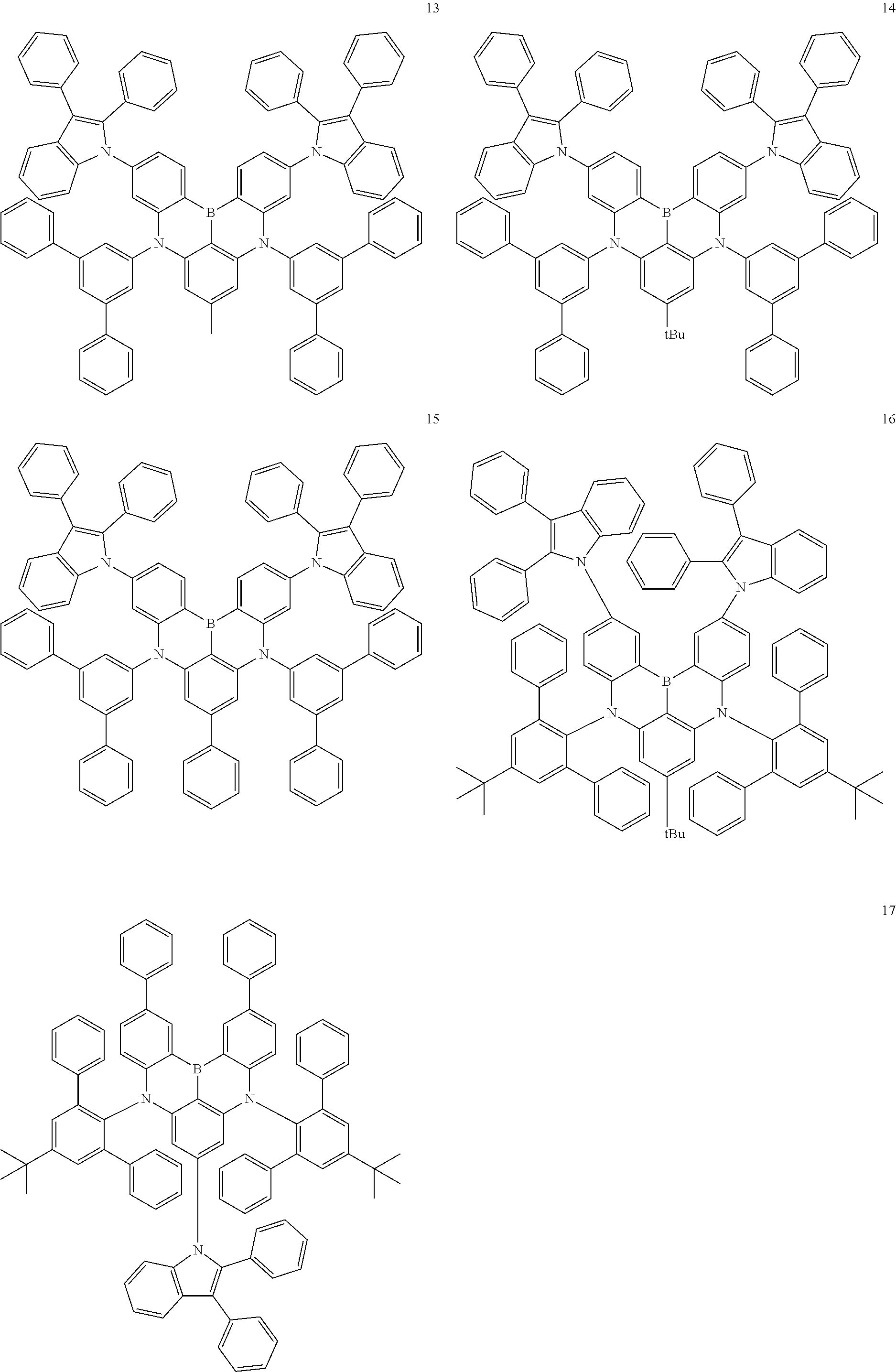

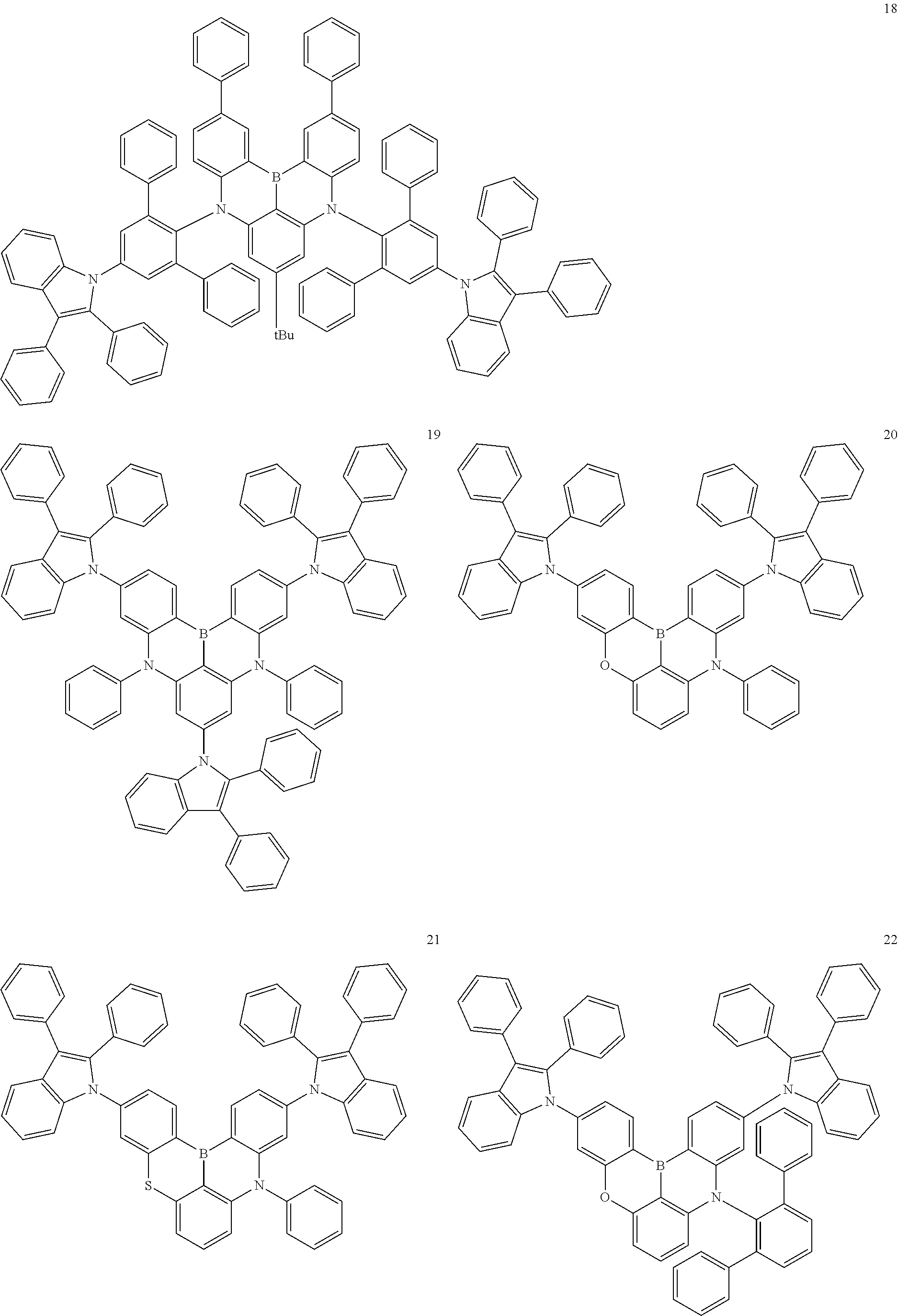

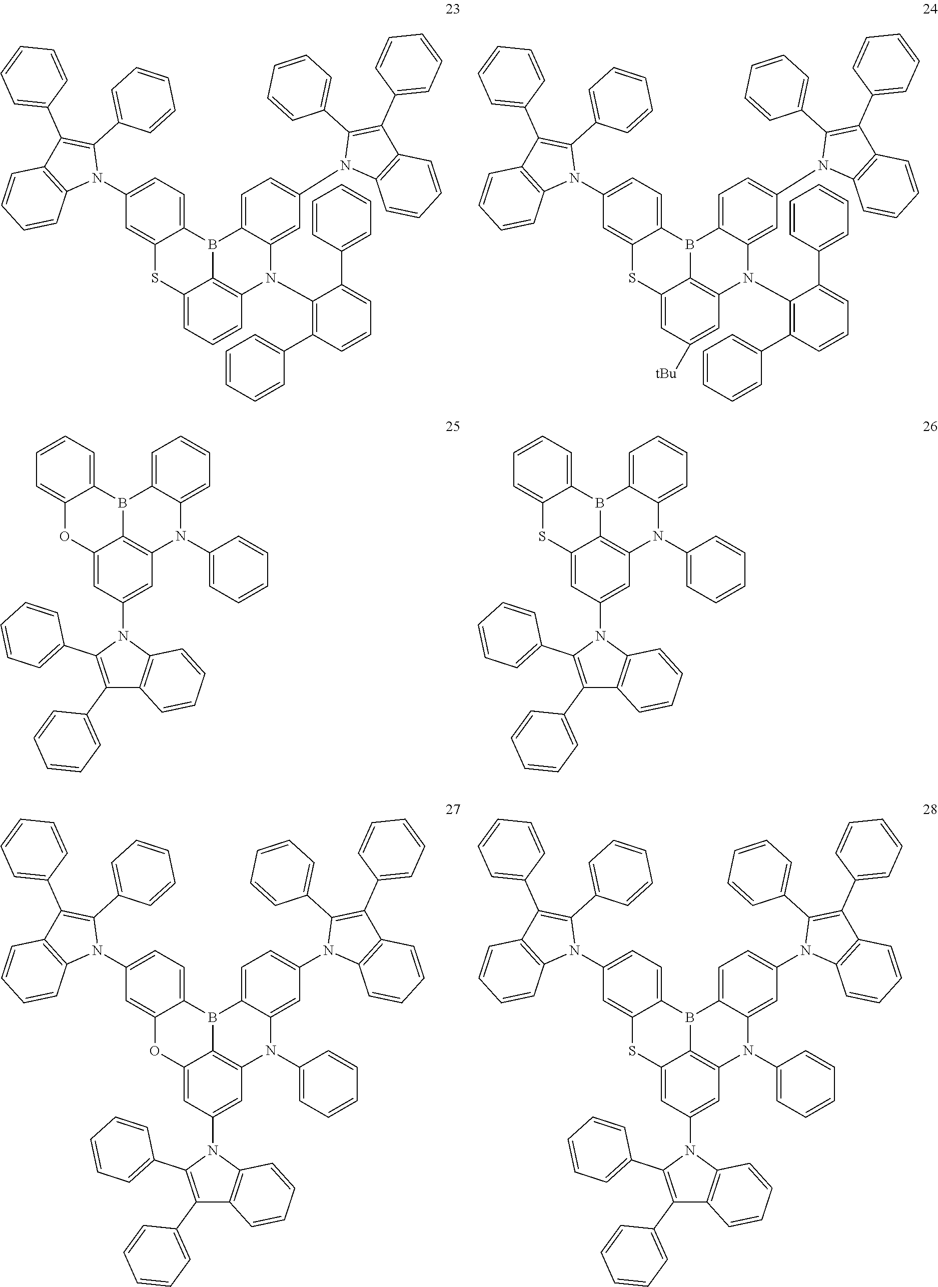

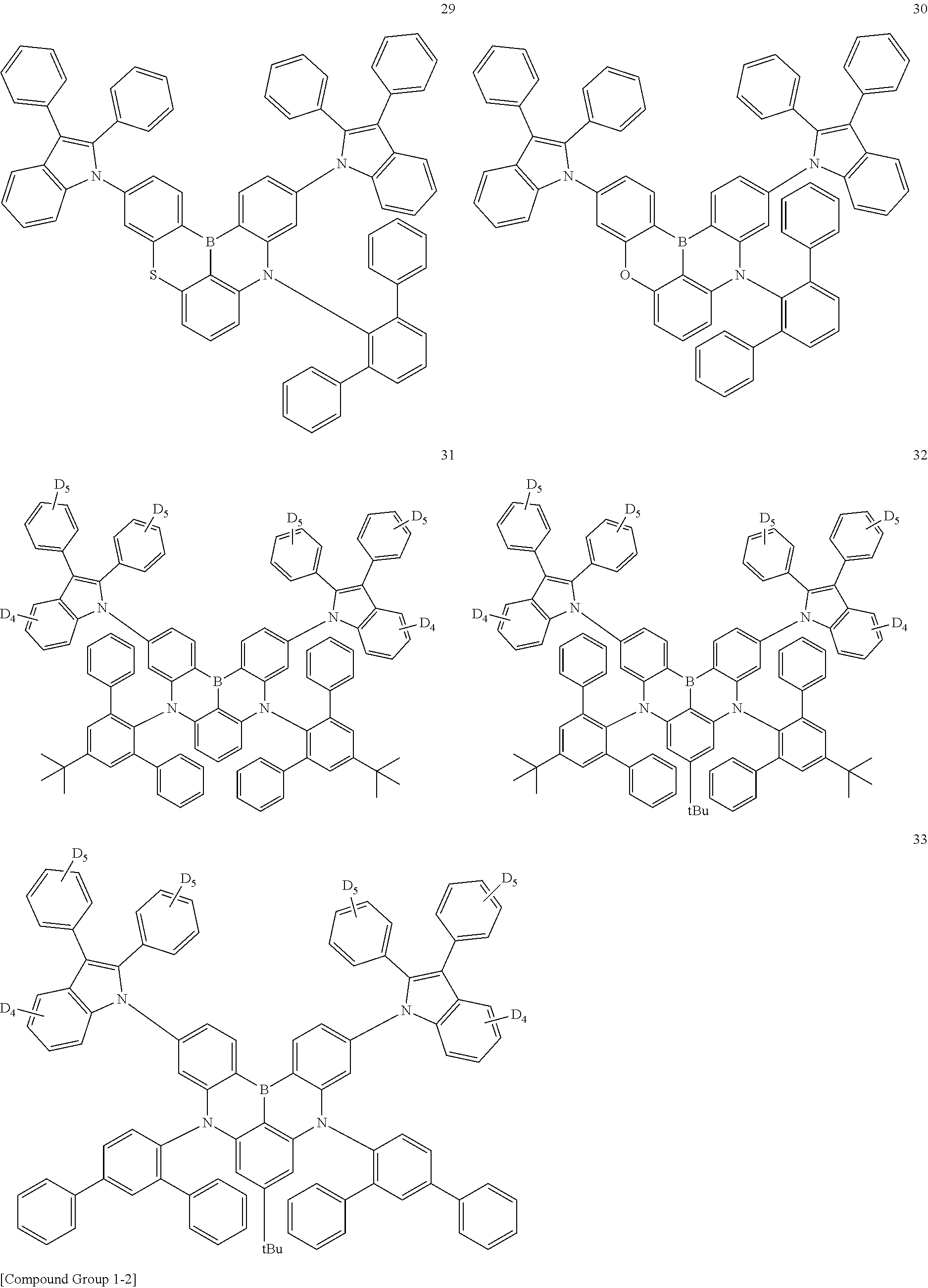

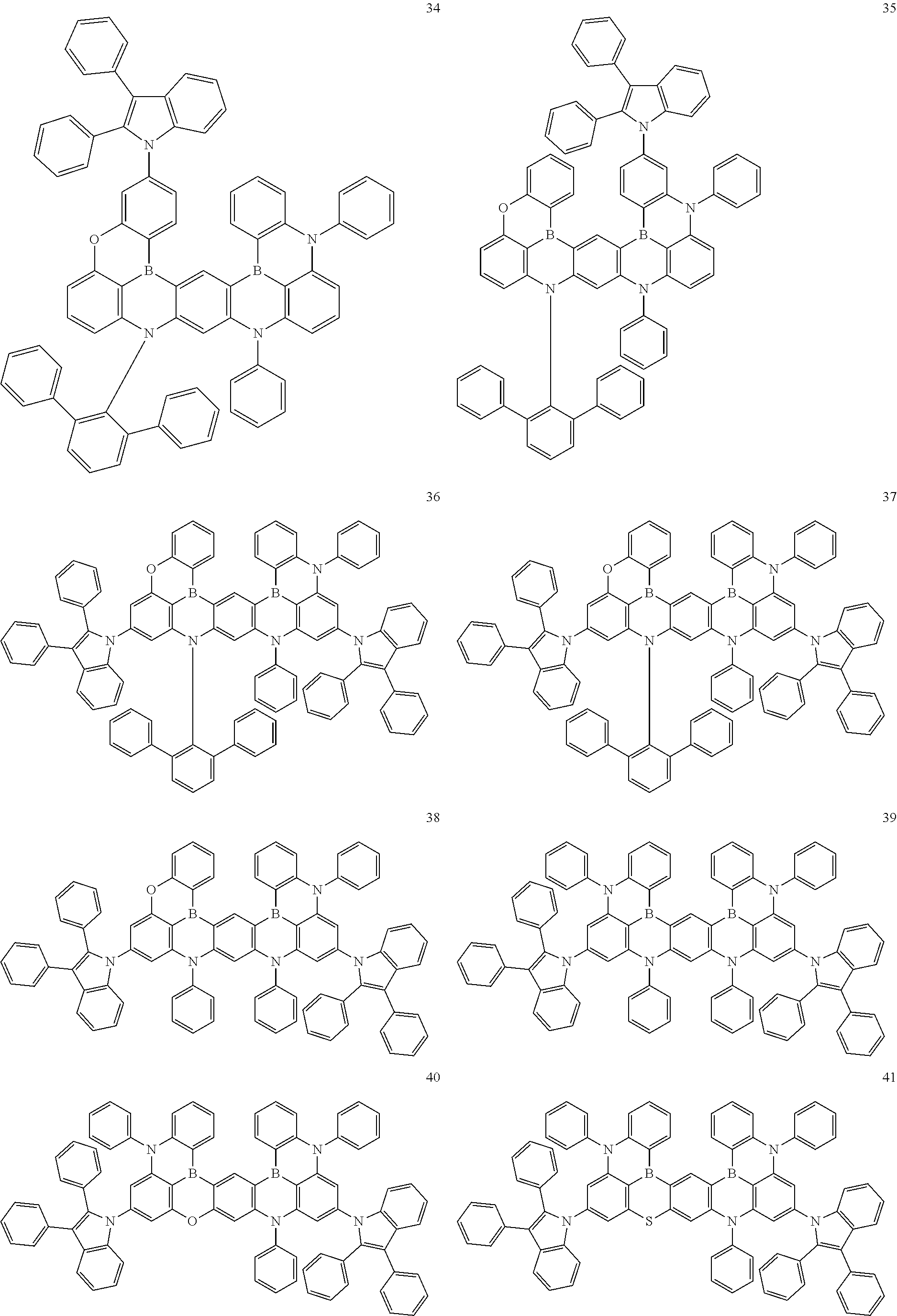

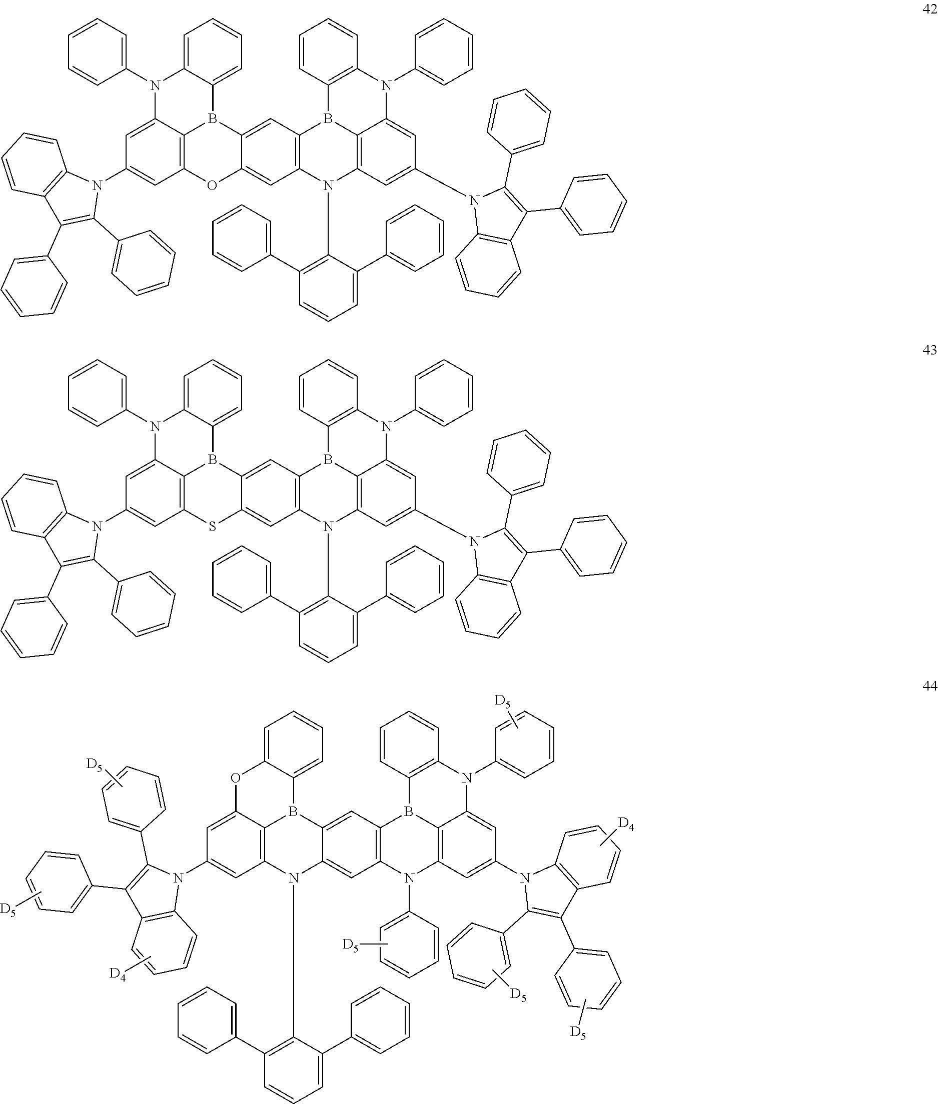

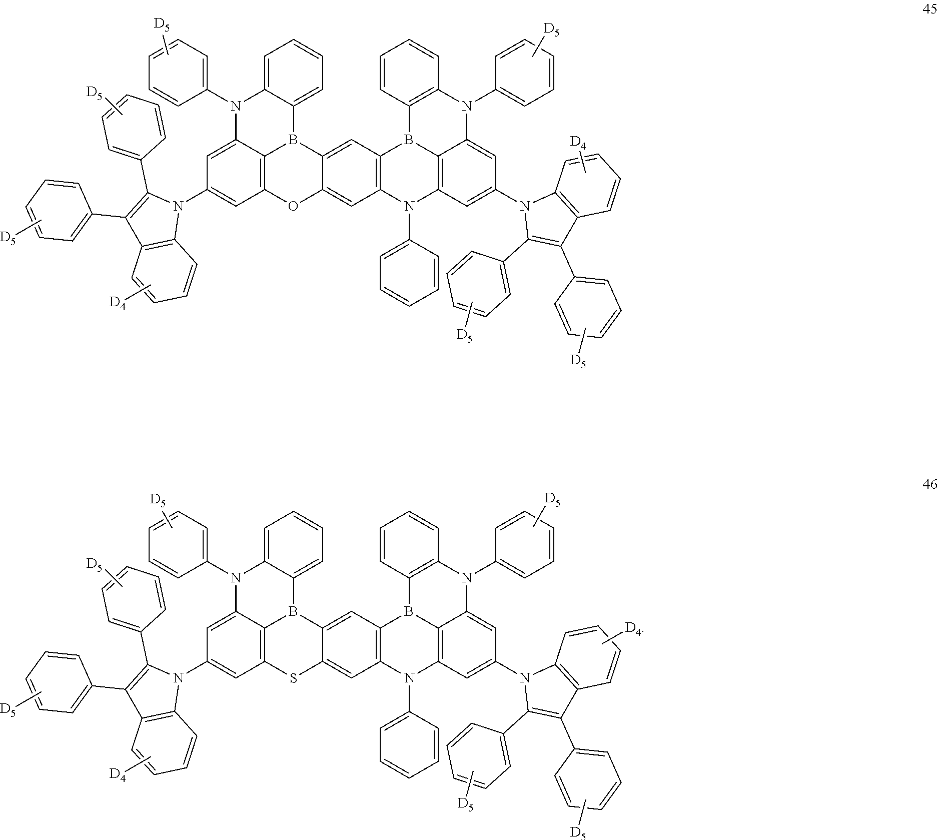

In Compound Group 1-1 and Compound Group 1-2, D represents a deuterium atom, and tBu represents a t-butyl group.

As described above, the polycyclic compound represented by Formula 1 may include a polycyclic core in which multiple aromatic rings are fused via a boron atom, a nitrogen atom, and a heteroatom, and a phenyl group is bonded to the nitrogen atom.

The polycyclic compound may include a pentacyclic structure in which first to third aromatic rings are fused via a boron atom, a nitrogen atom, and a heteroatom. The heteroatom may be, for example, a nitrogen atom, a sulfur atom, or an oxygen atom. The first to third aromatic rings may each independently be a substituted or unsubstituted benzene ring. The polycyclic core of the polycyclic compound may include a phenyl group bonded to the nitrogen atom.

In the polycyclic compound according to an embodiment, substituents of the pentacyclic core may be bonded to an adjacent substituent to form a ring. The ring formed by the bonding of adjacent substituents may include three heteroatoms, and the three heteroatoms may each be selected from a boron atom, a nitrogen atom, a sulfur atom, or an oxygen atom.

An indole group maybe bonded to at least one of three benzene rings of the polycyclic core or to a phenyl group bonded to the nitrogen atom. For example, an indole group with two phenyl substituents may be bonded to the benzene rings of the polycyclic core or to the phenyl group bonded to the nitrogen atom.

The polycyclic compound represented by Formula 1 has a structure in which at least one indole group is a substituent of the polycyclic core, and thus characteristics of the light emitting device such as luminous efficiency and a device service life may be improved. For example, the polycyclic compound may be stabilized by the inclusion of a substituent at the polycyclic core, wherein the substituent is an indole group with two phenyl substituents. Thus, when the polycyclic compound is applied to a light emitting device, color purity may be improved, thereby improving the luminous efficiency and device service life.

The polycyclic compound represented by Formula 1 may be included in the emission layer EML. The polycyclic compound may be included as a dopant material in the emission layer EML. The polycyclic compound may be a thermally activated delayed fluorescence (TADF) material. The polycyclic compound may be used as a thermally activated delayed fluorescence dopant. For example, in the light emitting device ED, the emission layer EML may include, as a thermally activated delayed fluorescence dopant, at least one polycyclic compound selected from Compound Group 1-1 and Compound Group 1-2 as described above. However, a use of the polycyclic compound is not limited thereto.

In an embodiment, the polycyclic compound represented by Formula 1 may be a thermally activated delayed fluorescence dopant having a difference (ΔE_{ST}) between a lowest triplet exciton energy level (T1 level) and a lowest singlet exciton energy level (Si level) that is equal to or less than about 0.6 eV. For example, the polycyclic compound may be a thermally activated delayed fluorescence dopant having a difference (ΔE_{ST}) between a lowest triplet exciton energy level (T1 level) and a lowest singlet exciton energy level (Si level) equal to or less than about 0.2 eV.

In an embodiment, an emission spectrum of the polycyclic compound represented by Formula 1 may have a full width at half maximum (FWHM) in a range of about 10 nm to about 35 nm. The emission spectrum of the polycyclic compound may have a FWHM in the range described above, and thus luminous efficiency may be improved when the polycyclic compound is applied to a device. When the polycyclic compound is used as a blue light emitting device material for the light emitting device, the device service life may be improved.

In an embodiment, the polycyclic compound represented by Formula 1 may emit blue light. In an embodiment, the polycyclic compound may have a maximum emission wavelength in a range of about 450 nm to about 480 nm. For example, the polycyclic compound may have a maximum emission wavelength in a range of about 455 nm to about 470 nm.

In an embodiment, the emission layer EML may include the first compound represented by Formula 1, and at least one of a second compound represented by Formula HT and a third compound represented by Formula ET.

In an embodiment, the emission layer EML may further include a second compound represented by Formula HT. In an embodiment, the second compound may be used as a hole transport host material in the emission layer EML.

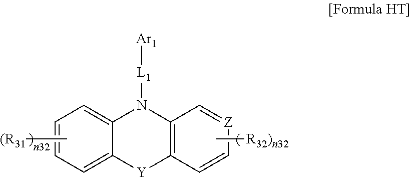

In Formula HT, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT, Ar₁ may be a substituted or unsubstituted aryl group having 6 to 30 ring-forming carbon atoms or a substituted or unsubstituted heteroaryl group having 2 to 30 ring-forming carbon atoms. For example, Ar may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT, Y may be a direct linkage, C(R_{y1})(R_{y2}), or Si(R_{y3})(R_{y4}). For example, the two benzene rings that are bonded to the nitrogen atom in Formula HT may be linked to each other via a direct linkage,

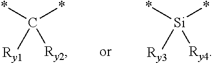

For example, when Y is a direct linkage, the second compound represented by Formula HT may include a carbazole moiety.

In Formula HT, Z may be C(R_{z}) or N.

In Formula HT, R_{y1} to R_{y4}, R₃₁, R₃₂, and R_{z} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R_{y1} to R_{y4} may each independently be a methyl group or a phenyl group. For example, R₃₁ and R₃₂ may each independently be a hydrogen atom or a deuterium atom.

In Formula HT, n31 may be an integer from 0 to 4. If n31 is 0, the second compound may not be substituted with R₃₁. A case where n31 is 4 and R₃₁ groups are all hydrogen atoms may be the same as a case where n31 is 0. When n31 is 2 or greater, at least two R₃₁ groups may be the same as each other, or at least one group thereof may be different from the remainder.

In Formula HT, n32 may be an integer from 0 to 3. If n32 is 0, the second compound may not be substituted with R₃₂. A case where n32 is 3 and R₃₂ groups are all hydrogen atoms may be the same as a case where n32 is 0. When n32 is 2 or greater, at least two R₃₂ groups may be the same as each other, or at least one group thereof may be different from the remainder.

In an embodiment, the emission layer EML may further include a third compound represented by Formula ET. In an embodiment, the third compound may be used as an electron transport host material in the emission layer EML.

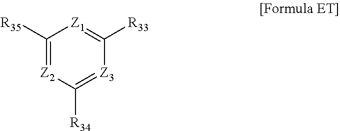

In Formula ET, Z₁ to Z₃ may each independently be N or C(R₃₆), and at least one of Z₁ to Z₃ may each be N. For example, Z₁ to Z₃ may each be N. For example, Z₁ and Z₂ may each be N, and Z₃ may be C(R₃₆); Z₁ may be C(R₃₆), and Z₂ and Z₃ may each be N; or Z₁ and Z₃ may each be N, and Z₂ may be C(R₃₆). For example, Z₁ may be N, and Z₂ and Z₃ may each independently be C(R₃₆); Z₂ may be N, and Z₂ and Z₃ may each independently be C(R₃₆); and Z₃ may be N, and Z₁ and Z₂ may each independently be C(R₃₆).

In Formula ET, R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₃₃ to R₃₆ may each independently be a substituted or unsubstituted phenyl group, a substituted or unsubstituted carbazole group, etc., but embodiments are not limited thereto.

In an embodiment, the emission layer EML may include the second compound and the third compound, and the second compound and the third compound may form an exciplex. In the emission layer EML, an exciplex may be formed by a hole transport host and an electron transport host. A triplet energy of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy (T1) of the exciplex formed by the hole transporting host and the electron transporting host may be in a range of about 2.4 eV to about 3.0 eV. The triplet energy of the exciplex may be a value that is smaller than an energy gap of each host material. The exciplex may have a triplet energy equal to or less than about 3.0 eV, which is an energy gap between the hole transporting host and the electron transporting host.

In an embodiment, the emission layer EML may further include a fourth compound, in addition to the first compound, the second compound, and the third compound as described above. The fourth compound maybe used as a phosphorescent sensitizer in the emission layer EML. Energy may be transferred from the fourth compound to the first compound, thereby emitting light.

The emission layer EML may include a fourth compound that is an organometallic complex containing platinum (Pt) as a central metal atom and ligands bonded to the central metal atom. In an embodiment, the emission layer EML may include a fourth compound represented by Formula PS:

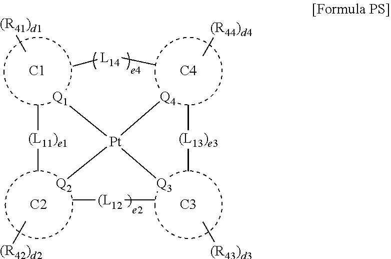

In Formula PS, Q₁ to Q₄ may each independently be C or N.

In Formula PS, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula PS, L₁₁ to L₁₄ may each independently be a direct linkage,

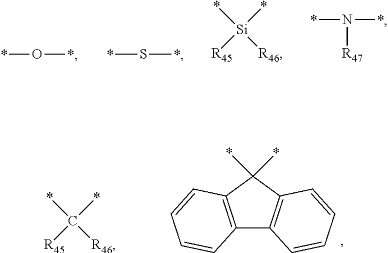

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₄,

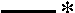 [SMILES: *C]

represents a bond to one of C1 to C4.

In Formula PS, e1 to e4 may each independently be 0 or 1. If e1 is 0, C1 and C2 may not be directly linked to each other. If e2 is 0, C2 and C3 may not be directly linked to each other. If e3 is 0, C3 and C4 may not be directly linked to each other. If e4 is 0, C1 and C4 may not be directly linked to each other.

In Formula PS, R₄₁ to R₄₉ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₄₁ to R₄₉ may each independently be a substituted or unsubstituted methyl group, or a substituted or unsubstituted t-butyl group.

In Formula PS, d1 to d4 may each independently be an integer from 0 to 4. If d1 to d4 are each 0, the fourth compound may not be substituted with any of R₄₁ to R₄₄. A case where d1 to d4 are 4 and R₄₁ groups, R₄₂ groups, R₄₃ groups, and R₄₄ groups are each hydrogen atoms may be the same as a case where d1 to d4 are each 0. When d1 to d4 are each 2 or greater, multiple groups of each of R₄₁ to R₄₄ may be the same as each other, or at least one group thereof may be different from the remainder.

In an embodiment, in Formula PS, C1 to C4 may each independently be a substituted or unsubstituted hydrocarbon ring or a substituted or unsubstituted heterocycle that is represented by any one of Formula C-1 to Formula C-4:

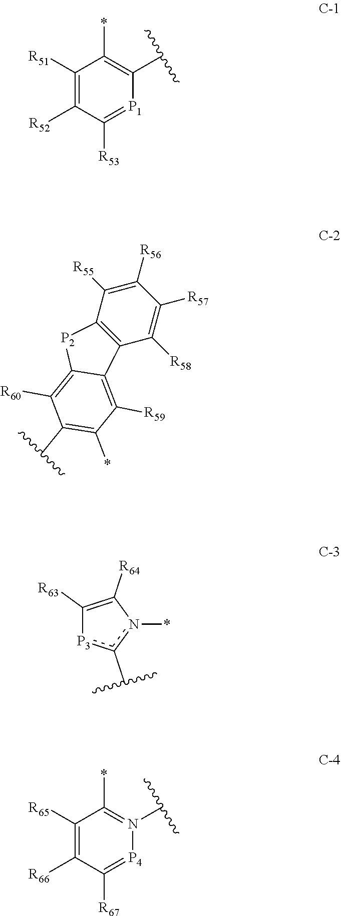

In Formula C-1 to Formula C-4, P₁ may be

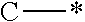 [SMILES: *C]

or C(R₄), P₂ may be

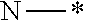 [SMILES: *N]

or N(R₆₁), P₃ may be

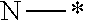 [SMILES: *N]

or N(R₆₂), and P₄ may be

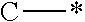 [SMILES: *C]

### or C(R₆₈).

In Formula C-1 to Formula C-4, R₅₁ to R₆₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula C-1 to Formula C-4,

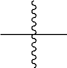

represents a to Pt that is a central metal atom in Formula PS, and

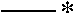 [SMILES: *C]

represents a bond to a neighboring cyclic group (C1 to C4) or to a linker (L₁₁ to L₁₄).

In an embodiment, the emission layer EML may include the first compound, and at least one of the second compound, the third compound, and the fourth compound. For example, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. In an embodiment, the fourth compound may be a sensitizer. The fourth compound included in the emission layer EML of the light emitting device ED may serve as a sensitizer to transfer energy from a host to the first compound, which is a light emitting dopant. For example, the fourth compound, which serves as an auxiliary dopant, may accelerate energy transfer to the first compound, which is a light emitting dopant, thereby increasing an emission ratio of the first compound. Therefore, the emission layer EML may have improved luminous efficiency. When the energy transfer to the first compound increases, excitons formed in the emission layer EML may not accumulate inside the emission layer EML and may emit light rapidly, so that deterioration of the device may be reduced. Therefore, the service life of the light emitting device ED may increase.

The light emitting device ED may include the first compound, the second compound, the third compound, and the fourth compound, and the emission layer EML may include a combination of two host materials and two dopant materials. In the light emitting device ED, the emission layer EML may include two different hosts, the first compound which emits delayed fluorescence, and the fourth compound which includes an organometallic complex, and thus, the light emitting device ED may exhibit excellent luminous efficiency characteristics.

In an embodiment, the second compound represented by Formula HT may be selected from Compound Group HT. In an embodiment, in the light emitting device ED, the second compound may include at least one compound selected from Compound Group HT. In Compound Group HT, D represents a deuterium atom, and Ph represents an unsubstituted phenyl group.

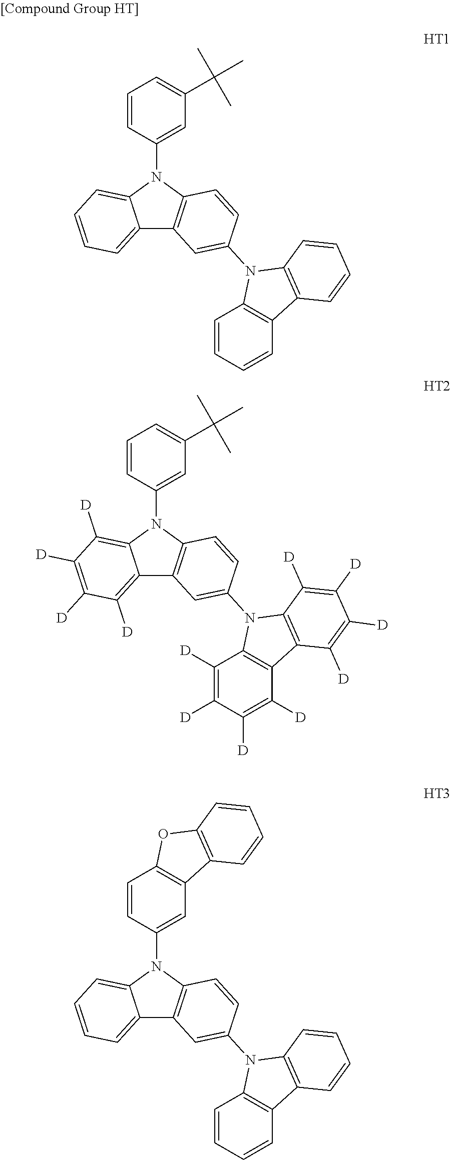

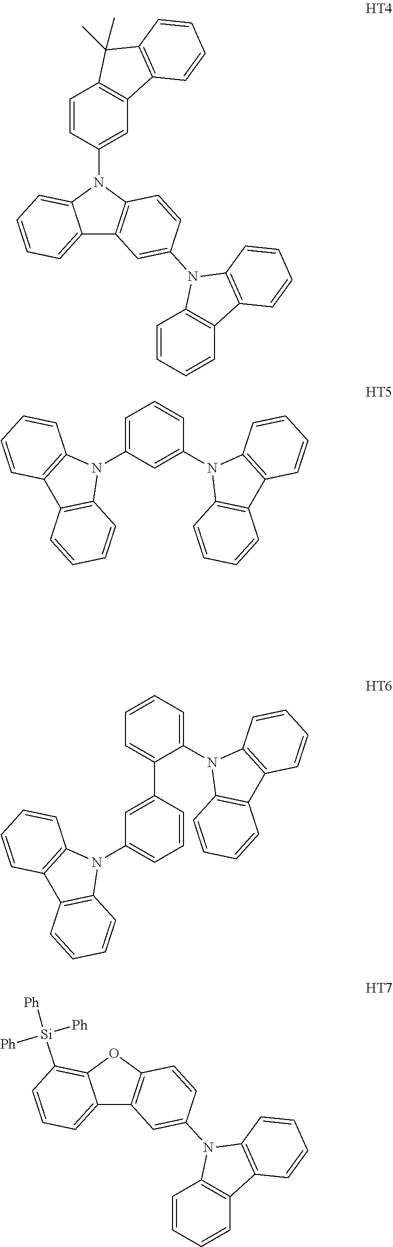

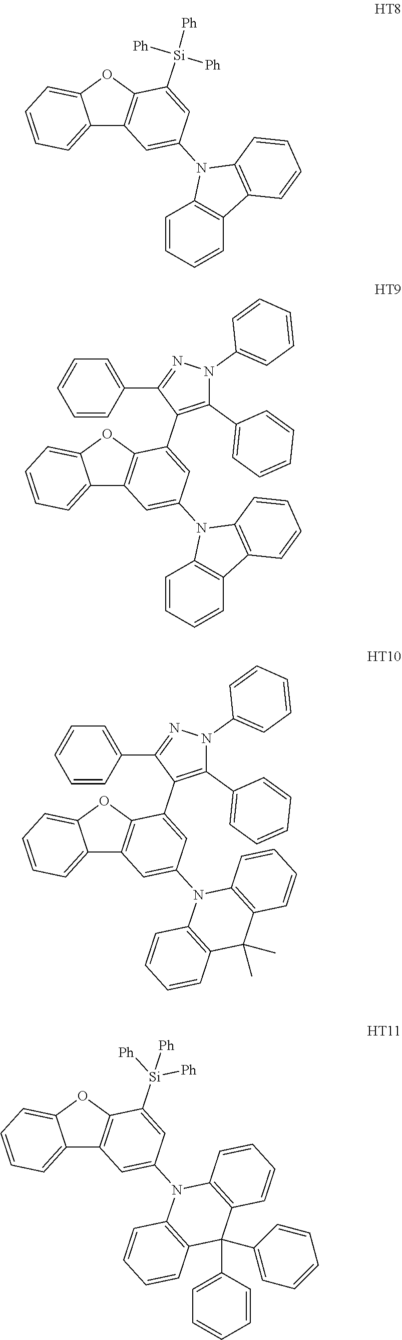 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

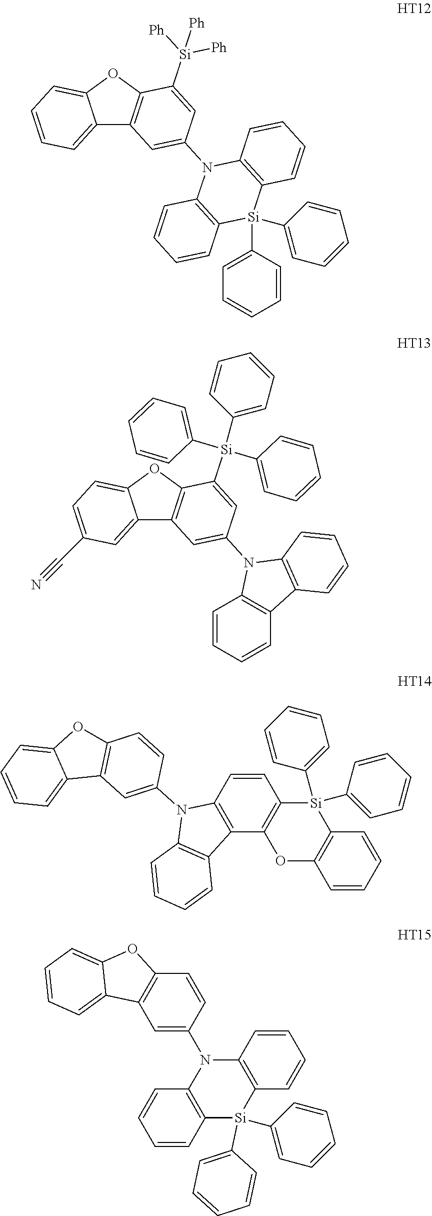

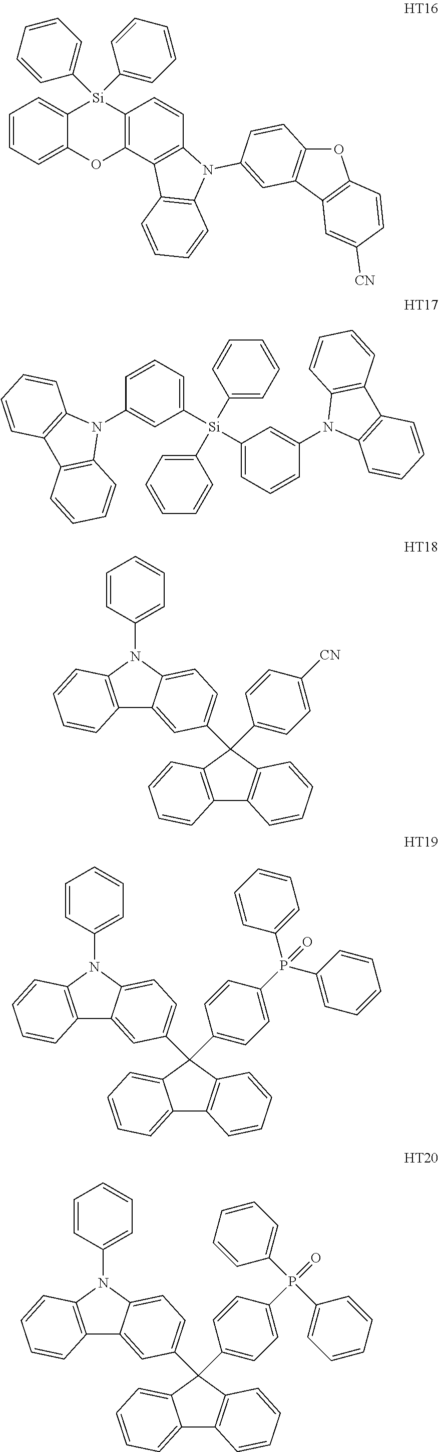

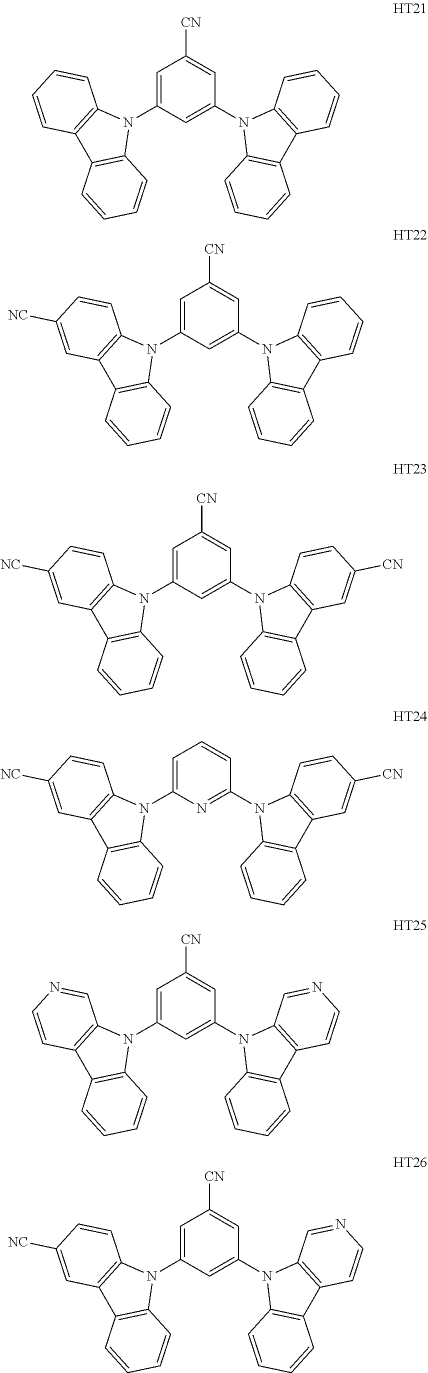

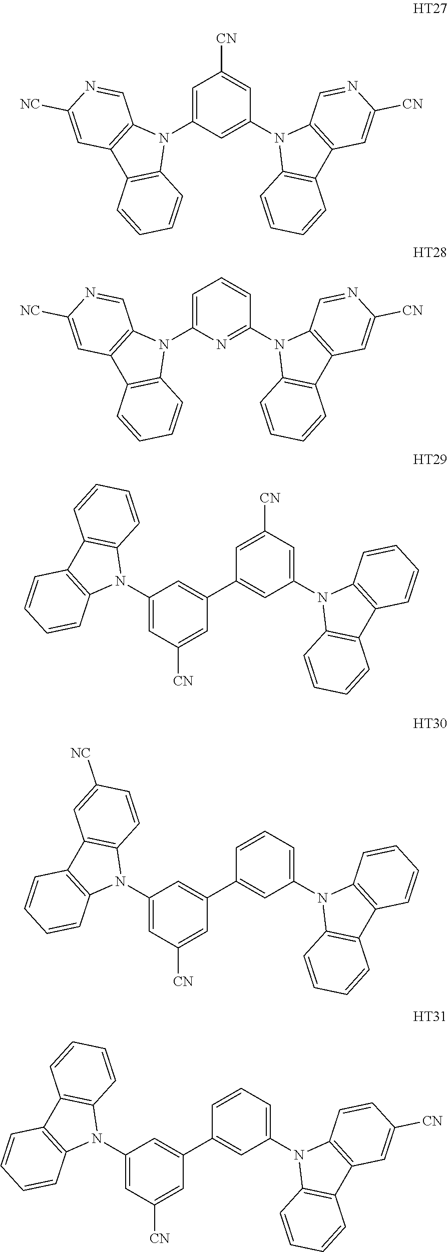 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

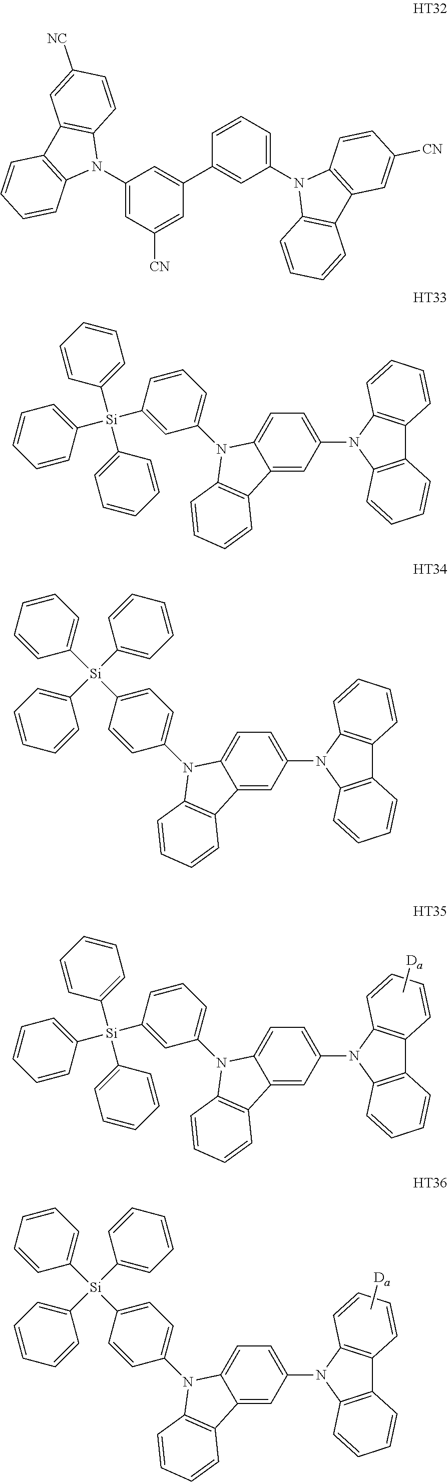

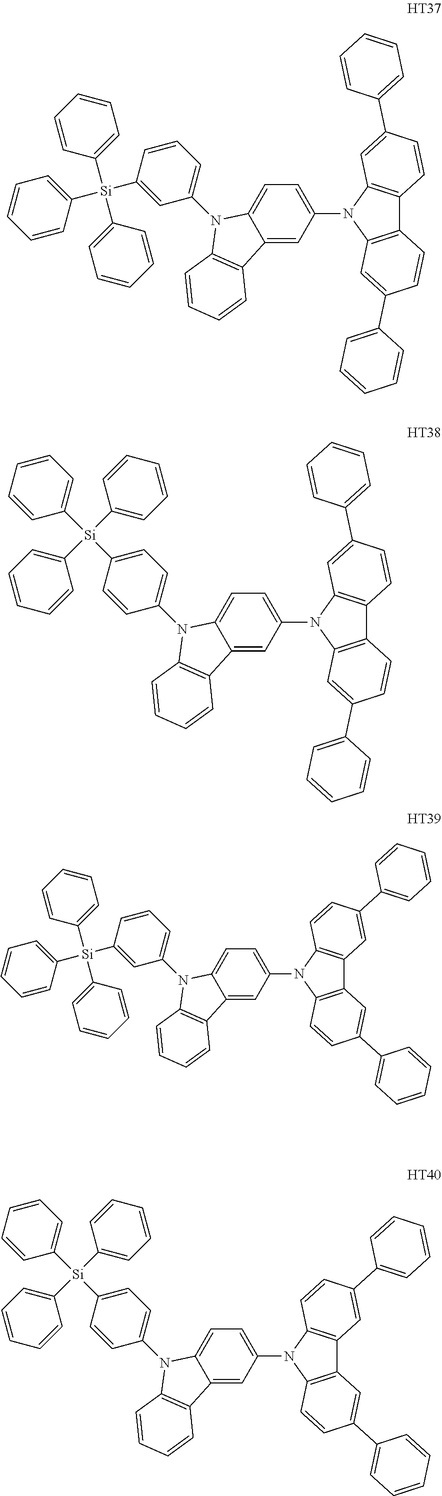 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

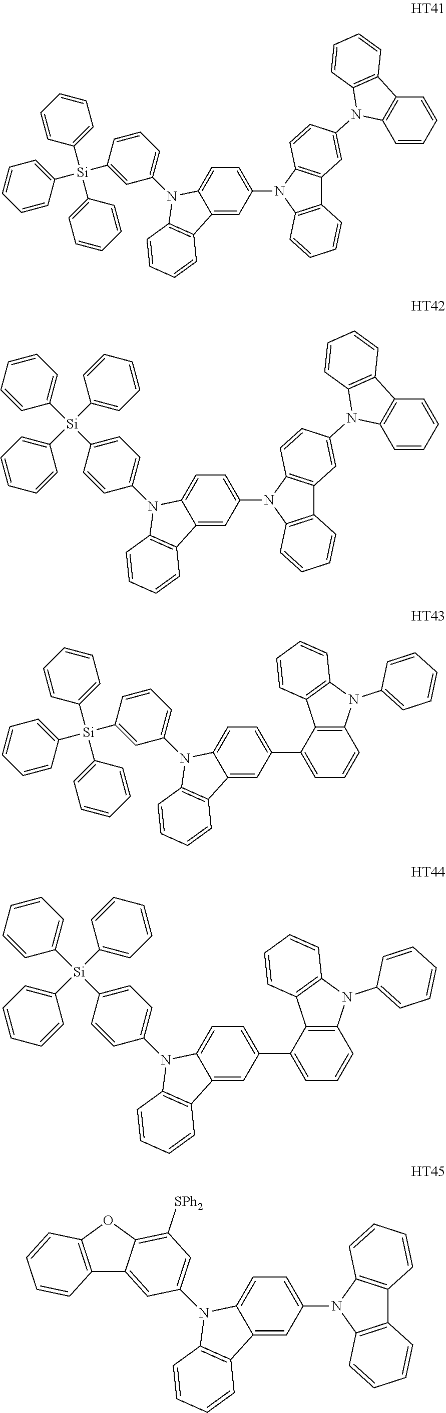

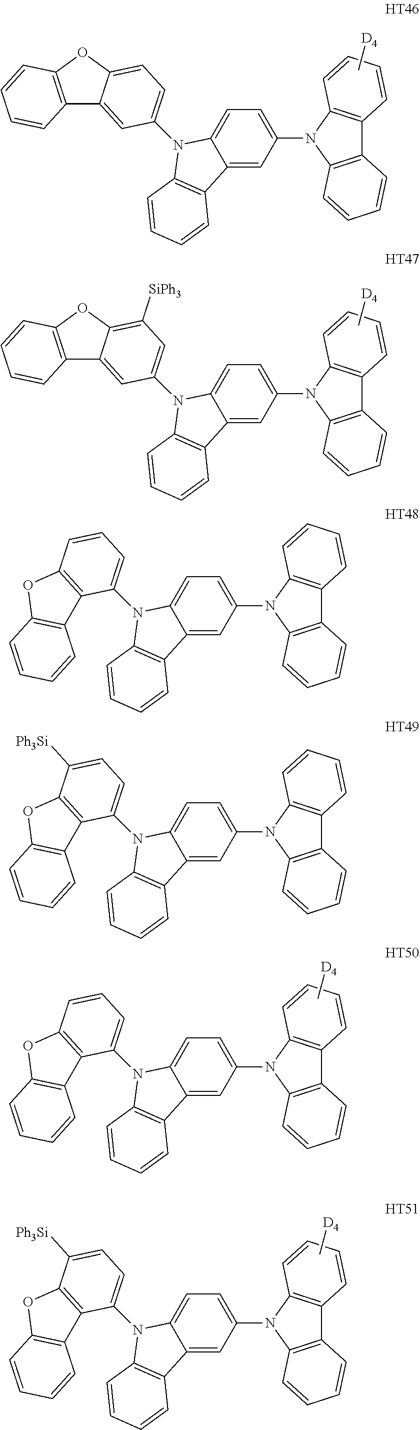

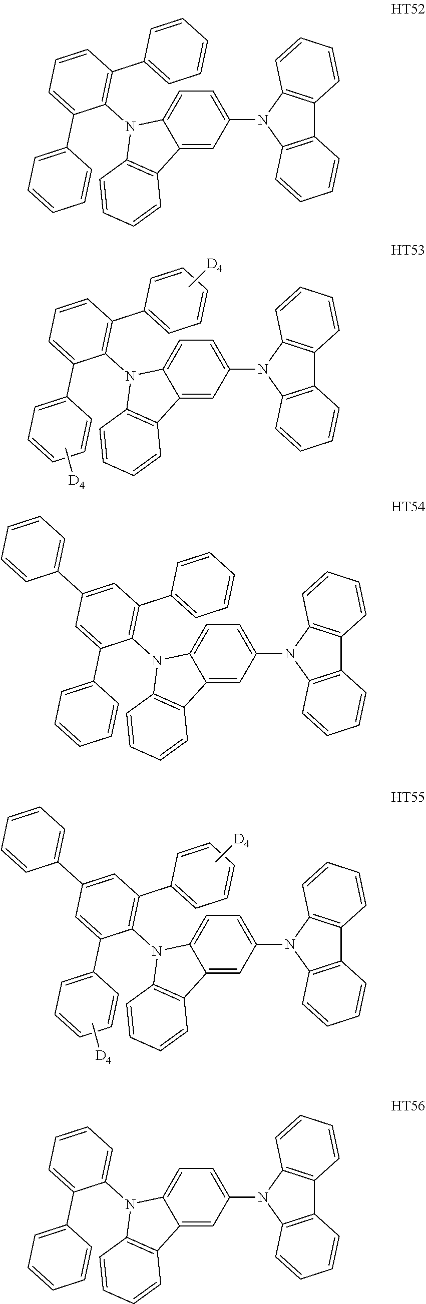

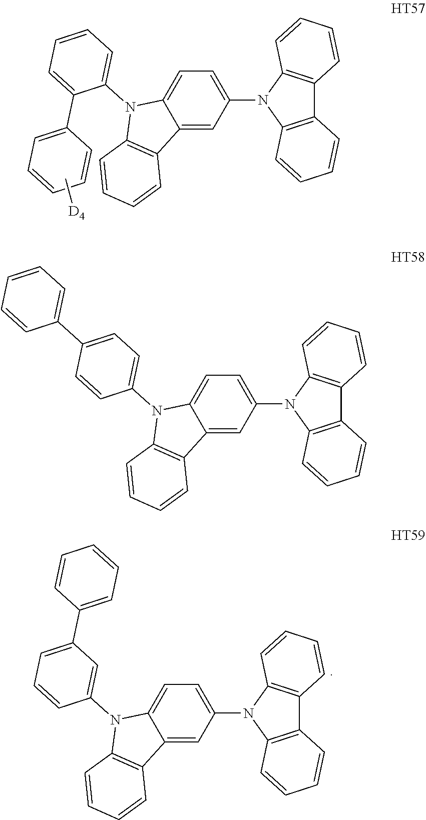

In an embodiment, the third compound represented by Formula ET may be selected from Compound Group ET. In an embodiment, in the light emitting device ED, the third compound may include at least one compound selected from Compound Group ET. In Compound Group ET, D represents a deuterium atom.

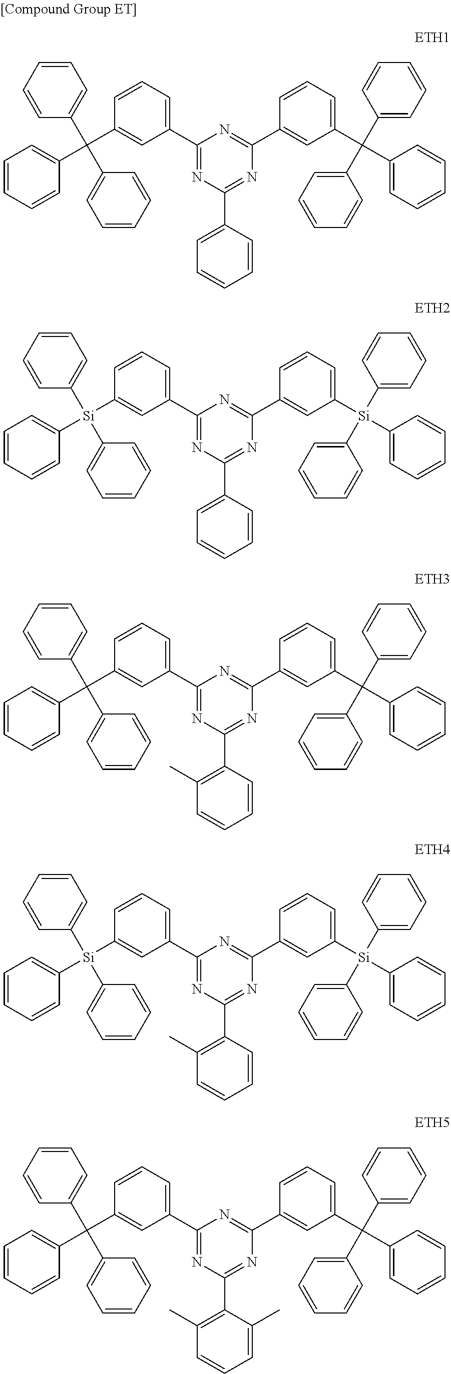

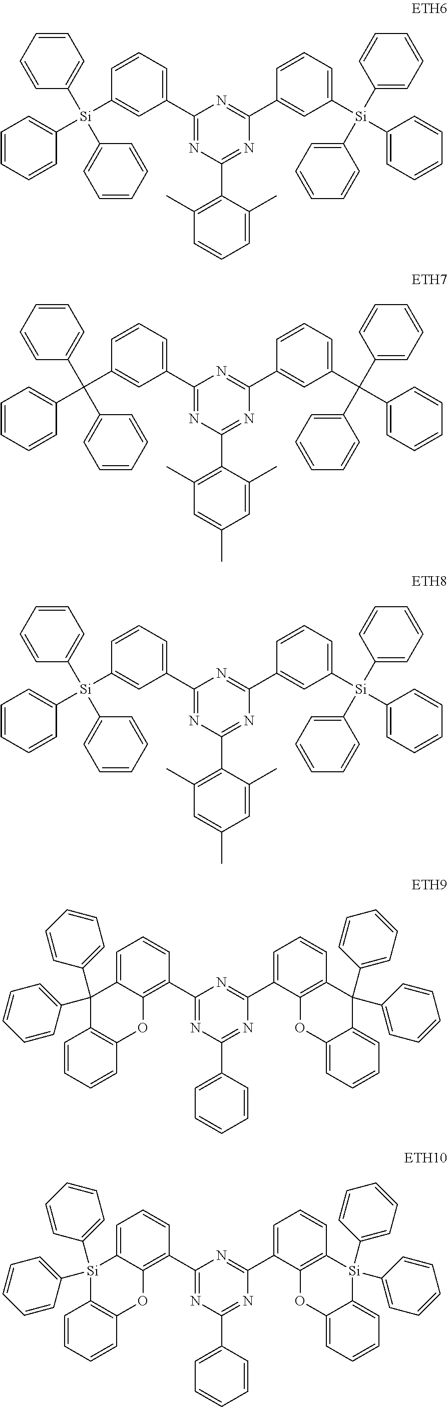

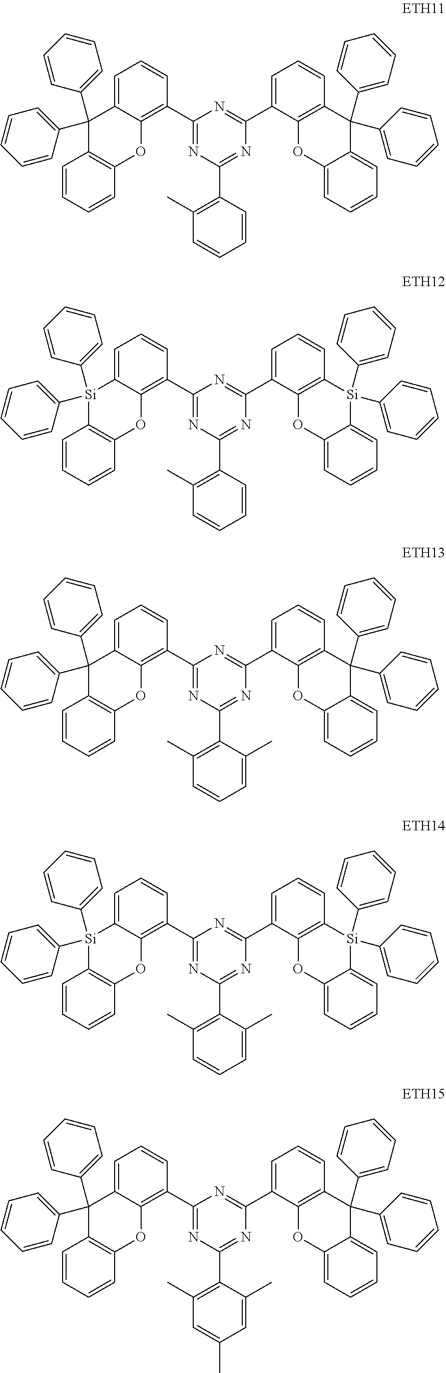

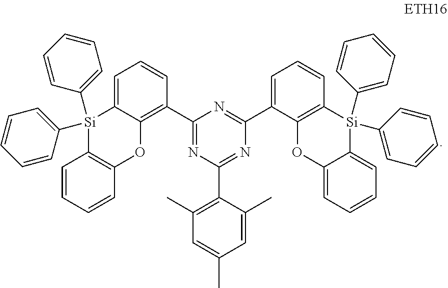 [SMILES: Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

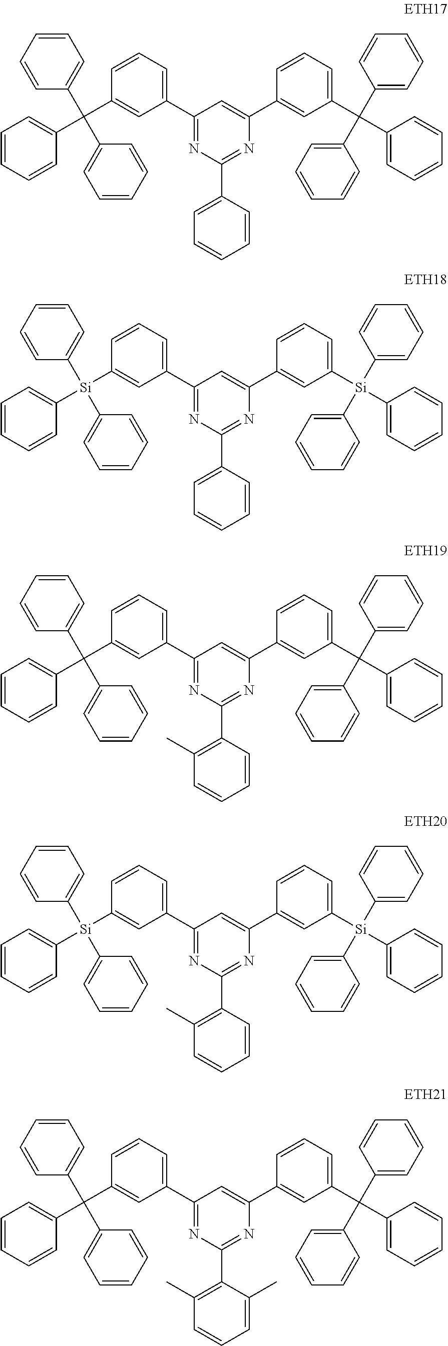

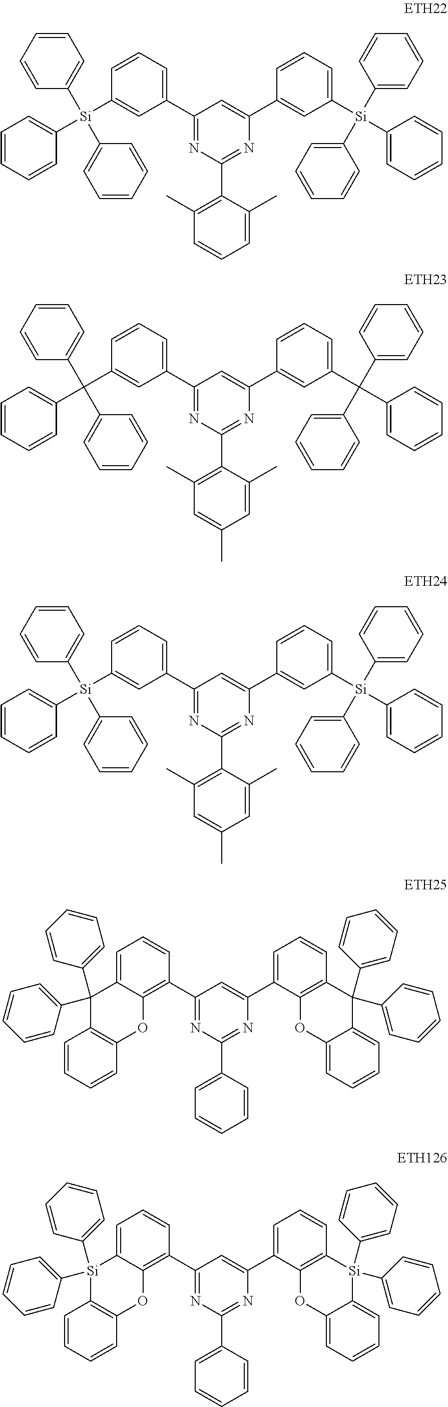

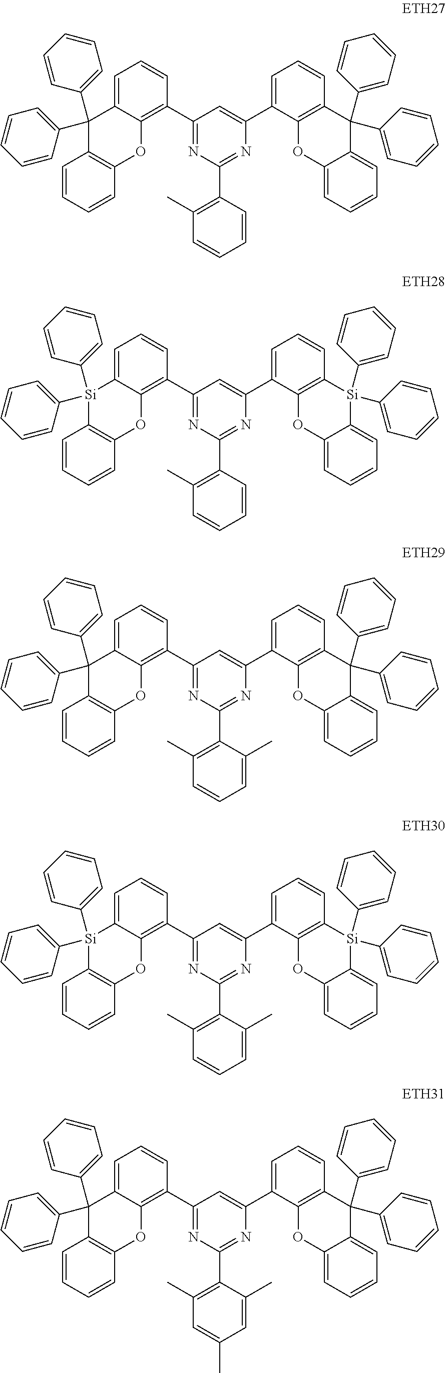

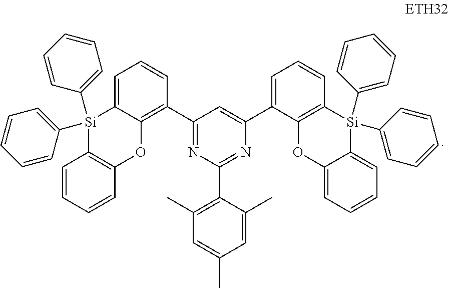 [SMILES: Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

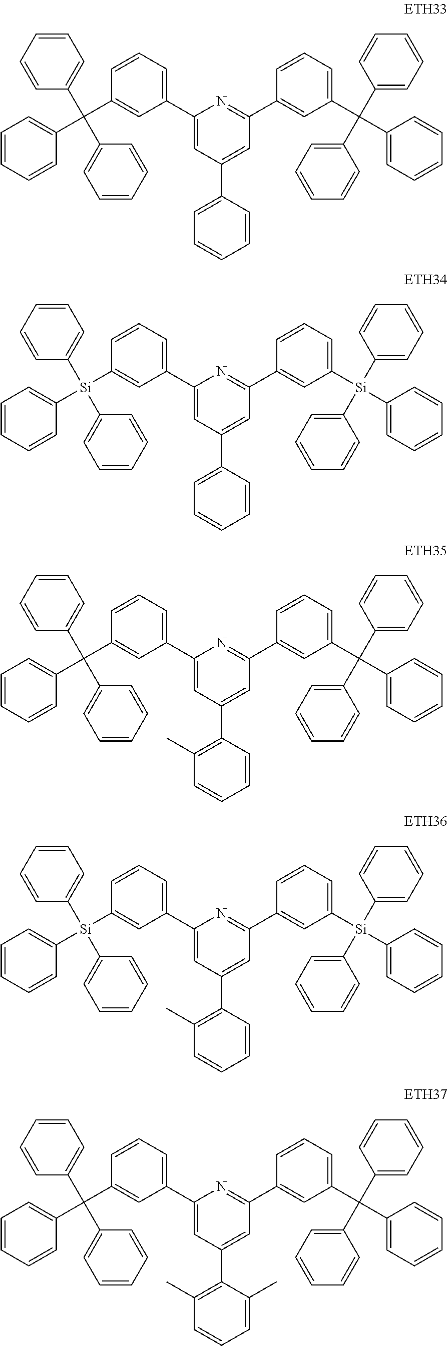

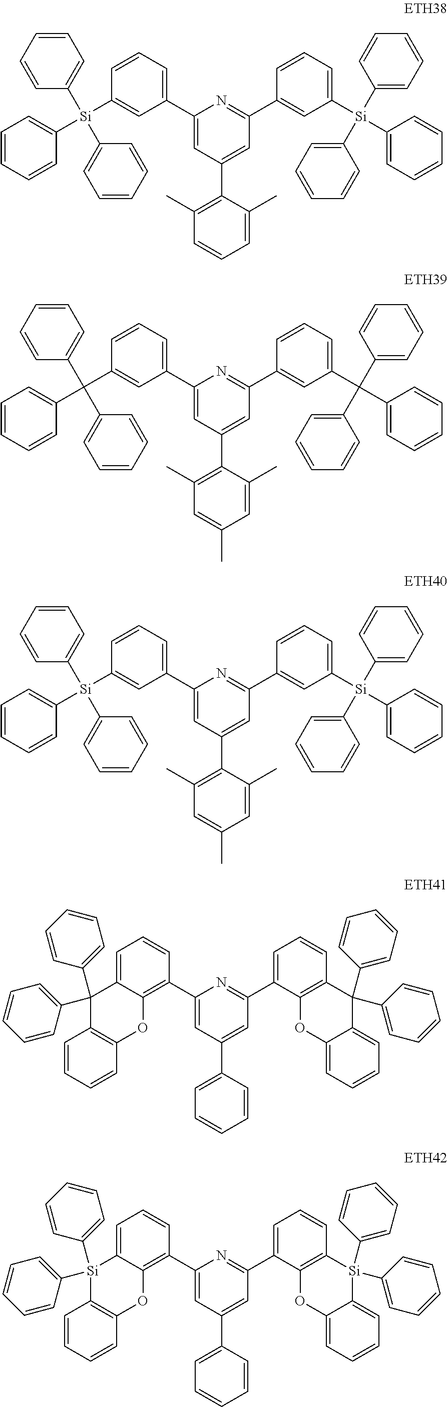

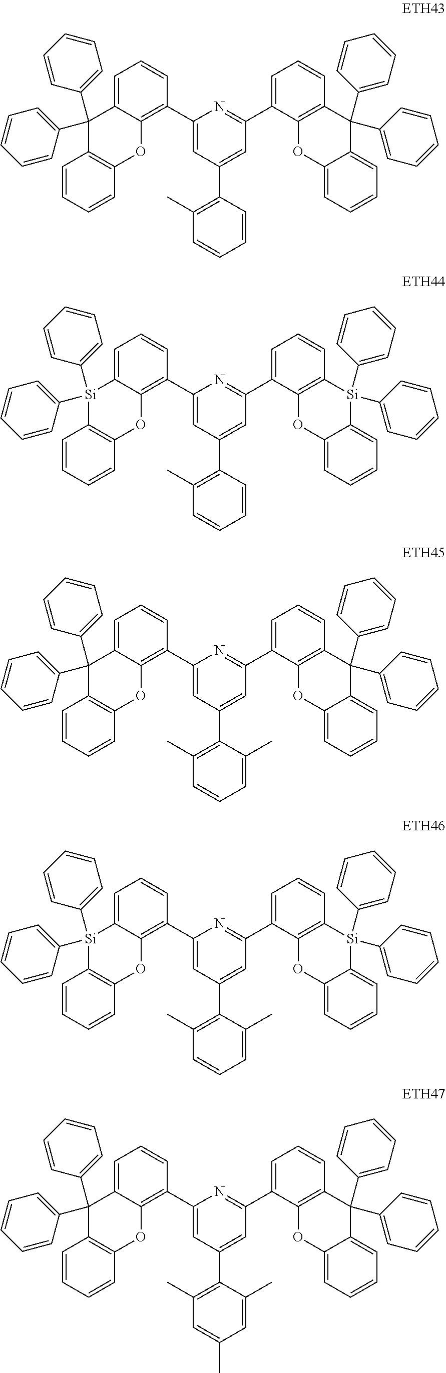

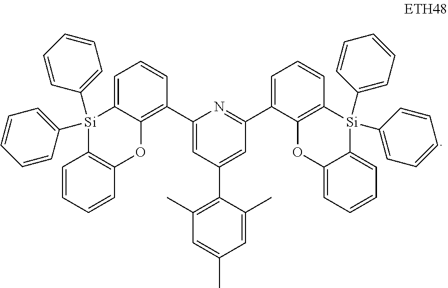 [SMILES: Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

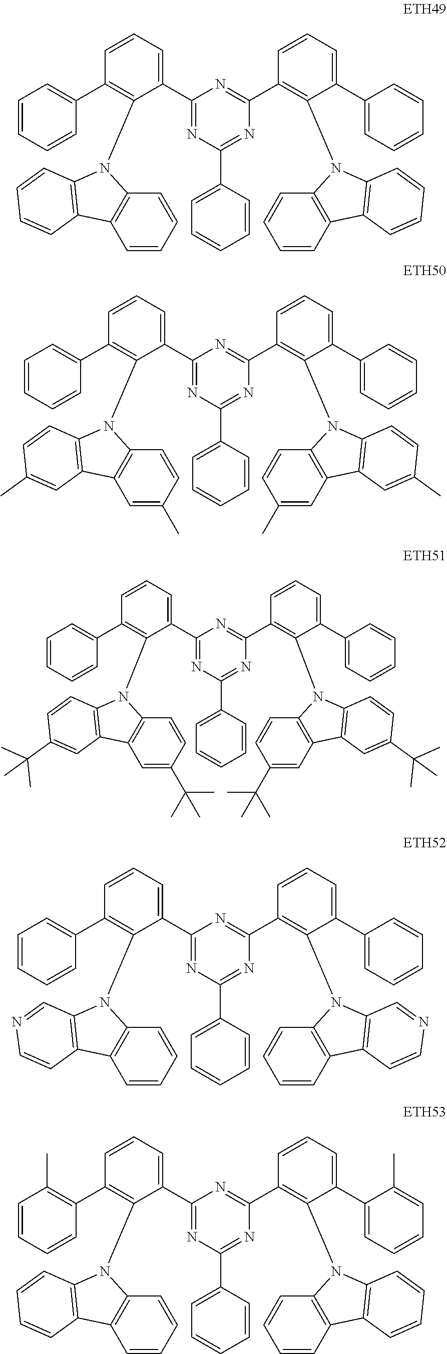

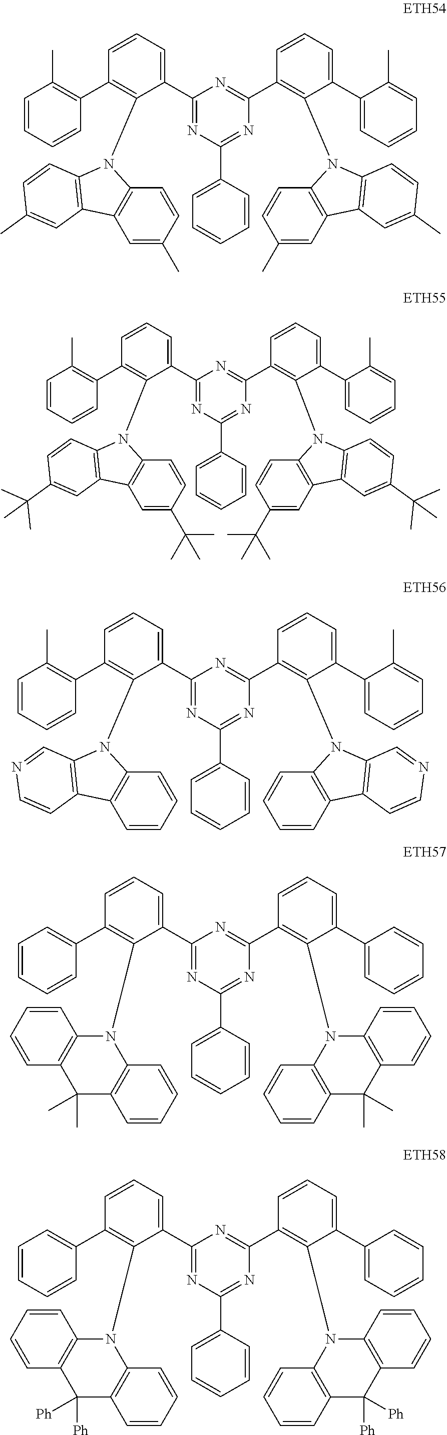

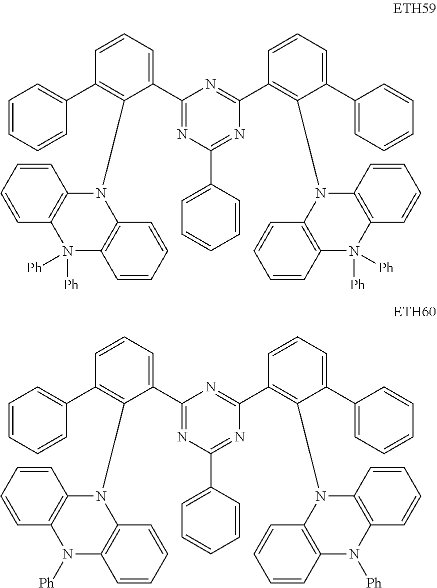

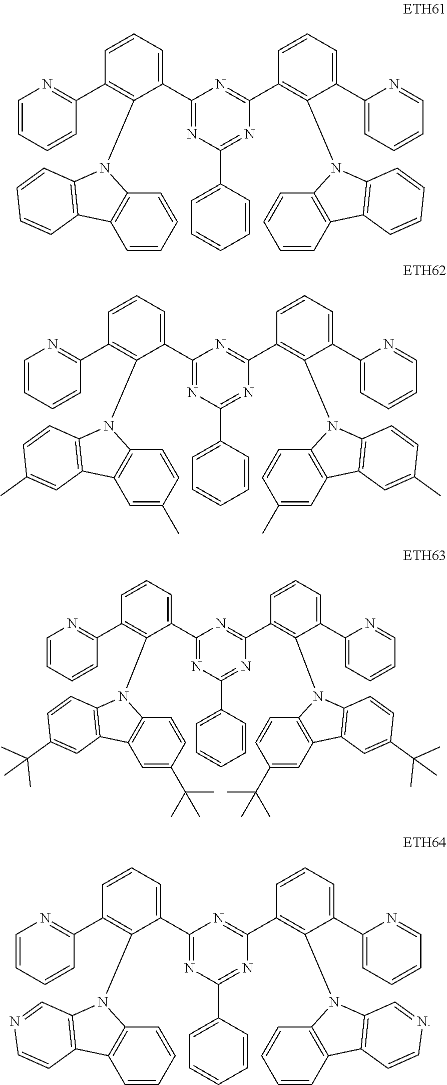

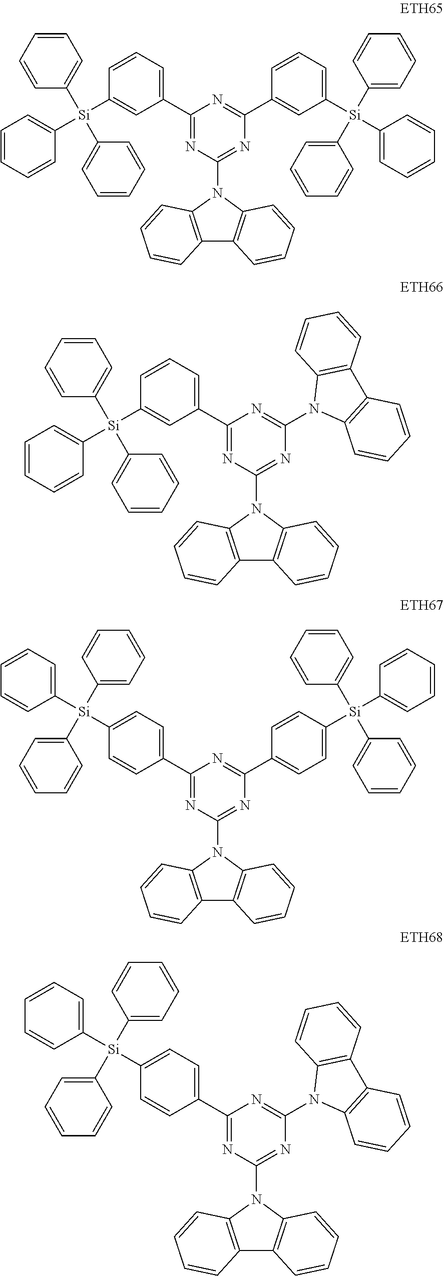

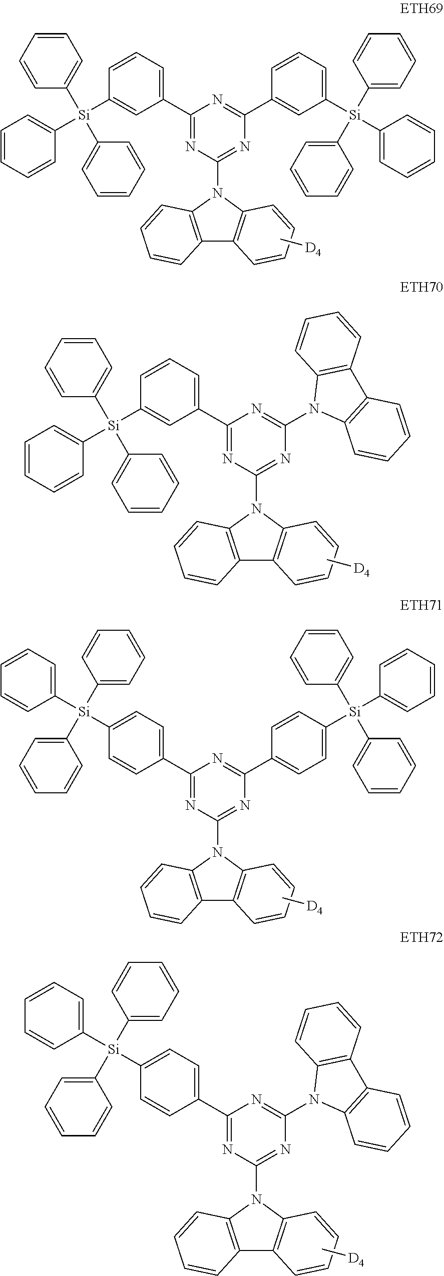

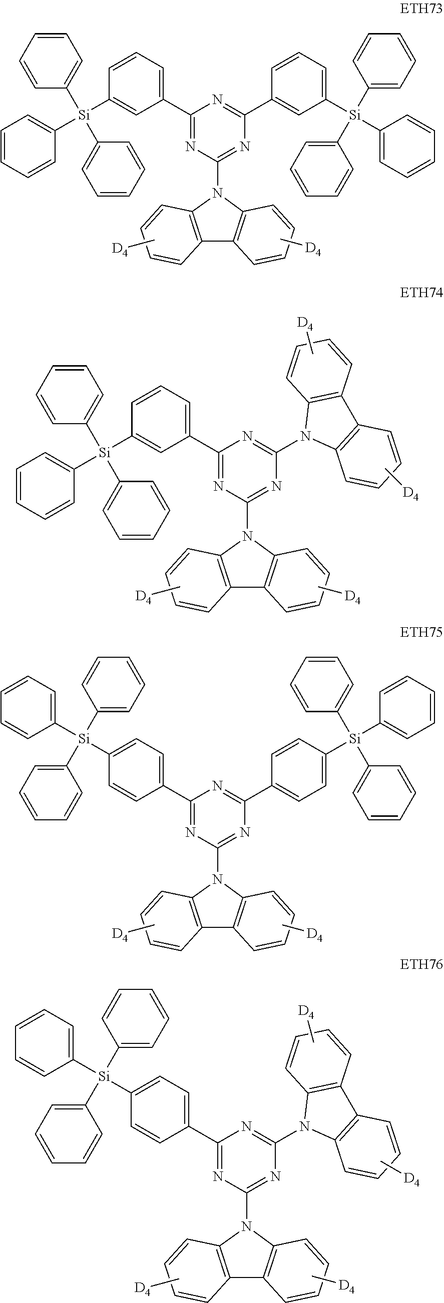

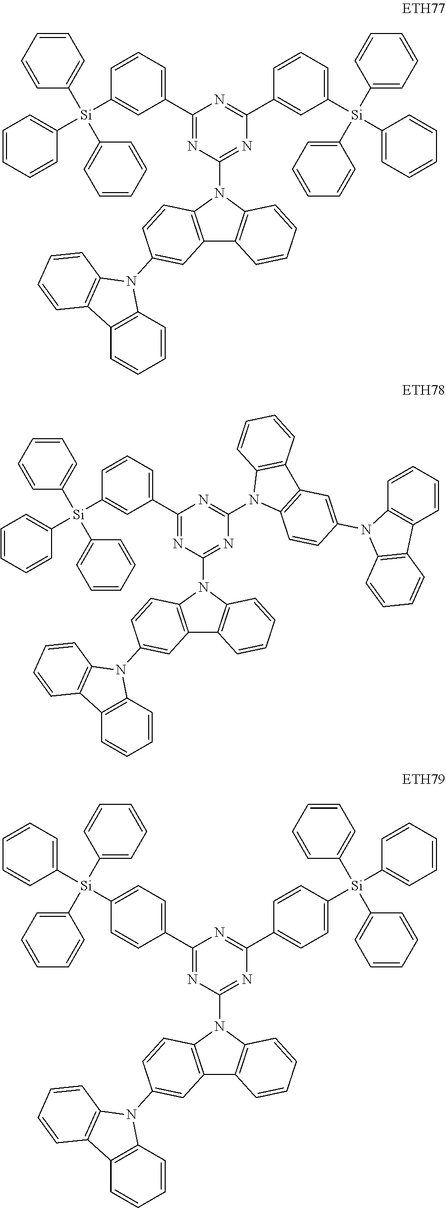 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

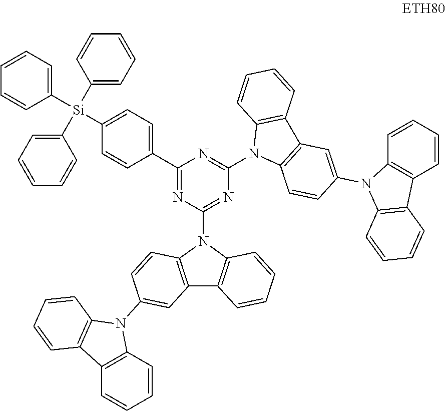 [SMILES: c1ccc([Si](c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1]

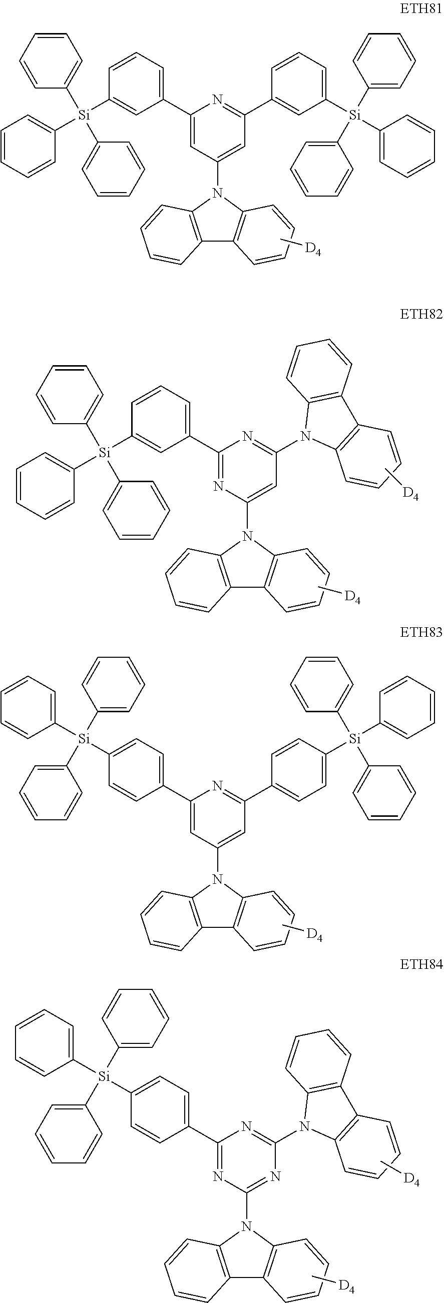

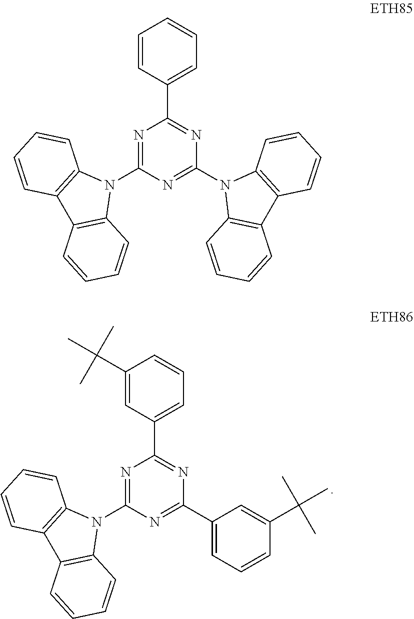 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In an embodiment, the fourth compound represented by Formula PS may be selected from Compound Group AD. In an embodiment, in the light emitting device ED, the fourth compound may include at least one compound selected from Compound Group AD.

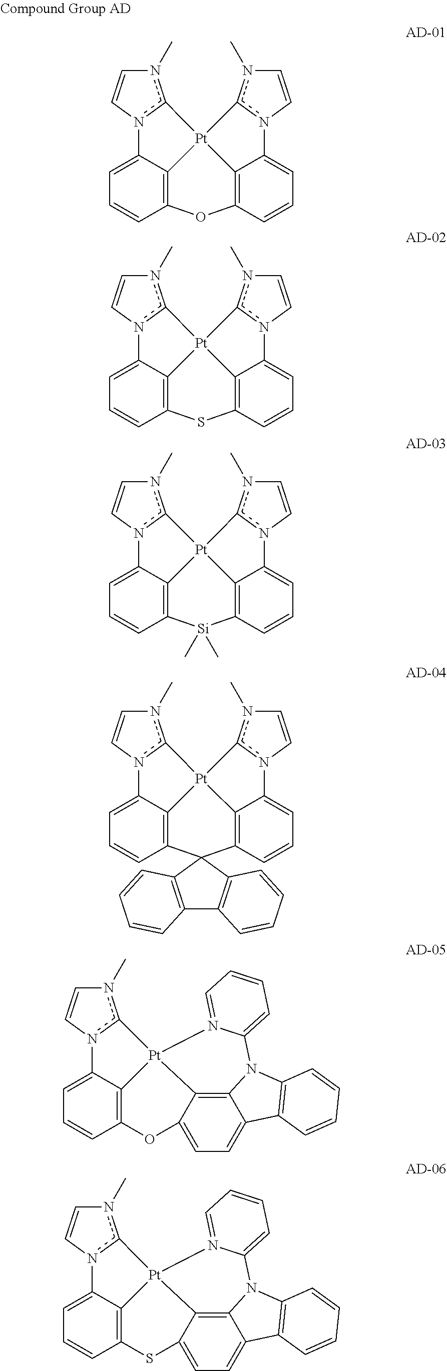

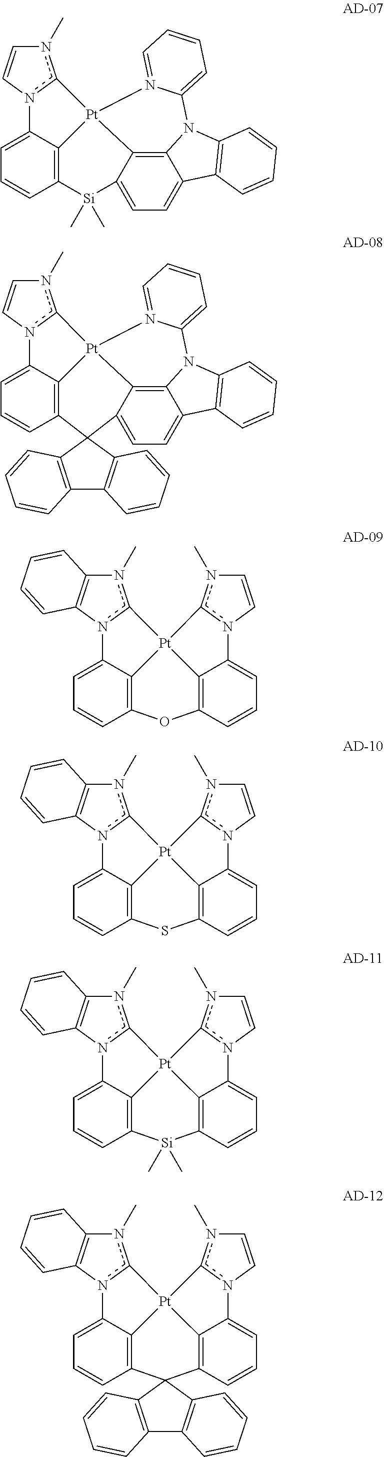

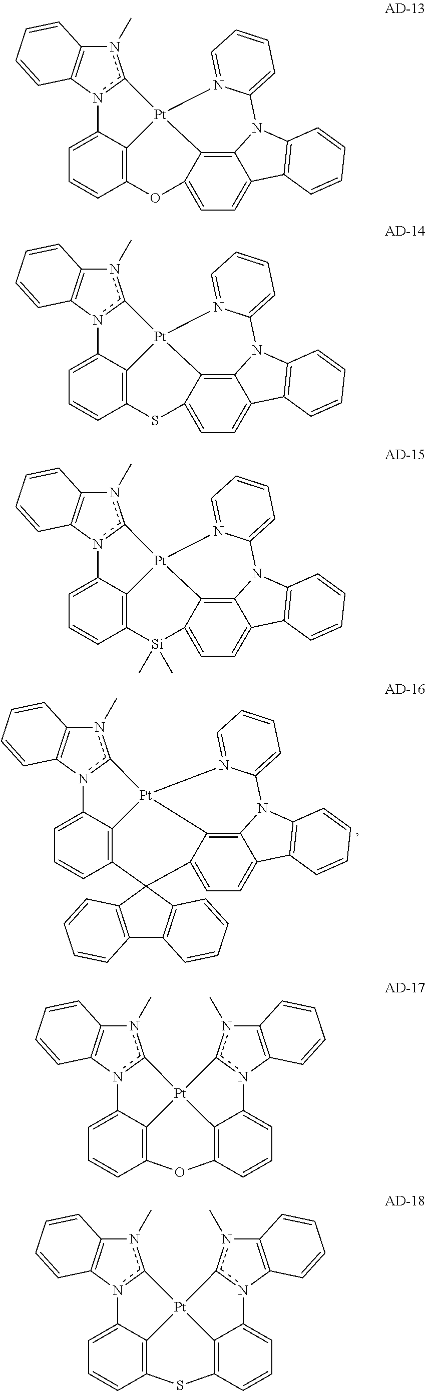

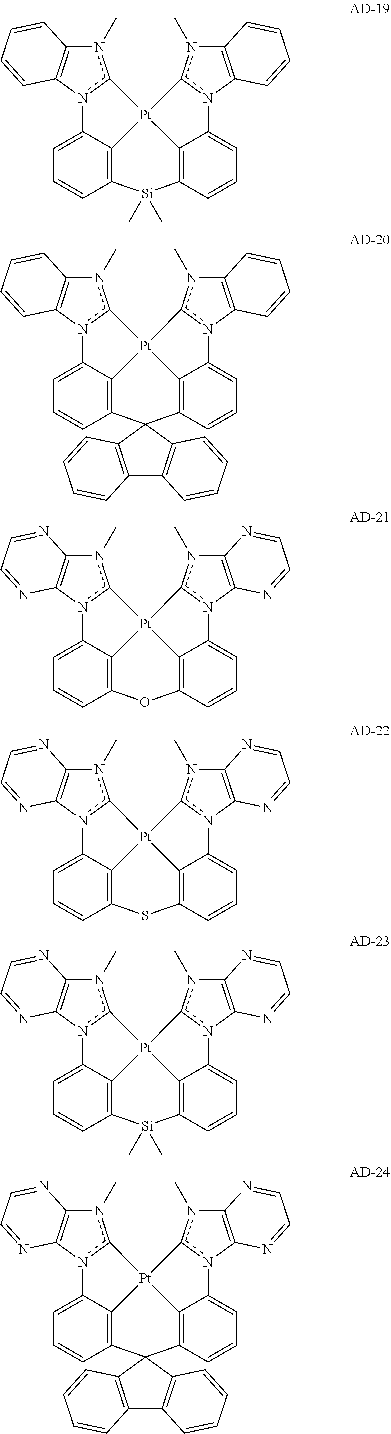

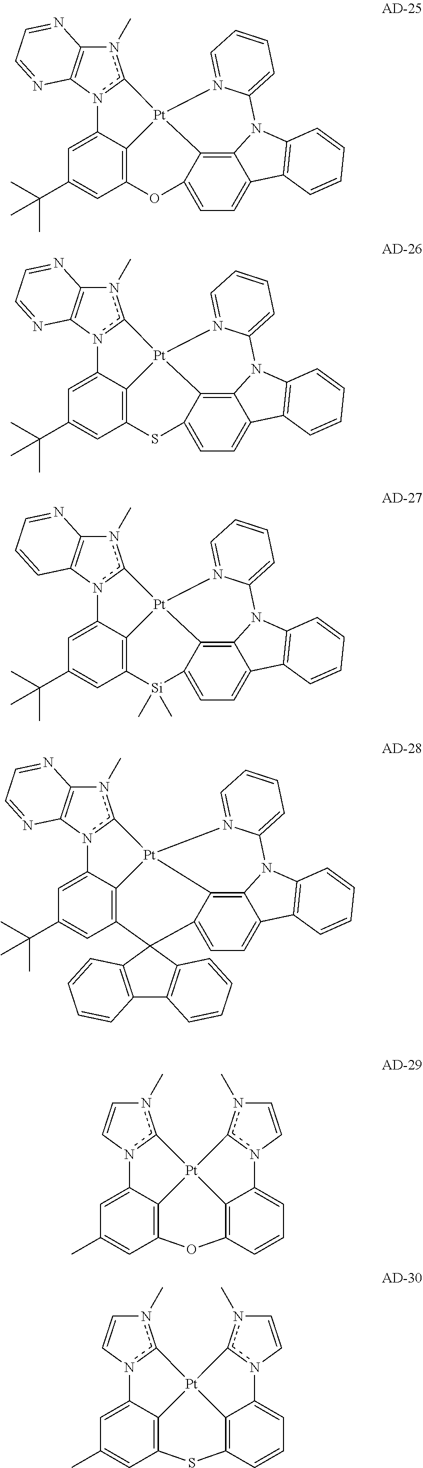

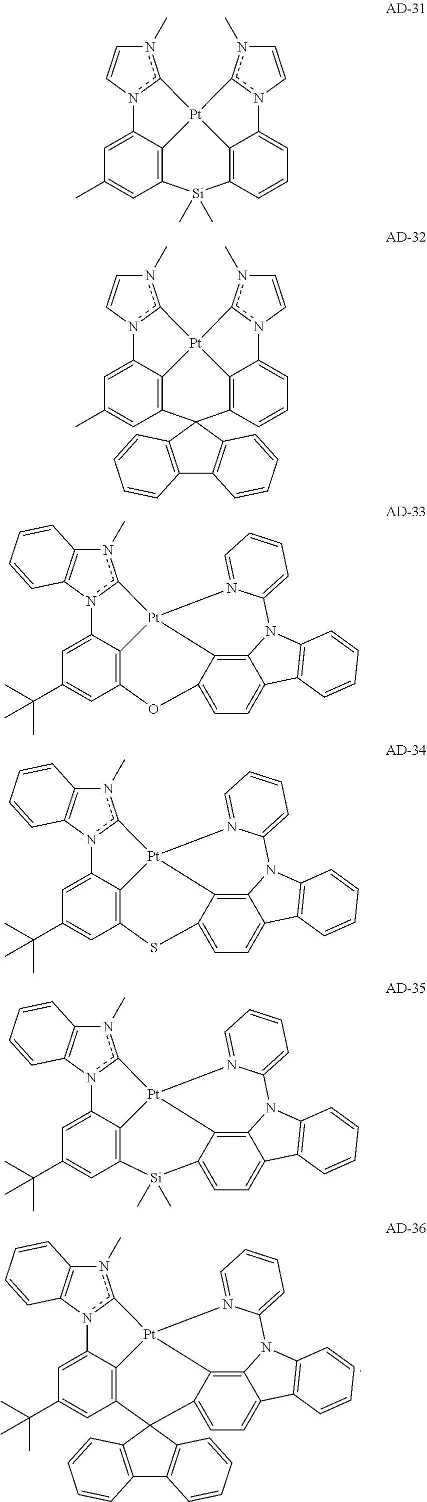

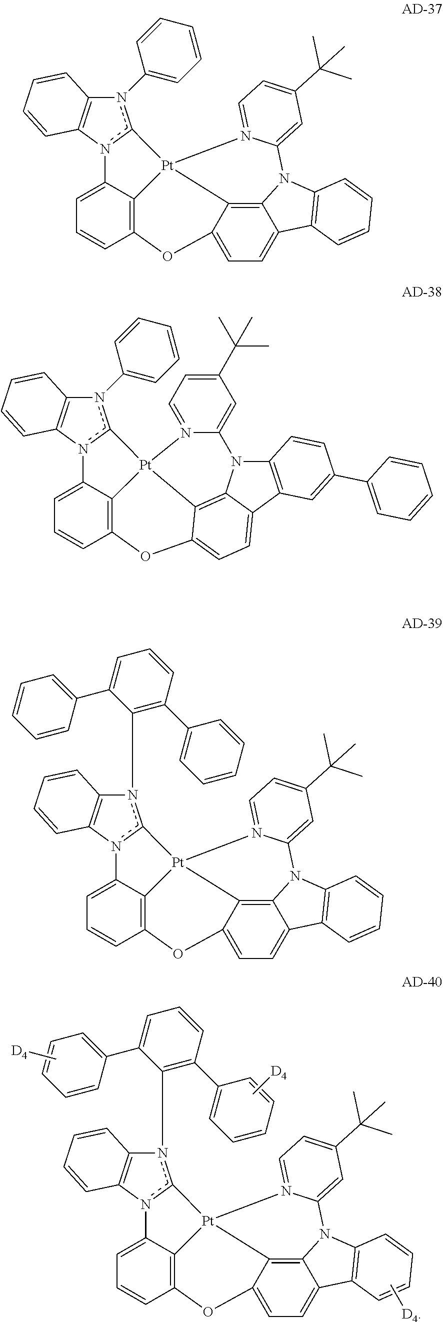

In an embodiment, the light emitting device ED may include multiple emission layers. The emission layers may be provided as a stack of emission layers, so that the light emitting device ED including multiple emission layers may emit white light. The light emitting device ED including multiple emission layers may be a light emitting device having a tandem structure. When the light emitting device ED includes multiple emission layers, at least one emission layer EML may include the first compound, the second compound, the third compound, and the fourth compound as described above.

In the light emitting device ED, the emission layer EML may further include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting device ED according to embodiments as illustrated in each of FIGS. 3 to 6, the emission layer EML may further include a host of the related art and a dopant of the related art, in addition to the above-described host and dopant. In an embodiment, the emission layer EML may include a compound represented by Formula E-1. The compound represented by Formula E-1 may be used as a fluorescent host material.

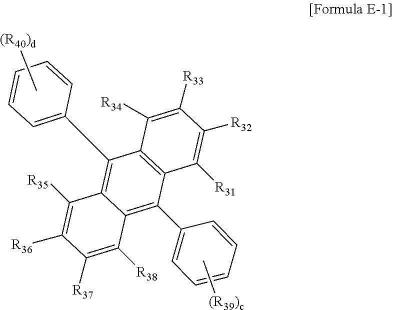

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, in Formula E-1, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19:

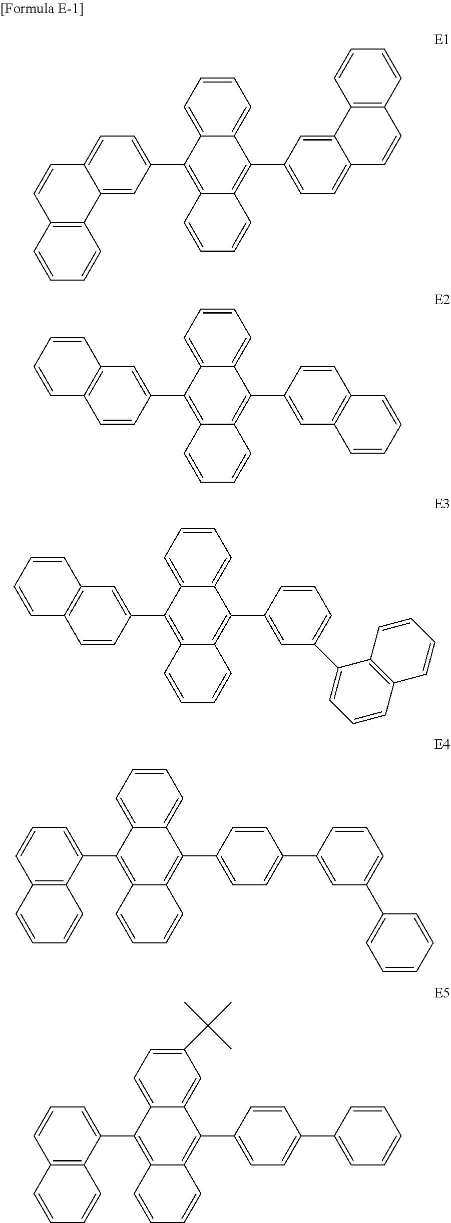

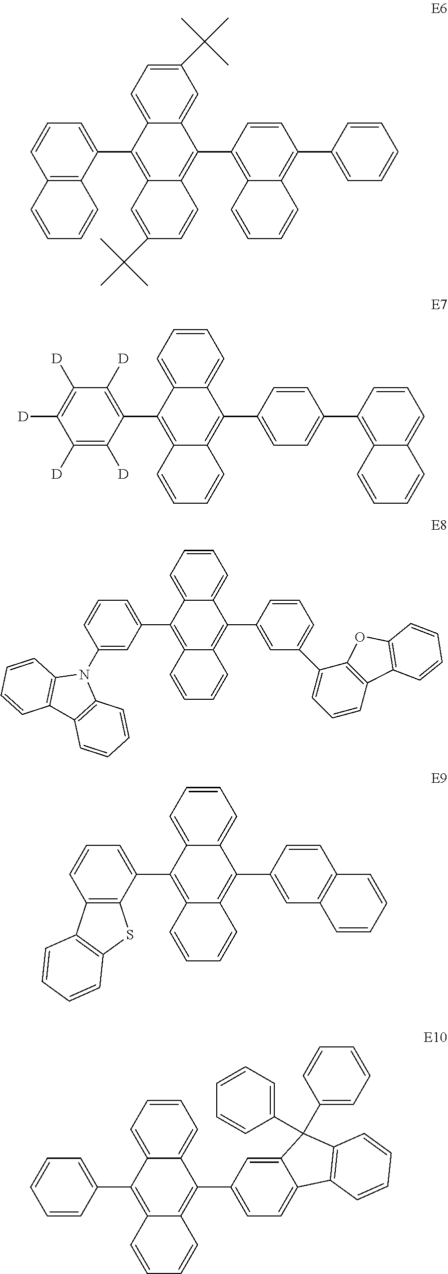

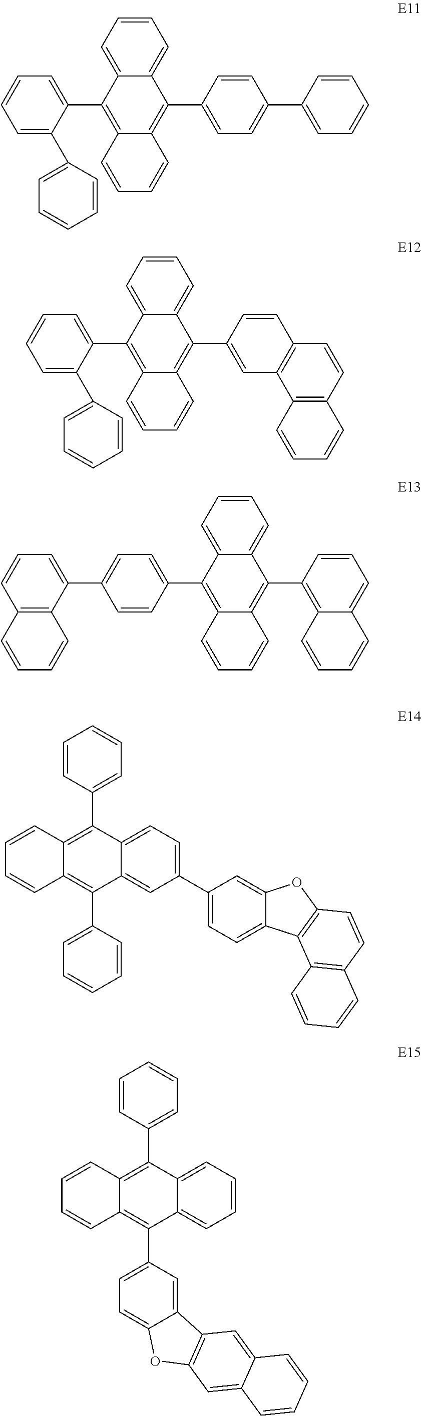

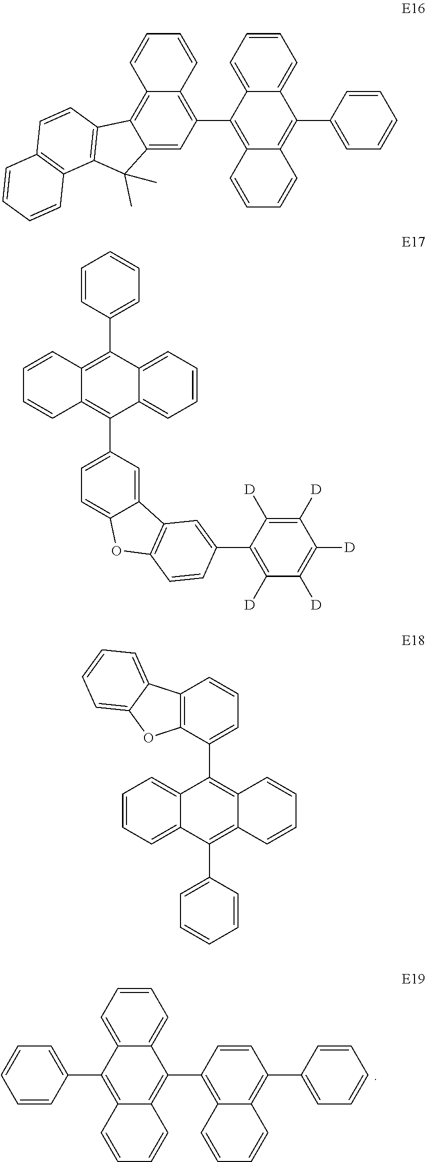

In an embodiment, the emission layer EML may include a compound represented by Formula E-2a or Formula E-2b. The compound represented by Formula E-2a or Formula E-2b may be used as a phosphorescent host material.

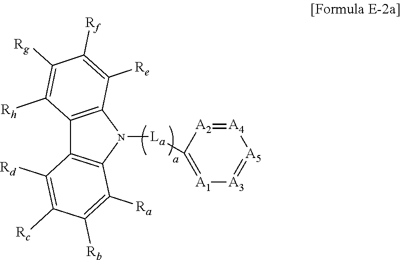

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

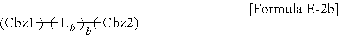

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

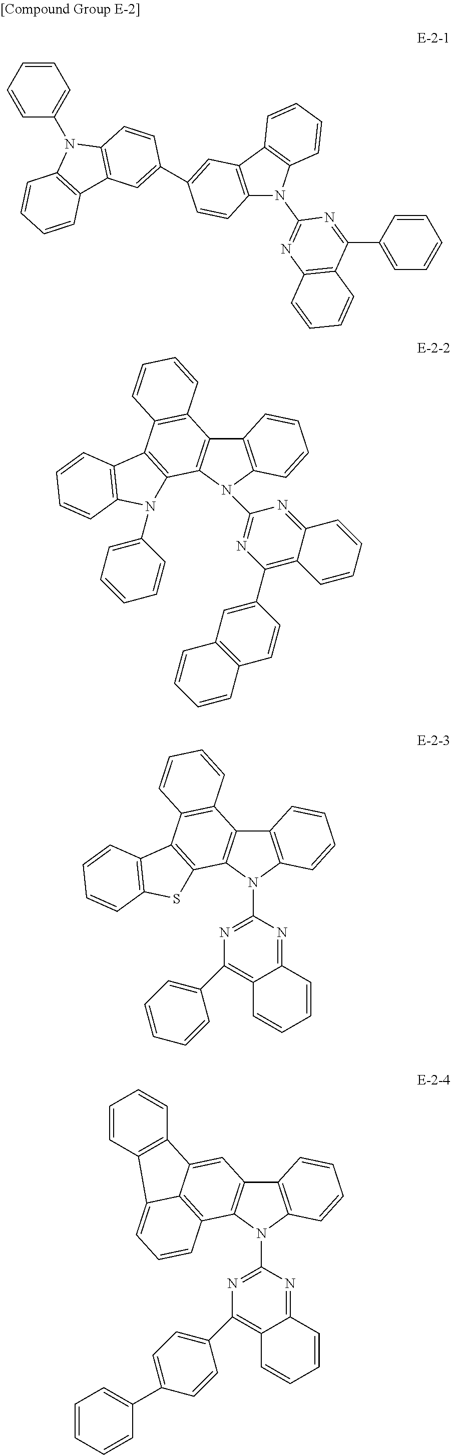

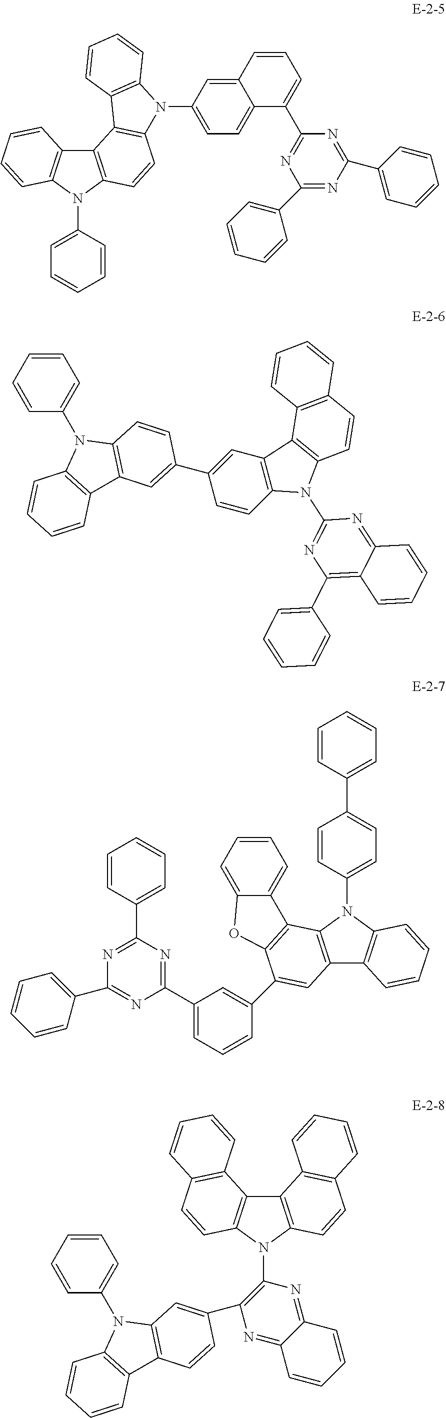 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

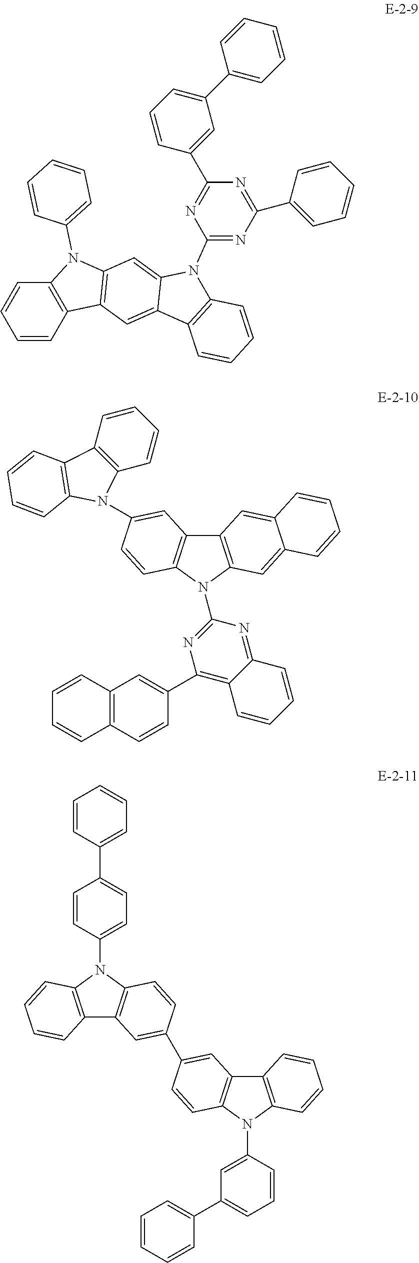 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

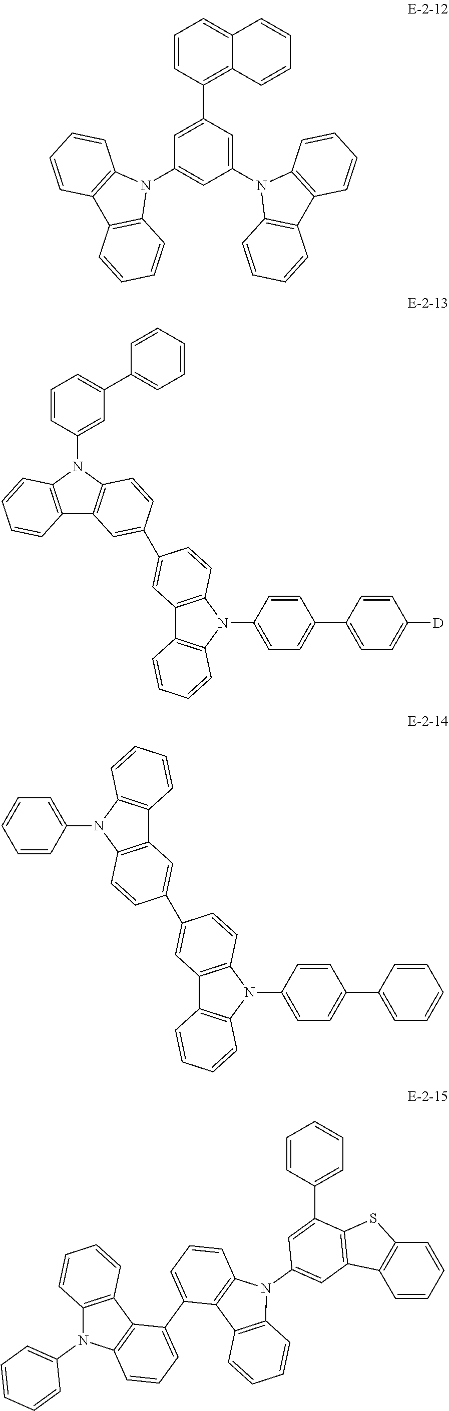 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

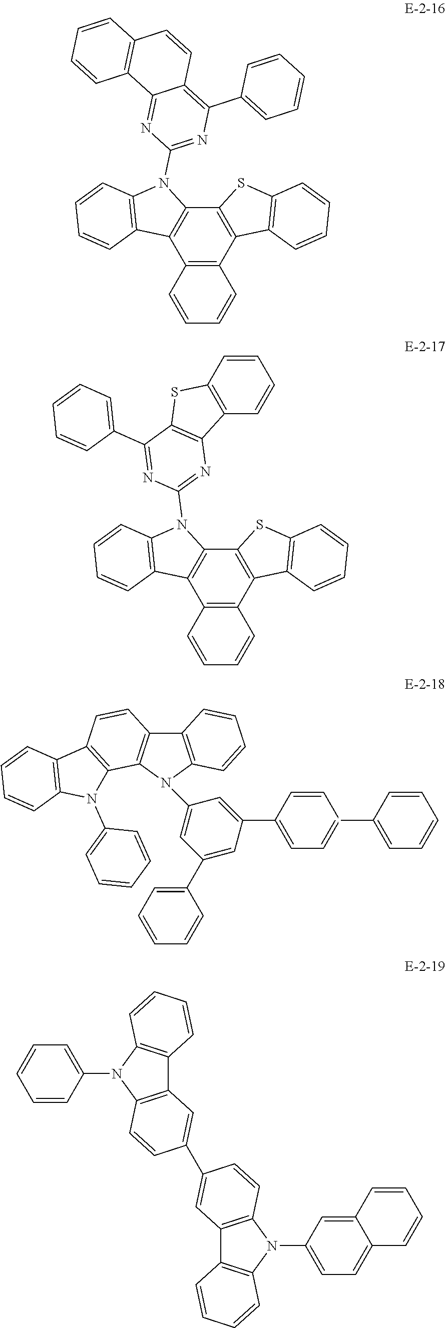

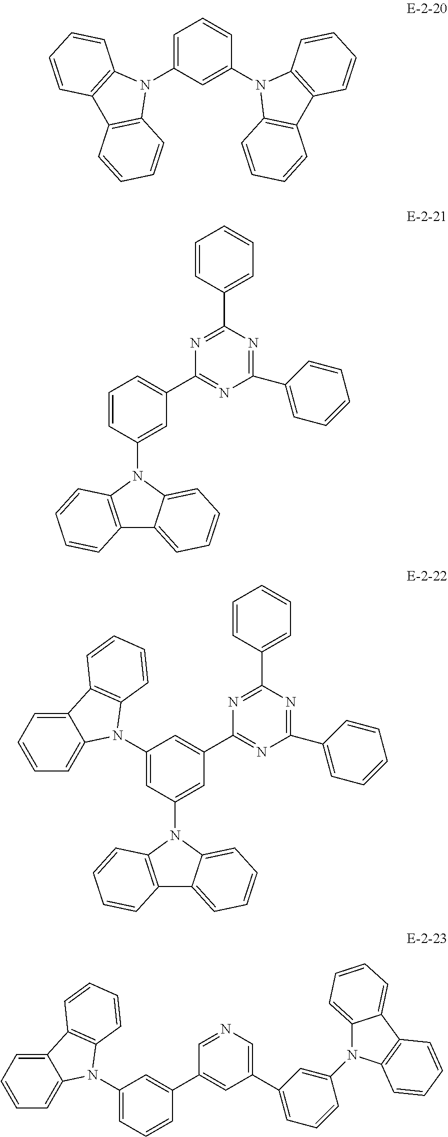 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

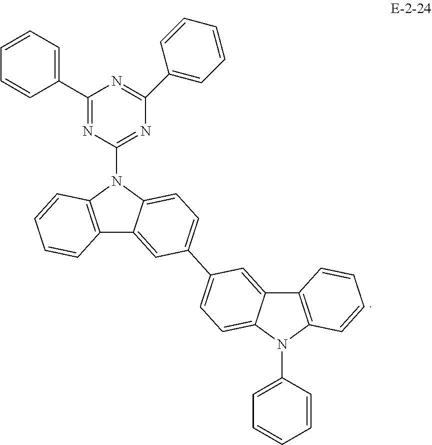 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

The emission layer EML may include a compound represented by Formula M-a. The compound represented by Formula M-a may be used as a phosphorescent dopant material.

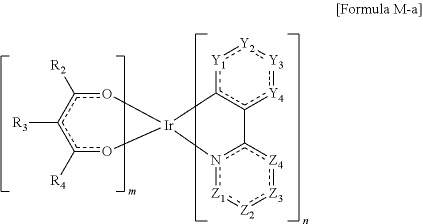

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

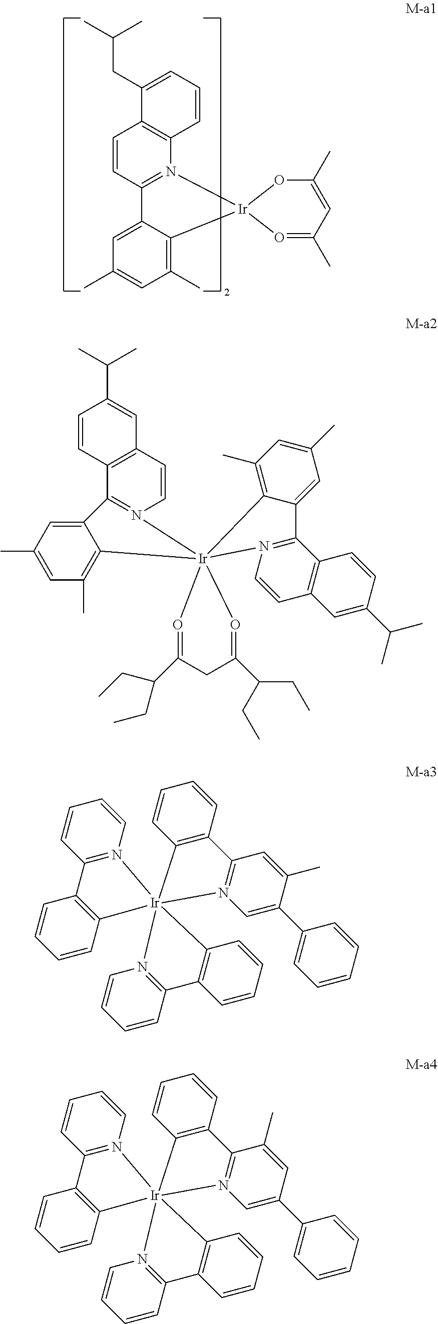

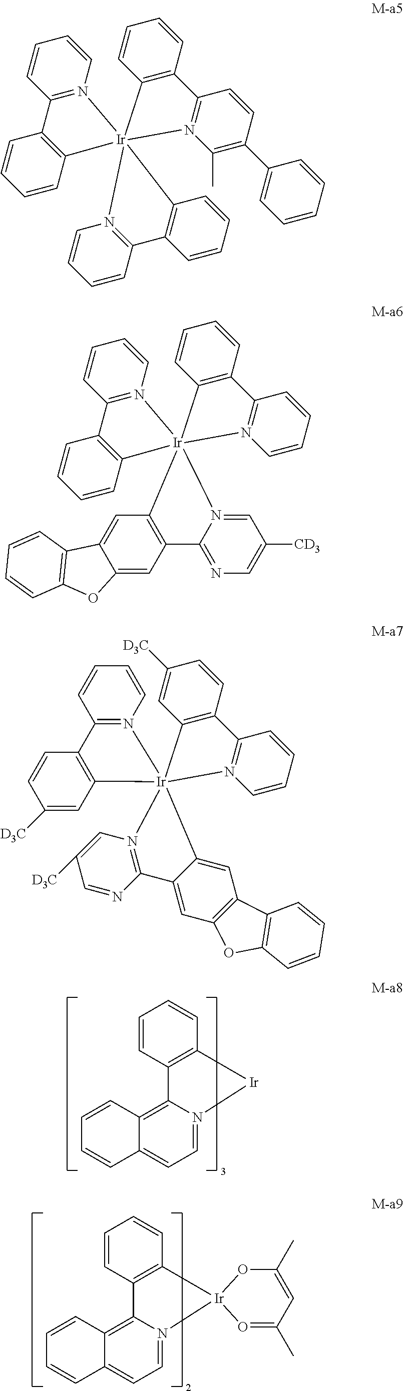

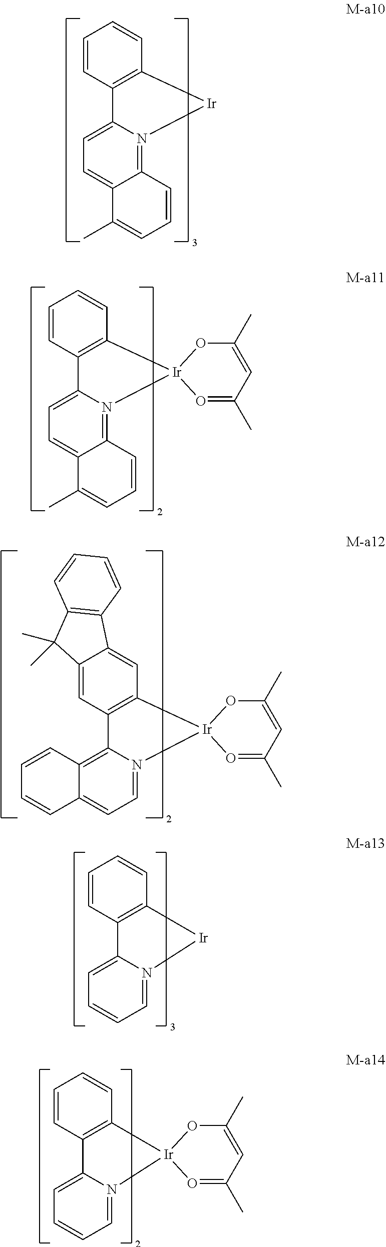

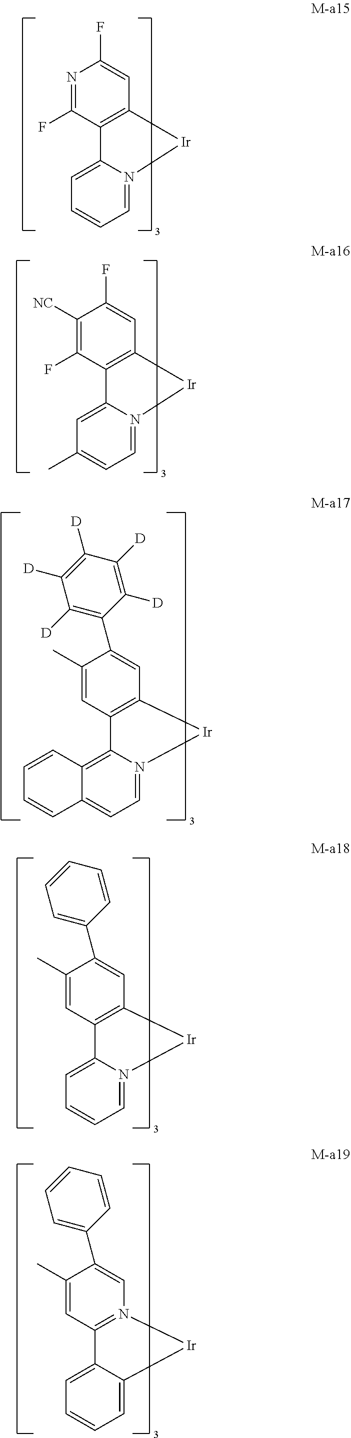

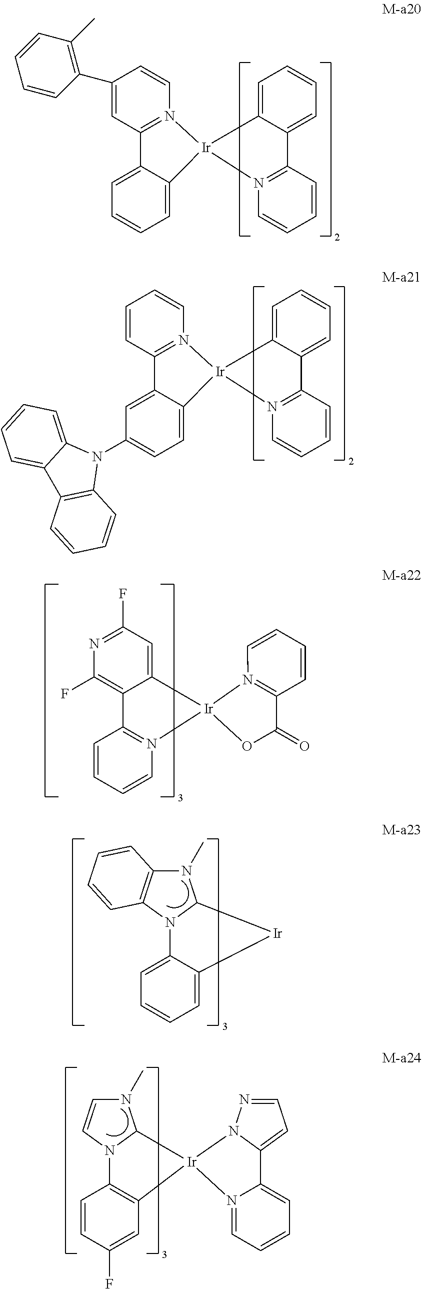

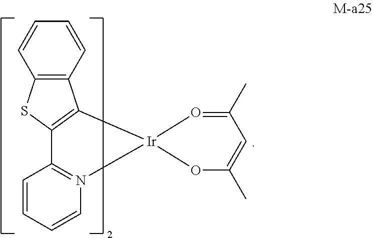

The emission layer EML may include a compound represented by any one of Formula F-a to Formula F-c. The compound represented by one of Formula F-a to Formula F-c may be used as a fluorescence dopant material.

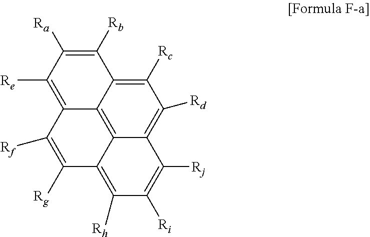

In Formula F-a, two of Rₐ to Rⱼ may each independently be substituted with a group represented by

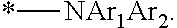

The remainder of Rₐ to Rⱼ which are not substituted with the group represented by

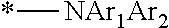

may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by

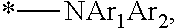

Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ or Ar₂ may each independently be a heteroaryl group containing O or S as a ring-forming atom.

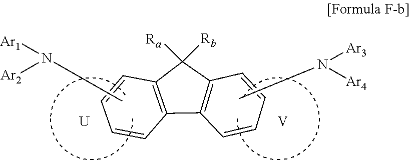

In Formula F-b, Rₐ and Rₑ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be respectively present at a portion indicated by U or V. When the number of U or V is 0, a fused ring may not be present at the portion indicated by U or V does not exist. When the number of U is 0 and the number of V is 1, or when the number of U is 1 and the number of V is 0, a fused ring having a fluorene core of Formula F-b may be a cyclic compound having four rings. When the number of U and V is each 0, a fused ring having a fluorene core of Formula F-b may be a cyclic compound having three rings. When the number of U and V is each 1, a fused ring having a fluorene core of Formula F-b may be a cyclic compound having five rings.

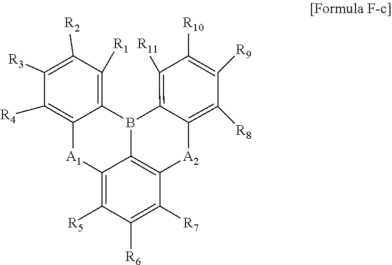

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc.

The emission layer EML may include a phosphorescent dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

The emission layer EML may include a quantum dot material. In the specification, a quantum dot may be a crystal of a semiconductor compound. The quantum dot may emit light having various emission wavelengths depending on a size of crystal. The quantum dot may emit light having various emission wavelengths as the ratio of elements in the quantum dot compound is adjusted.

The quantum dot may be a Group II-VI compound, a Group III-VI compound, a Group 1-III-VI compound, a Group III-V compound, a Group III—II-V compound, a Group IV-VI compound, a Group IV element, a Group IV compound, or a combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof; or any combination thereof.

Examples of a Group III-VI compound may include: a binary compound such as In₂S₃ or In₂Se₃; a ternary compound such as InGaS₃ or InGaSe₃; or any combination thereof.

Examples of a Group I-III-VI compound may include: a ternary compound selected from the group consisting of AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂ or CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; or any combination thereof. In an embodiment, a Group III-V compound may further include a Group II element. For example, InZnP, etc., may be selected as a Group III-II-V compound.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof.

Examples of a Group IV element may include Si, Ge, and a mixture thereof. Examples of a Group IV compound may include a binary compound selected from the group consisting of SiC, SiGe, and a mixture thereof.

Examples of a Group IV element or compound may include: a single element material such as Si or Ge; a binary compound such as SiC or SiGe; or any combination thereof.

Each element included in a binary compound, a ternary compound, or a quaternary compound may be present in a particle at a uniform concentration distribution or at a non-uniform concentration distribution. For example, a formula of a binary compound, a ternary compound, or a quaternary compound may describe the elements included in the compound, wherein the elemental ratio of the compound may be different. For example, AgInGaS₂ may be interpreted as AgInₓGa₁₋ₓS₂ (wherein x is a real number from 0 to 1).

In an embodiment, a quantum dot may have a single structure in which the concentration of each element included in the quantum dot may be uniform.

In another embodiment, a quantum dot may have a core-shell structure in which one quantum dot surrounds another quantum dot. For example, a material included in the core may be different from a material included in the shell.

The shell of a quantum dot may serve as a protection layer to prevent the chemical deformation of the core to maintain semiconductor properties, and/or may serve as a charging layer to impart electrophoresis properties to the quantum dot. The shell may be a single layer or multiple layers. A quantum dot having a core/shell structure may have a concentration gradient in which the concentration of a material that is present in the shell decreases toward the core.

Examples of a shell of a quantum dot may include a metal oxide, a non-metal oxide, a semiconductor compound, or a combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; or any combination thereof.

Examples of a semiconductor compound may include a Group III-VI semiconductor compound; a Group II-VI semiconductor compound; a Group III-V semiconductor compound; a Group I-III-VI semiconductor compound; a Group IV-VI semiconductor compound; or any combination thereof, as described herein. Examples of a semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in any of the above ranges. Light emitted through such a quantum dot may be emitted in all directions, so that a wide viewing angle may be improved.

The form of the quantum dot is not particularly limited, as long as it is a form used in the related art. For example, the quantum dot may have a spherical shape, a pyramidal shape, a multi-arm shape, or a cubic shape, or the quantum dot may be in the form of nanoparticles, nanotubes, nanowires, nanofibers, nanoplate particles, etc.

As the size of the quantum dot is adjusted or the elemental ratio in the quantum dot is adjusted, it is possible to control an energy band gap, so that light of various wavelength ranges may be obtained from a quantum dot emission layer. Therefore, the quantum dot as described above, which uses different sizes of quantum dots or different elemental ratios in the quantum dot may be implemented in the light emitting device, so that light of various wavelengths may be emitted. For example, the size of the quantum dot or the elemental ratio of the quantum dot may be adjusted to emit red light, green light, and/or blue light. In an embodiment, quantum dots may be configured to emit white light by combining various colors of light. A diameter of the quantum dot may be in a range of about 1 nm to about 10 nm.

The quantum dot may be synthesized by a wet chemical process, a metal organic chemical vapor deposition process, a molecular beam epitaxy process, a similar process thereto, or the like.

The wet chemical process is a method in which a precursor material is mixed with an organic solvent to grow quantum dot particle crystals. When the crystals grow, the organic solvent naturally may serve as a dispersant coordinated on the surface of the quantum dot crystals and may control the growth of the crystals. Thus, the wet chemical process may control the growth of quantum dot particles through a process which may be more readily performed than vapor deposition methods, such as metal organic chemical vapor deposition (MOCVD) or molecular beam epitaxy (MBE), and which is performed at a low cost.

In the light emitting devices ED according to an embodiment as illustrated in each of FIGS. 3 to 6, the electron transport region ETR may be provided on the emission layer EML. The electron transport region ETR may include at least one of a hole blocking layer HBL, an electron transport layer ETL, or an electron injection layer EIL. However, embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single-layered structure formed of different materials, or may have a structure in which an electron transport layer ETL/electron injection layer EIL, or a hole blocking layer HBL/electron transport layer ETL/electron injection layer EIL are stacked in its respective stated order from an emission layer EML, but embodiments are not limited thereto. The electron transport region ETR may have a thickness, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting device ED according to an embodiment, the electron transport region ETR may include a compound represented by Formula ET-1:

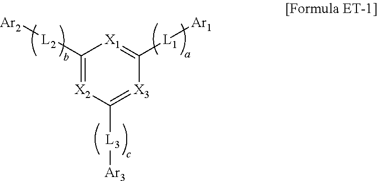

In Formula ET-1, at least one of X₁ to X₃ may each be N, and the remainder of X₁ to X₃ may each independently be C(Rₐ). In Formula ET-1, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-1, Ar₁ to Arₙ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), beryllium bis(benzoquinolin-10-olate) (Bebg₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one compound selected from Compound ET1 to Compound ET36:

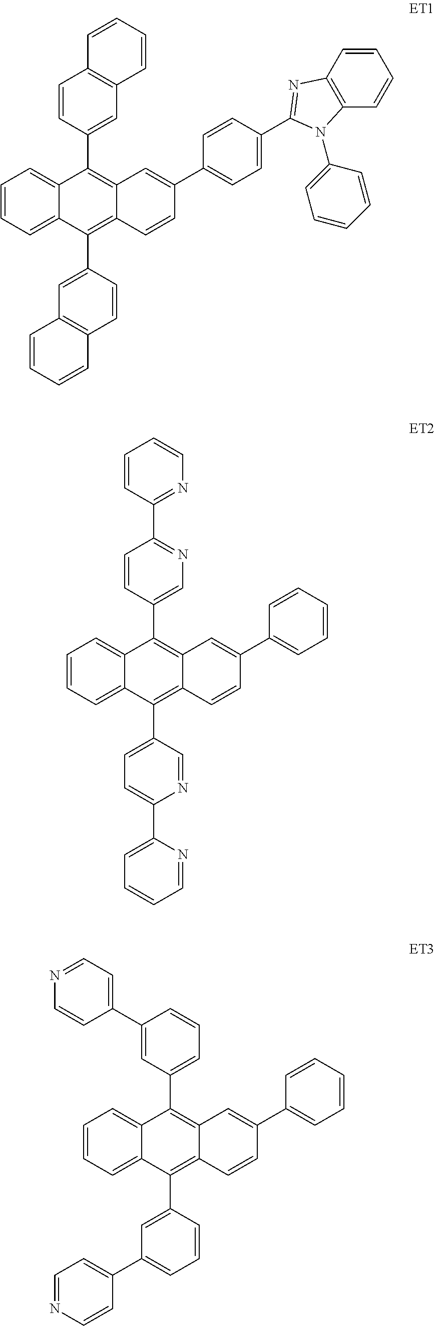 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

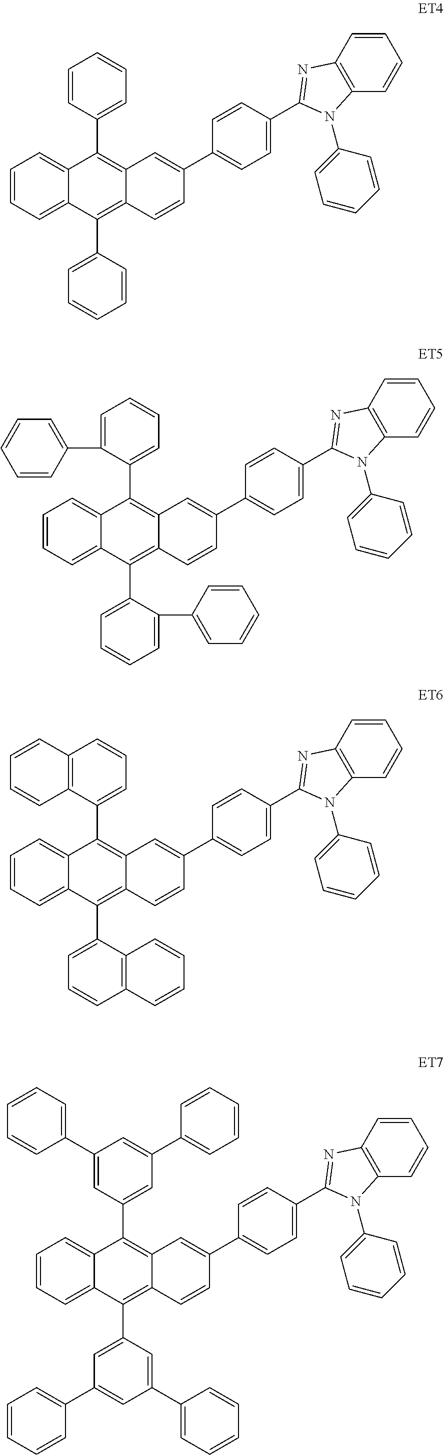 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

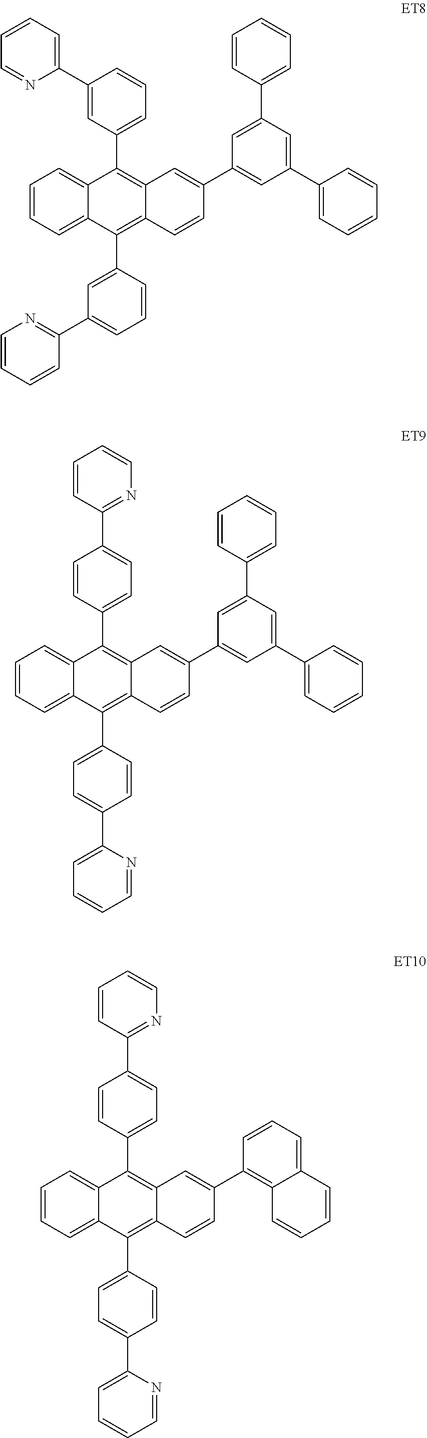 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

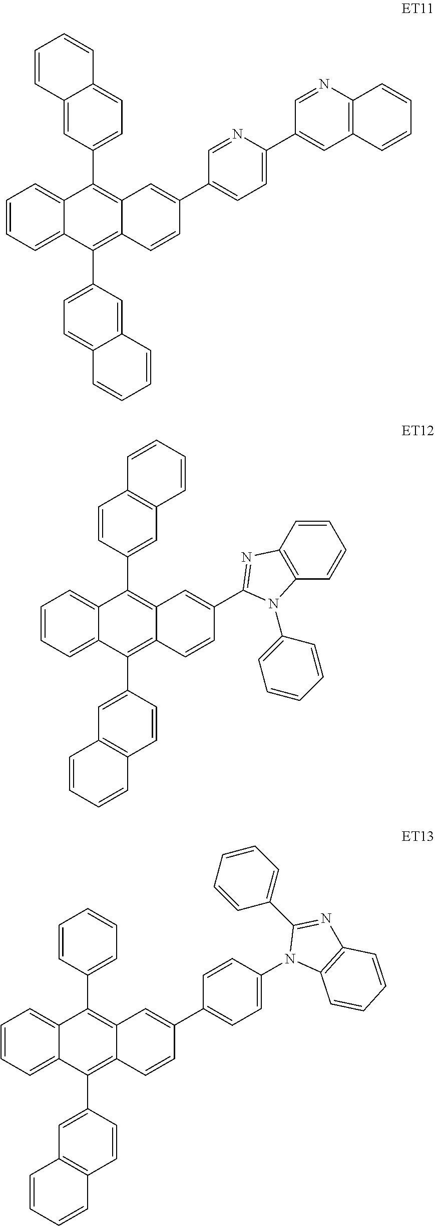 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

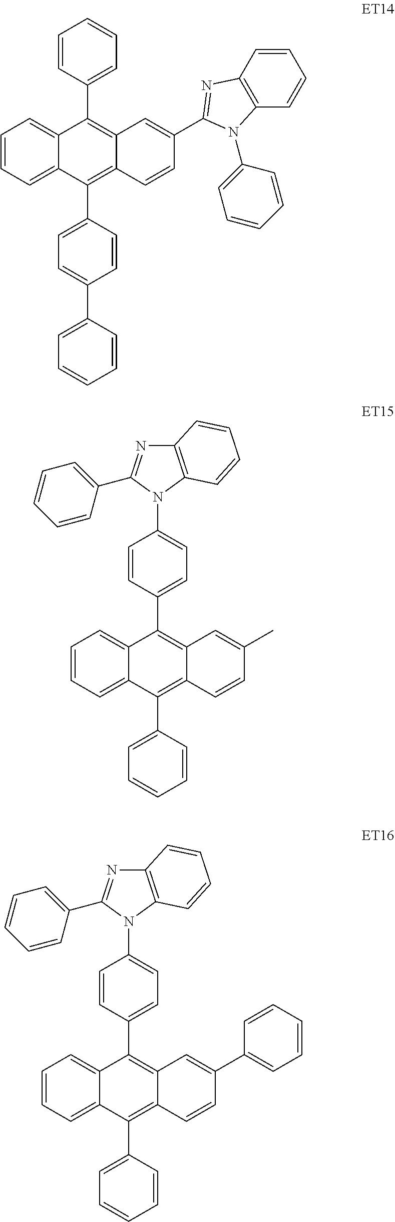 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

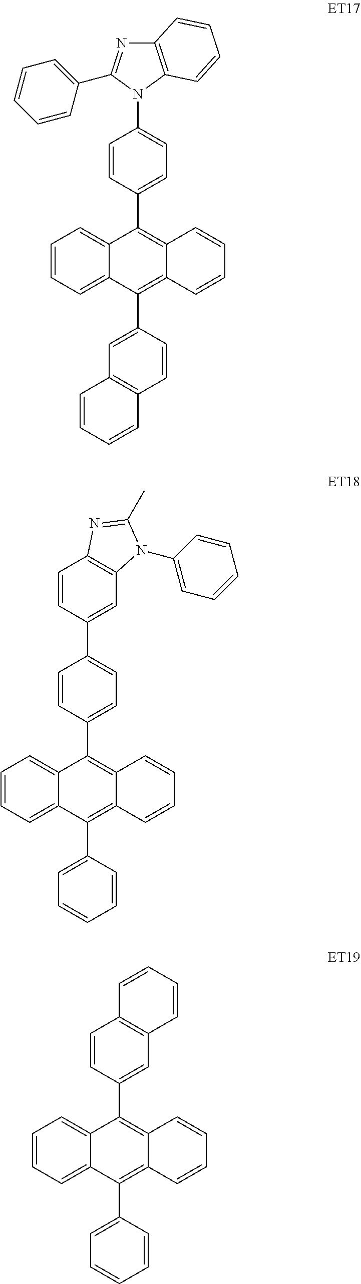

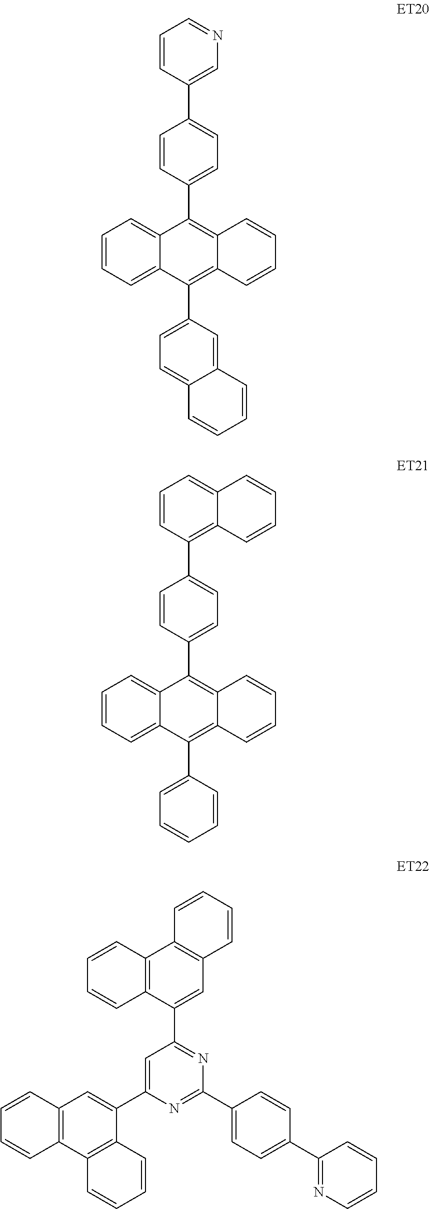

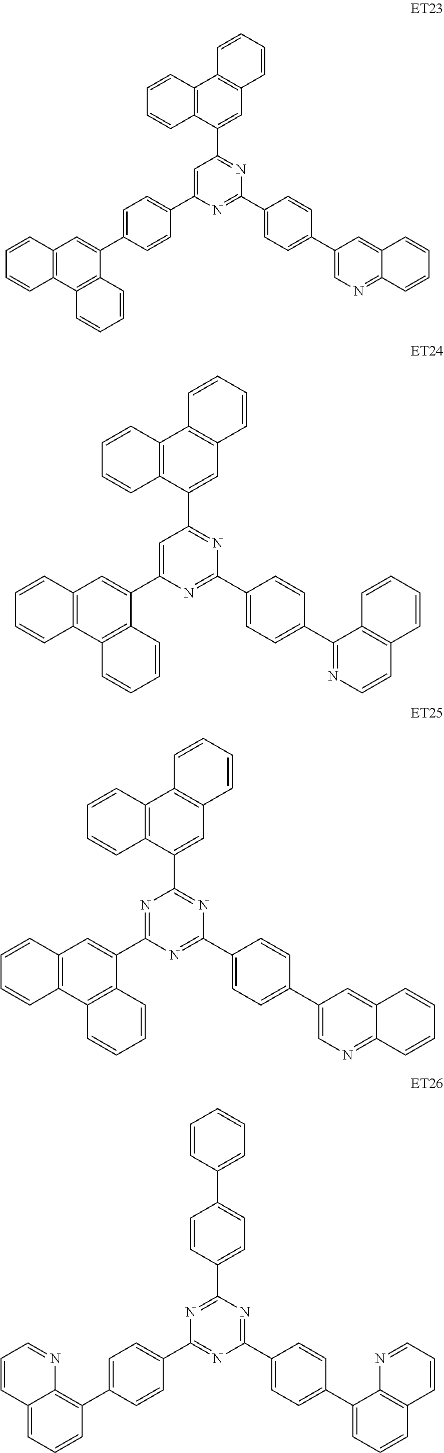 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

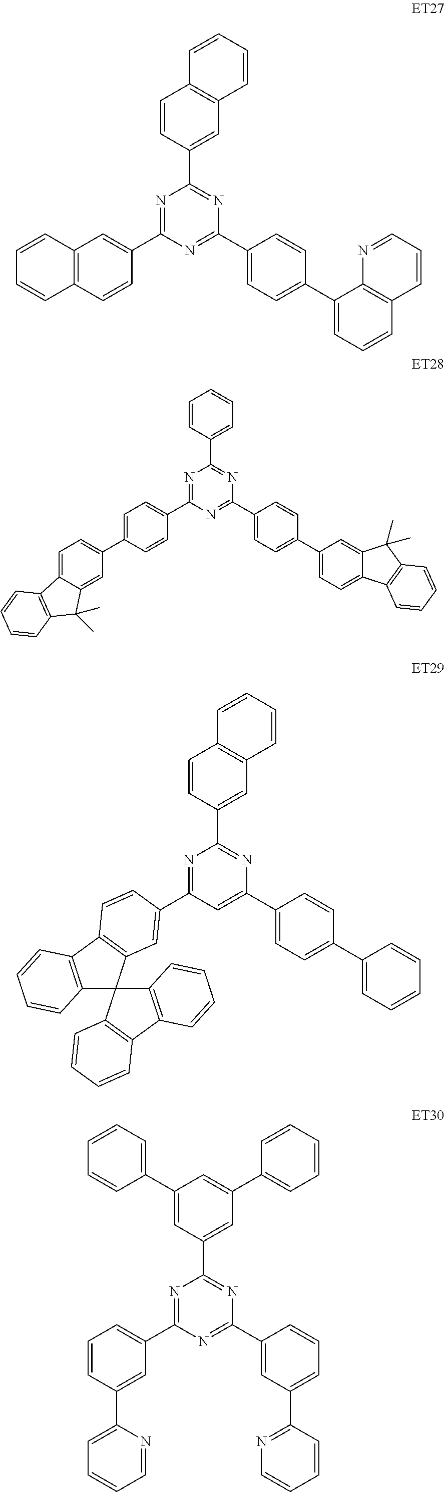

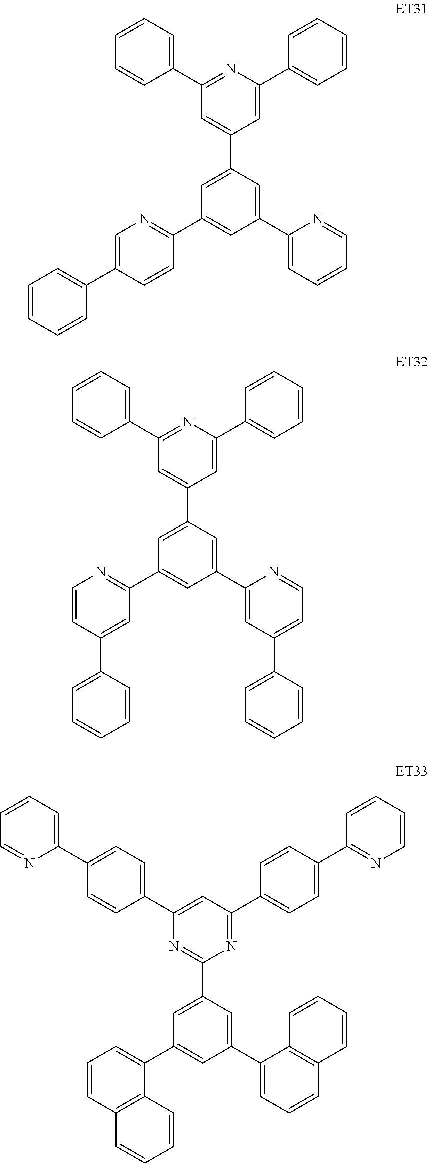 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

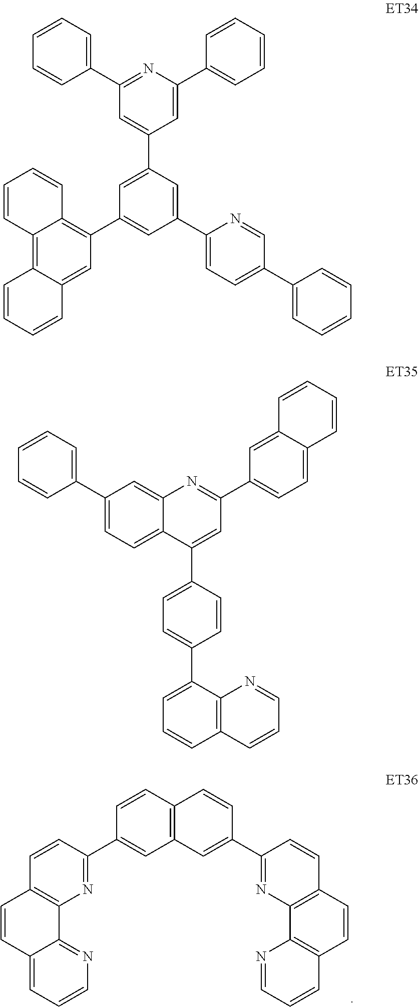

In an embodiment, the electron transport region ETR may include: a metal halide such as LiF, NaCl, CsF, RbCl, RbI, CuI, and KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may include a metal oxide such as Li₂O or BaO, or 8-hydroxyl-lithium quinolate (Lig), etc., but embodiments are not limited thereto. In another embodiment, the electron transport region ETR may be formed of a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen), in addition to the above-described materials. However, embodiments are not limited thereto.

The electron transport region ETR may include the above-described compounds of the hole transport region in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode. The second electrode may include Ag, Mg, Cu, Al, Pt, Pd, Au, Ni, Nd, Ir, Cr, Li, Ca, LiF, Mo, Ti, W, In, Sn, and Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgAg). In an embodiment, the second electrode EL2 may have a multi-layered structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, the resistance of the second electrode EL2 may decrease.

In an embodiment, the light emitting device ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol sol-9-yl)triphenylamine (TCTA), etc., or may include an epoxy resin, or an acrylate such as methacrylate. However, embodiments are not limited thereto, and the capping layer CPL may include at least one of Compounds P1 to P5:

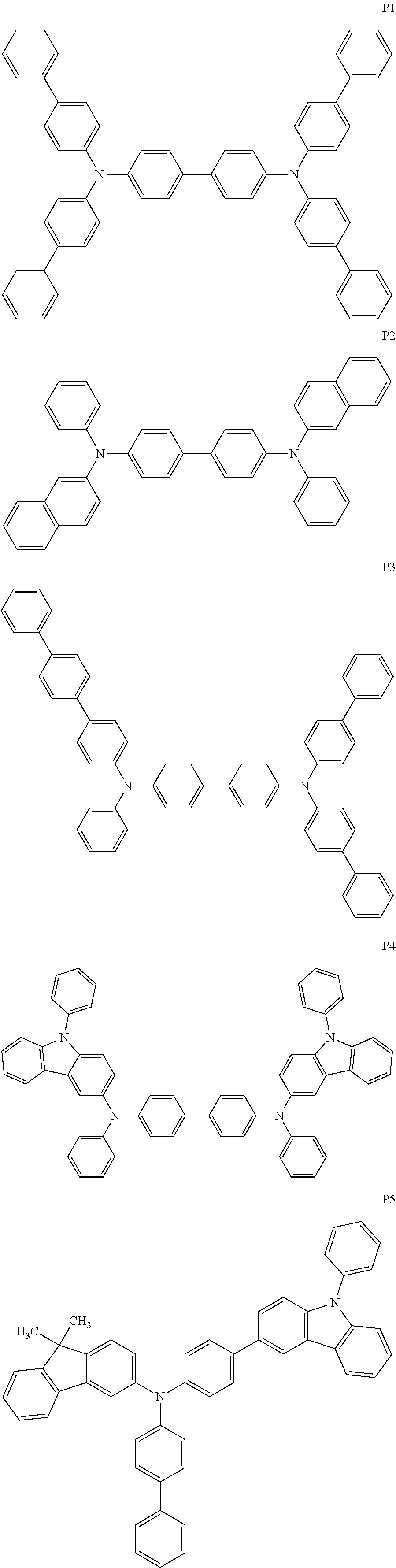 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example a refractive index of the capping layer CPL may be equal to or greater than about 1.6 with respect to light in a wavelength range of about 550 nm to about 660 nm.

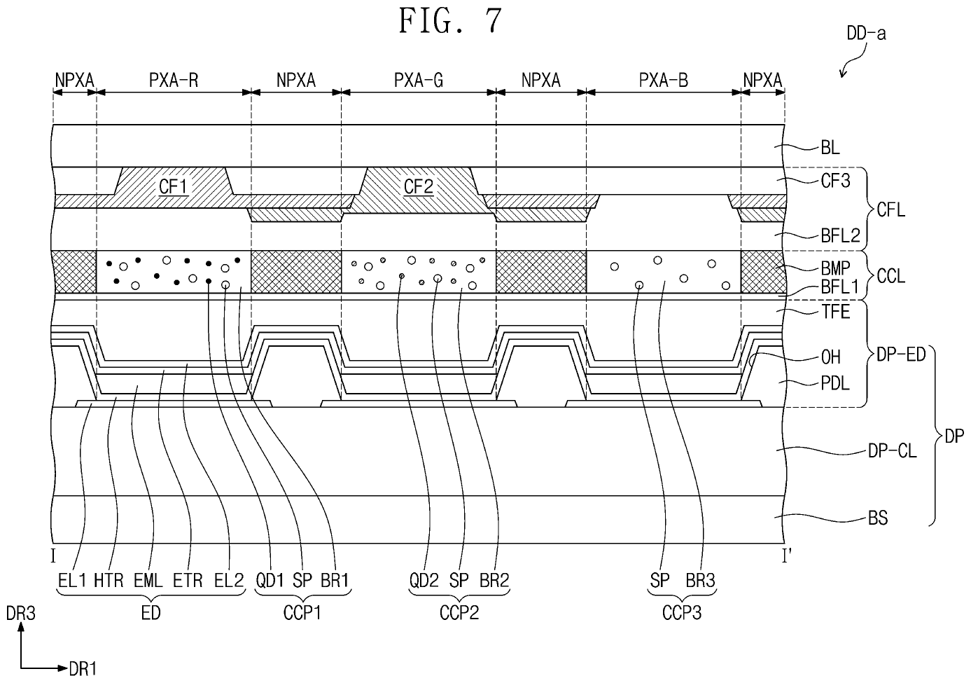

FIGS. 7 to 10 are each a schematic cross-sectional view of a display apparatus according to an embodiment. In the descriptions of the display apparatuses according to embodiments as depicted in FIGS. 7 to 10, the features which have been described above with respect to FIGS. 1 to 6 will not be described again, and the differing features will be described.

Referring to FIG. 7, the display apparatus DD-a according to an embodiment may include a display panel DP including a display device layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and the display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting device ED illustrated in FIG. 7 may be the same as a structure of a light emitting device ED according to one of FIGS. 3 to 6 as described above.

The emission layer EML of the light emitting device ED included in the display apparatus DD-a may include the above-described polycyclic compound.

Referring to FIG. 7, the emission layer EML may be disposed in an opening OH defined in a pixel defining film PDL. For example, the emission layer EML which is divided by the pixel defining film PDL and correspondingly provided to each of the light emitting regions PXA-R, PXA-G, and PXA-B, may each emit light in a same wavelength range. In the display apparatus DD-a, the emission layer EML may emit blue light. Although not shown in the drawings, in an embodiment, the emission layer EML may be provided as a common layer for each of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and may emit the resulting light. For example, the light control layer CCL may be a layer containing a quantum dot or a layer containing a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3, which are spaced apart from each other, but embodiments are not limited thereto. In FIG. 7, it is shown that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 containing a first quantum dot QD1 that converts first color light provided from the light emitting device ED into second color light, a second light control part CCP2 containing a second quantum dot QD2 that converts the first color light into third color light, and a third light control part CCP3 that transmits the first color light.

In an embodiment, the first light control part CCP1 may provide red light, which is the second color light, and the second light control part CCP2 may provide green light, which is the third color light. The third light control part CCP3 may provide blue light by transmitting the blue light that is the first color light provided from the light emitting device ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and a scatterer SP, the second light control part CCP2 may include the second quantum dot QD2 and a scatterer SP, and the third light control part CCP3 may not include a quantum dot but may include a scatterer SP.

The scatterer SP may be inorganic particles. For example, the scatterer SP may include at least one of TiO₂, ZnO, Al₂O₃, SiO₂, or hollow silica. The scatterer SP may include any of TiO₂, ZnO, Al₂O₃, SiO₂, or hollow silica, or the scatterer SP may be a mixture of at least two materials selected from TiO₂, ZnO, Al₂O₃, SiO₂, and hollow sphere silica.

The first light control part CCP1, the second light control part CCP2, and the third light control part CCP3 may each include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may be disposed on the light control parts CCP1, CCP2, and CCP3 to block the light control parts CCP1, CCP2, and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently further include an organic film. The barrier layers BFL1 and BFL2 may be formed of a single layer or of multiple layers.

In the display apparatus DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include a light shielding part (not shown) and filters CF1, CF2, and CF3. The color filter layer CFL may include a first filter CF1 that transmits the second color light, a second filter CF2 that transmits the third color light, and a third filter CF3 that transmits the first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter.

The first to third filters CF1, CF2, and CF3 may be disposed to respectively correspond to the red light emitting region PXA-R, the green light emitting region PXA-G, and the blue light emitting region PXA-B.

The light shielding part (not shown) may be a black matrix. The light shielding part (not shown) may include an organic light shielding material or an inorganic light shielding material containing a black pigment or dye. The light shielding part (not shown) may separate boundaries between the adjacent filters CF1, CF2, and CF3. In an embodiment, the light shielding part (not shown) may be formed of a blue filter.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

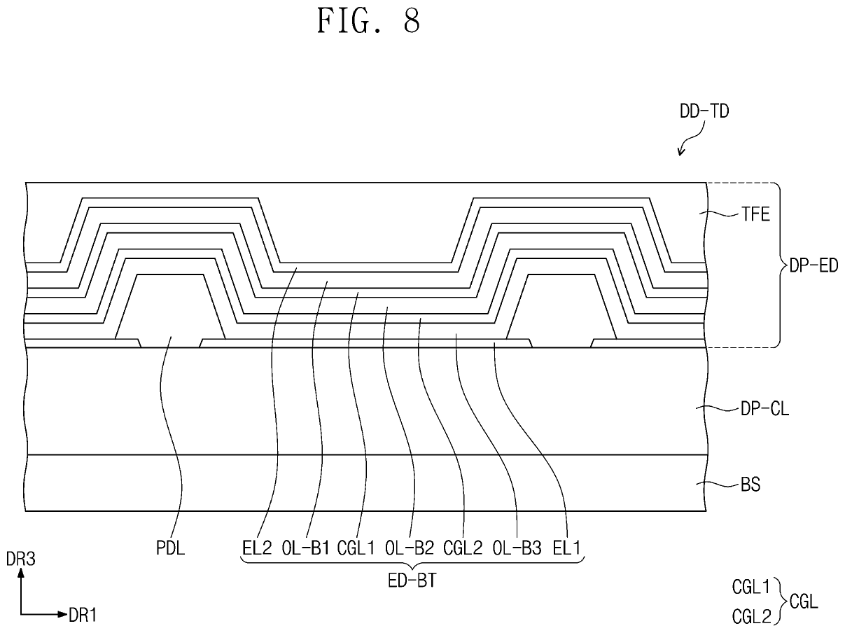

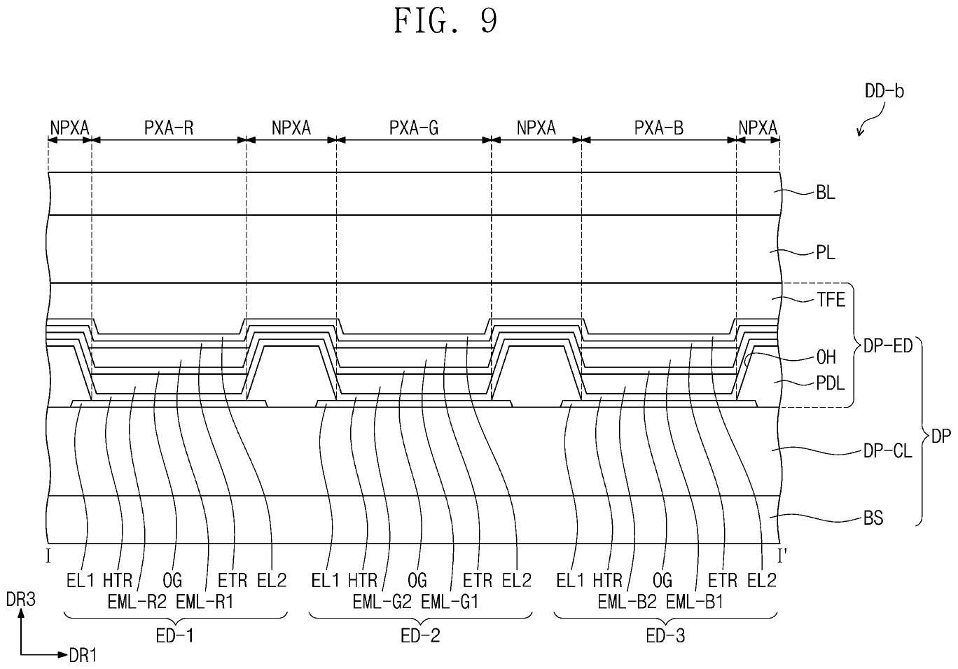

FIG. 8 is a schematic cross-sectional view of a portion of a display apparatus according to an embodiment. In the display apparatus DD-TD according to an embodiment, the light emitting device ED-BT may include light emitting structures OL-B1, OL-B2, and OL-B3. The light emitting device ED-BT may include a first electrode EL1 and a second electrode EL2 which face each other, and the light emitting structures OL-B1, OL-B2, and OL-B3, which are stacked in a thickness direction between the first electrode EL1 and the second electrode EL2. The light emitting structures OL-B1, OL-B2, and OL-B3 may each include an emission layer EML (FIG. 7) and a hole transport region HTR and an electron transport region ETR disposed with the emission layer EML (FIG. 7) therebetween.

For example, the light emitting device ED-BT included in the display apparatus DD-TD may be a light emitting device having a tandem structure and including multiple emission layers.

In an embodiment illustrated in FIG. 8, light emitted from the light emitting structures OL-B1, OL-B2, and OL-B3 may each be blue light. However, embodiments are not limited thereto, and the light emitted from the light emitting structures OL-B1, OL-B2, and OL-B3 may have wavelength ranges that are different from each other. For example, the light emitting device ED-BT including the light emitting structures OL-B1, OL-B2, and OL-B3, which emit light having wavelength ranges that are different from each other, may emit white light.

A charge generation layer CGL may be disposed between neighboring light emitting structures among the light emitting structures OL-B1, OL-B2, and OL-B3. In FIG. 8, the charge generation layer CGL includes charge generation layers CGL1 and CGL2. The charge generation layers CGL1 and CGL2 may each independently include a p-type charge generation layer and/or an n-type charge generation layer.

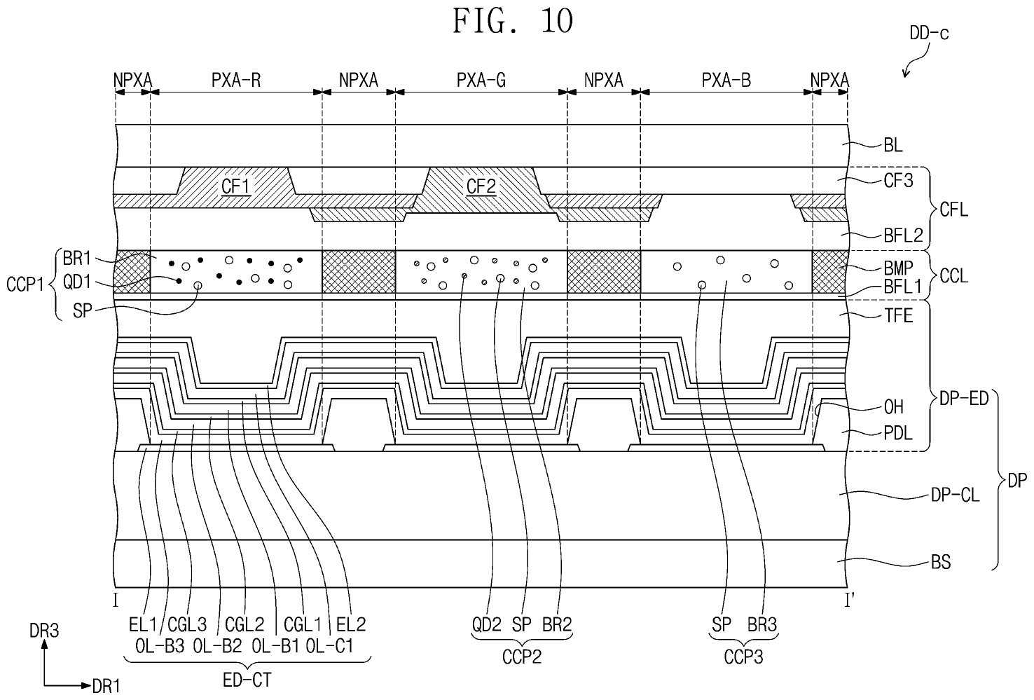

Referring to FIG. 9, a display apparatus DD-b according to an embodiment may include light emitting devices ED-1, ED-2, and ED-3, which each include two emission layers that are stacked. In comparison to the display apparatus DD illustrated in FIG. 2, the embodiment illustrated in FIG. 9 is different at least in that the first to third light emitting devices ED-1, ED-2, and ED-3 each include two emission layers that are stacked in a thickness direction. In each of the first to third light emitting devices ED-1, ED-2, and ED-3, the two emission layers may emit light in a same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. The third light emitting device ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for all of the first to third light emitting devices ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the electron transport region ETR and the emission auxiliary part OG. The second red emission layer EML-R2, the second green emission layer EML-G2, and the second blue emission layer EML-B2 may each be disposed between the emission auxiliary part OG and the hole transport region HTR.

For example, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2, which are stacked in that order. For example, the second light emitting device ED-2 may include the first electrode EL1, the hole transport region HTR, the second green emission layer EML-G2, the emission auxiliary part OG, the first green emission layer EML-G1, the electron transport region ETR, and the second electrode EL2, which are stacked in that order. For example, the third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2, which are stacked in that order.

An optical auxiliary layer PL may be disposed on the display device layer DP-ED. The optical auxiliary layer PL may include a polarizing layer. The optical auxiliary layer PL may be disposed on the display panel DP and may control light reflected at the display panel DP from an external light. Although not shown in the drawings, in an embodiment, the optical auxiliary layer PL may be omitted from the display apparatus DD-b.

At least one emission layer included in the display apparatus DD-b illustrated in FIG. 9 may include the above-described polycyclic compound according to an embodiment. For example, in an embodiment, at least one of a first blue emission layer EML-B1 or a second blue emission layer EML-B2 may include the polycyclic compound.

In contrast to FIGS. 8 and 9, FIG. 10 illustrates a display apparatus DD-c that is different at least in that it includes four light emitting structures OL-B1, OL-B2, OL-B3, and OL-C1. A light emitting device ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may be disposed between adjacent light emitting structures among the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may each emit light in a different wavelength region.

The charge generation layers CGL1, CGL2, and CGL3 which are disposed between adjacent light emitting structures OL-B1, OL-B2, OL-B3, and OL-C1 may each independently include a p-type charge generation layer and/or an n-type charge generation layer.

In the display apparatus DD-c, at least one of the light emitting structures OL-B1, OL-B2, OL-B3, and OL-C1 may each independently include the polycyclic compound according to an embodiment. For example, in an embodiment, at least one of the first to third light emitting structures OL-B1, OL-B2, and OL-B3 may each independently include the polycyclic compound.

The light emitting device ED according to an embodiment may include the polycyclic compound according to an embodiment in at least one functional layer disposed between the first electrode EL1 and the second electrode EL2, thereby exhibiting excellent luminous efficiency and improved service life characteristics. For example, the emission layer EML of the light emitting device ED may include the polycyclic compound, and the light emitting device ED may exhibit high efficiency and long service life characteristics.

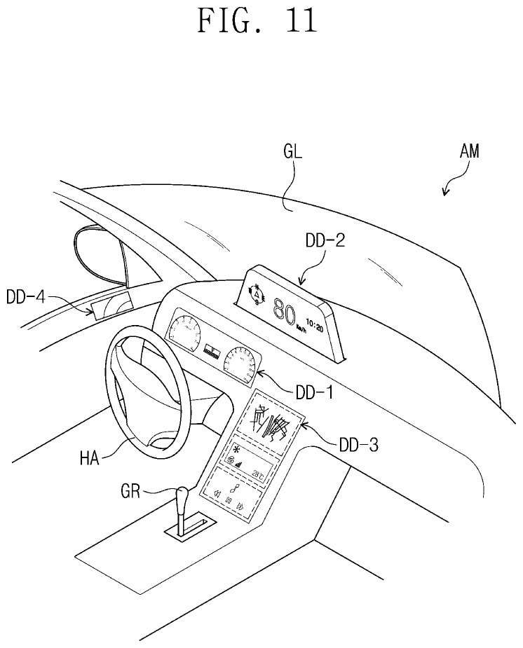

FIG. 11 is a schematic perspective view of an electronic apparatus according to an embodiment. FIG. 11 illustrates a part of a vehicle AM as an example of an electronic apparatus. However, embodiments are not limited thereto, and the electronic apparatus may be various transportation means such as bicycles, motorcycles, trains, ships, and airplanes.

Referring to FIG. 11, the vehicle AM may include first to fourth display apparatuses DD-1, DD-2, DD-3, and DD-4 for a vehicle. At least one of the first to fourth display apparatuses DD-1, DD-2, DD-3, and DD-4 may have a structure according to one of the display apparatuses DD, DD-a, DD-TD, DD-b, and DD-c as described in reference to FIG. 1, and FIG. 2, and FIGS. 7 to 10.

In an embodiment, at least one of the first to fourth display apparatuses DD-1, DD-2, DD-3, and DD-4 may include a light emitting device ED according to an embodiment as described in reference to one of FIGS. 3 to 6. The first to fourth display apparatuses DD-1, DD-2, DD-3, and DD-4 may each independently include multiple light emitting devices ED (see FIGS. 3 to 6). The light emitting devices ED may each include the first electrode EL1, the hole transport region HTR, the emission layer EML, the electron transport region ETR, and the second electrode EL2 (see FIGS. 3 to 6). The emission layer EML (see FIGS. 3 to 6) may include a polycyclic compound according to an embodiment as described above. Thus, the first to fourth display apparatuses DD-1, DD-2, DD-3, and DD-4 for a vehicle AM may exhibit improved image quality.

Referring to FIG. 11, the vehicle AM may include a steering wheel HA and a gearshift GR for driving the vehicle AM. The vehicle AM may include a front window GL that is disposed so as to face the driver.

The first display apparatus DD-1 may be disposed in a first region overlapping the steering wheel HA. For example, the first display apparatus DD-1 may be a digital cluster that displays first information of the vehicle AM. The first information may include a first gauge for indicating a driving speed of the vehicle AM, a second gauge for indicating revolutions per minute (RPM), an image that indicate fuel level, etc. A first gauge and a second gauge may each be represented by a digital image.

The second display apparatus DD-2 may be disposed in a second region facing the driver's seat and overlapping the front window GL. The driver's seat may be a seat where the steering wheel HA is disposed. For example, the second display apparatus DD-2 may be a head up display (HUD) that displays second information of the vehicle AM. The second display apparatus DD-2 may be optically transparent. The second information may include digital numbers that indicate a driving speed of the vehicle AM, and may further include information such as the current time.

The third display apparatus DD-3 may be disposed in a third region adjacent to the gearshift GR. For example, the third display apparatus DD-3 may be disposed between the driver's seat and a passenger seat and may be a center information display (CID) for a vehicle that displays third information. The passenger seat may be a seat that is spaced apart from the driver's seat, with the gearshift GR disposed therebetween. The third information may include information about traffic (e.g., navigation information), information about playing music or radio, information about playing video, information about temperatures inside the vehicle AM, etc.

The fourth display apparatus DD-4 may be disposed in a fourth region that is adjacent to the side of the vehicle AM and may be spaced apart from the steering wheel HA and the gearshift GR. For example, the fourth display apparatus DD-4 may be a digital side-view mirror that displays fourth information. The fourth display apparatus DD-4 may display an image of the exterior of the vehicle AM that is taken by a camera module disposed outside the vehicle AM.

The first to fourth information are described herein only as examples, and the first to fourth display apparatuses DD-1, DD-2, DD-3, and DD-4 may further display information about the interior and exterior of the vehicle. The first to fourth information may include information that are different from each other. However, embodiments are not limited thereto, and a part of the first to fourth information may include the same information as one another.

Hereinafter, a polycyclic compound according to an embodiment and a light emitting device according to an embodiment will be described in detail with reference to the Examples and the Comparative Examples. The Examples described below are only provided as illustrations to assist in understanding the disclosure, and the scope thereof is not limited thereto.

### Examples

### 1. Synthesis of Polycyclic Compound

A synthesis method of a polycyclic compound according to the current embodiment will be described in detail by illustrating synthesis methods of Compounds 11, 16, 30, and 40. the synthesis methods of the polycyclic compounds as explained below are only provided as examples, and the synthesis method of the polycyclic compound is not limited to the Examples below.

### (1) Synthesis of Compound 11

Compound 11 may be synthesized, for example, by Reaction Scheme 1 below:

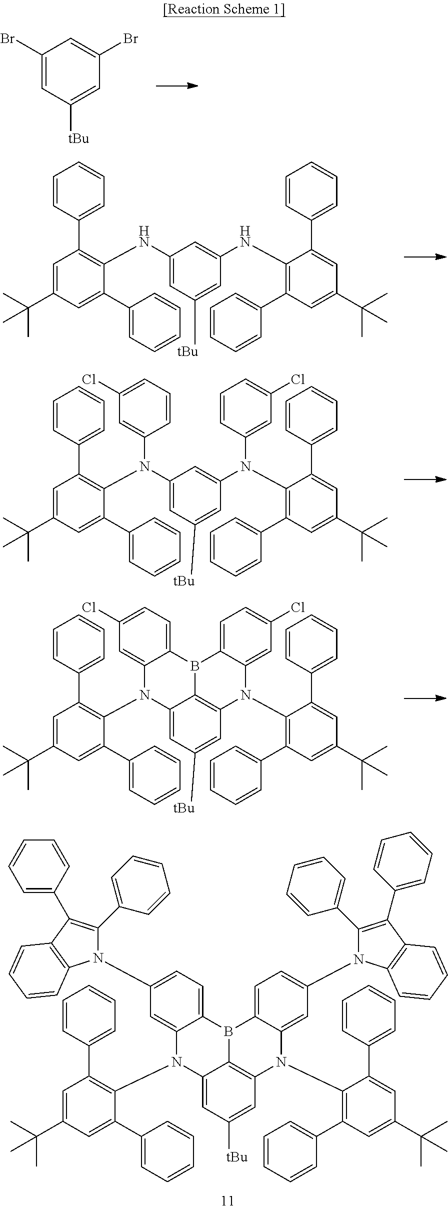

Reaction Scheme 1 will be described in detail in Reaction Scheme 1-1 to Reaction Scheme 1-4 below:

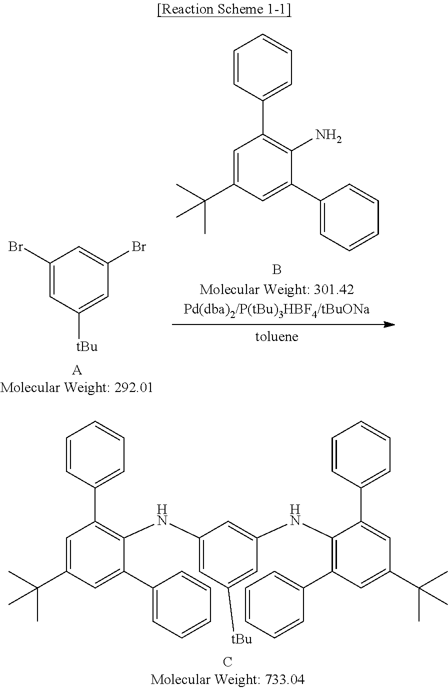 [SMILES: CC(C)(C)c1cc(Br)cc(Br)c1 ; CC(C)(C)c1cc(-c2ccccc2)c(N)c(-c2ccccc2)c1 ; CC(C)(C)c1cc(Nc2c(-c3ccccc3)cc(C(C)(C)C)cc2-c2ccccc2)cc(Nc2c(-c3ccccc3)cc(C(C)(C)C)cc2-c2ccccc2)c1]

A (20.0 g, 68.4 mmol), B (41.3 g, 137 mmol), Pd(dba)₂ (3.93 g, 6.84 mmol), P(tBu)₃HBF₄ (0.99 g, 3.42 mmol), and tBuONa (6.57 g, 68.4 mmol) were added to 925 mL of toluene, and the resultant mixture was heated and stirred at about 110° C. for about 6 hours. Water was added to the reactant, and the resultant mixture was subjected to Celite filtering and liquid separation to concentrate an organic layer. The organic layer was purified by silica gel column chromatography to obtain C.

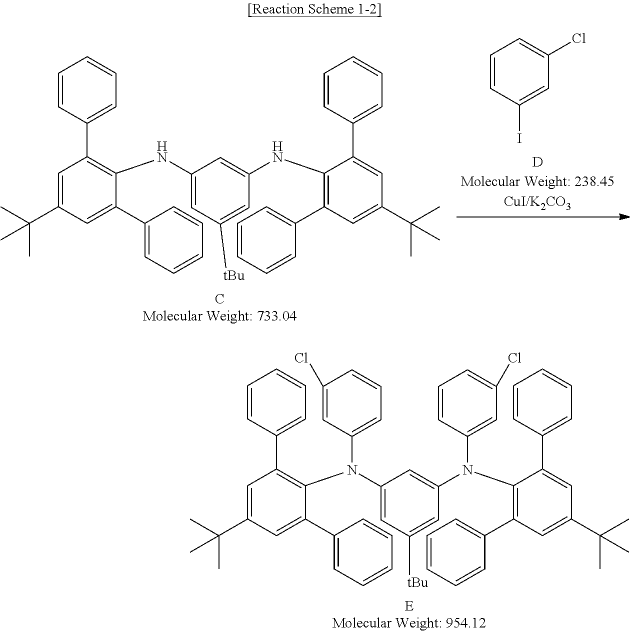

C (15.0 g, 20.5 mmol), D (24.6 g, 103 mmol), CuI (3.90 g, 20.5 mmol), and K₂CO₃ (14.2 g, 103 mmol) were added thereto, and the resultant mixture was heated and stirred at about 80° C. for about 12 hours. Water was added to the reactant, and the resultant mixture was subjected to Celite filtering and liquid separation to concentrate an organic layer. The organic layer was purified by silica gel column chromatography to obtain E.

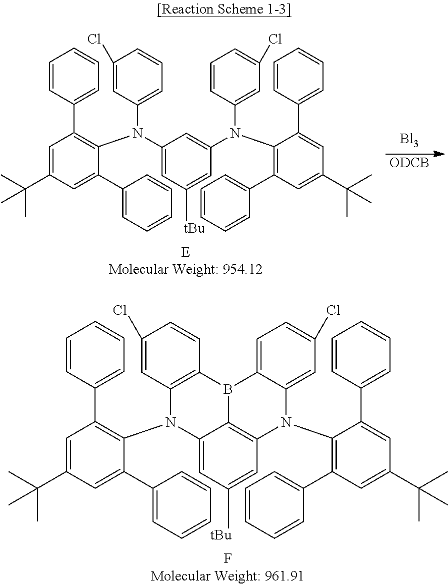

E (20.0 g, 21 mmol), BI₃ (16.4 g, 42 mmol), and ODCB (80 mL) were added thereto, and the resultant mixture was heated and stirred at about 160° C. for about 12 hours. Water was added to the reactant, and the resultant mixture was subjected to Celite filtering and liquid separation to concentrate an organic layer. The organic layer was purified by silica gel column chromatography to obtain F.

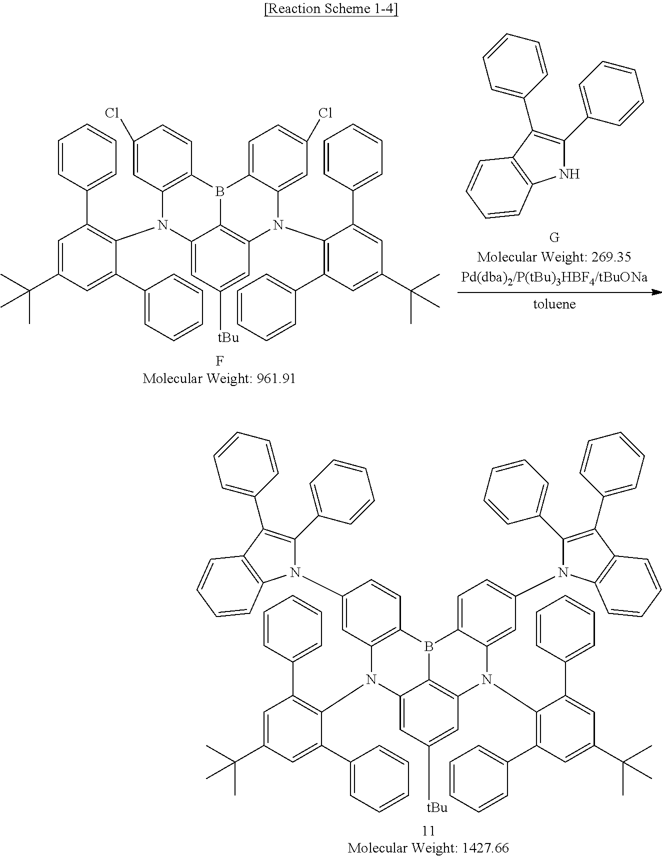 [SMILES: CC(C)(C)c1cc(-c2ccccc2)c(N2c3cc(Cl)ccc3B3c4ccc(Cl)cc4N(c4c(-c5ccccc5)cc(C(C)(C)C)cc4-c4ccccc4)c4cc(C(C)(C)C)cc2c43)c(-c2ccccc2)c1 ; c1ccc(-c2[nH]c3ccccc3c2-c2ccccc2)cc1 ; CC(C)(C)c1cc(-c2ccccc2)c(N2c3cc(-n4c(-c5ccccc5)c(-c5ccccc5)c5ccccc54)ccc3B3c4ccc(-n5c(-c6ccccc6)c(-c6ccccc6)c6ccccc65)cc4N(c4c(-c5ccccc5)cc(C(C)(C)C)cc4-c4ccccc4)c4cc(C(C)(C)C)cc2c43)c(-c2ccccc2)c1]

F (2.00 g, 2.08 mmol), G (1.12 g, 4.16 mmol), Pd(dba)₂ (0.12 g, 0.21 mmol), P(tBu)₃HBF₄ (0.03 g, 0.11 mmol), and tBuONa (0.40 g, 4.16 mmol) were added to 92 mL of toluene, and the resultant mixture was heated and stirred at about 110° C. for about 6 hours. Water was added to the reactant, and the resultant mixture was subjected to Celite filtering and liquid separation to concentrate an organic layer. The organic layer was purified by silica gel column chromatography to obtain Compound 11.

### (2) Synthesis of Compound 16

Compound 16 may be synthesized, for example, by Reaction Scheme 2 below:

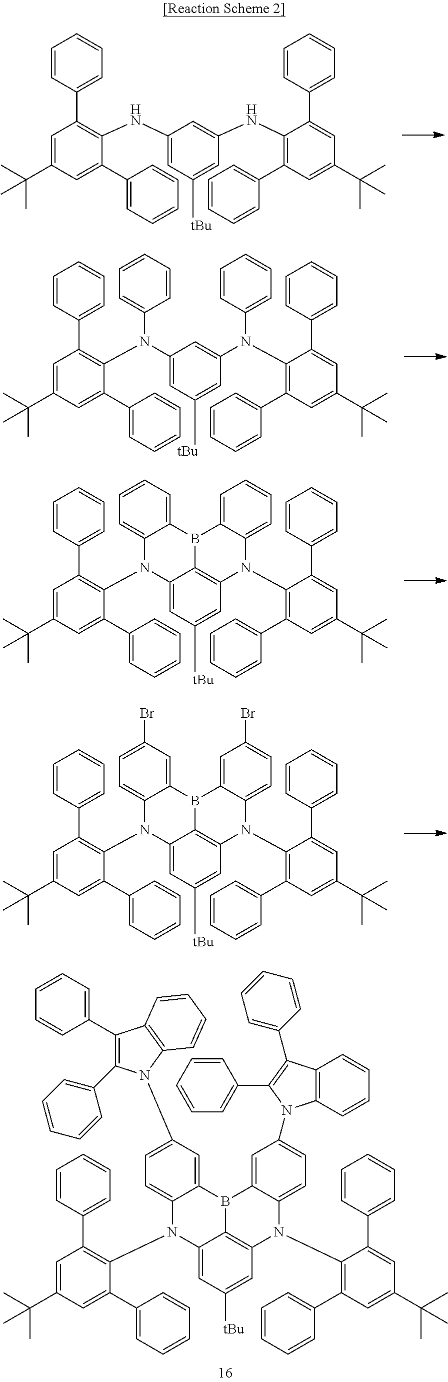

Reaction Scheme 2 above will be described in detail in Reaction Scheme 2-1 and Reaction Scheme 2-2 below:

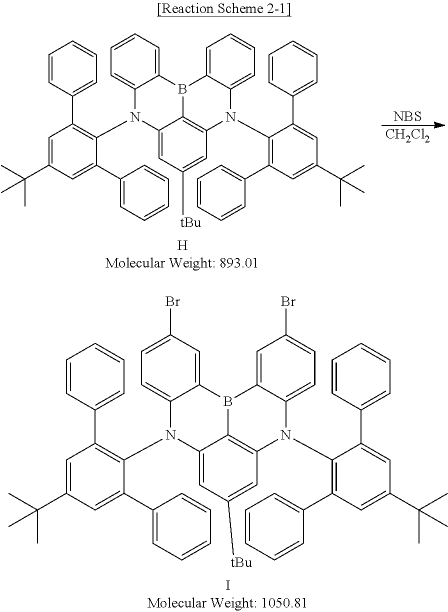

H (2.00 g, 2.24 mmol), NBS (0.80 g, 4.48 mmol), and CH₂Cl₂ (80 mL) were added, and the resultant mixture was stirred at room temperature for about 1 hour. Water was added to the reactant, and the resultant mixture was subjected to Celite filtering and liquid separation to concentrate an organic layer. The organic layer was purified by silica gel column chromatography to obtain I. H was synthesized under the same conditions as Reaction Scheme 1-1 to Reaction Scheme 1-3 above.

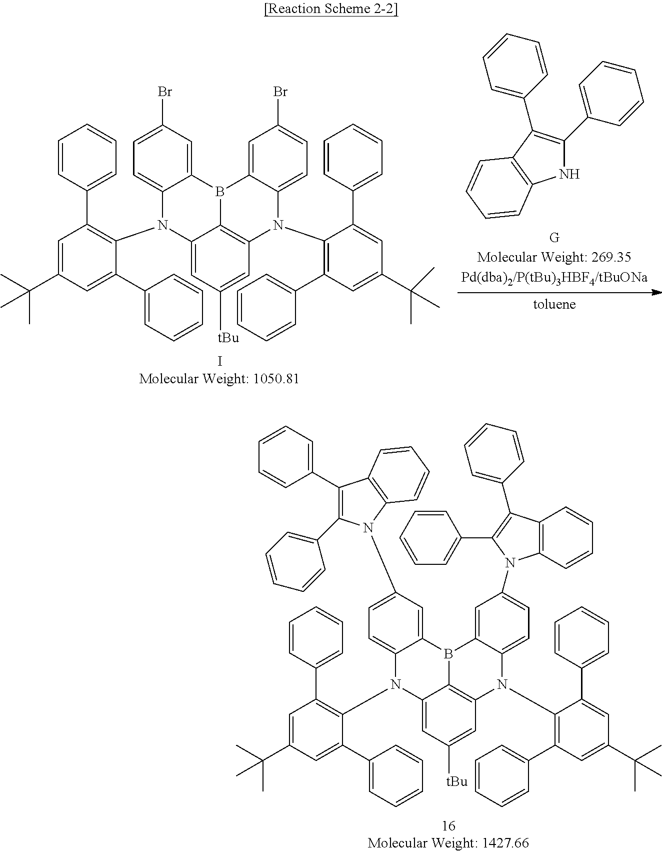

Synthesis was performed under the same conditions as Reaction Scheme 1-4 to obtain Compound 16.

### (3) Synthesis of Compound 30

Compound 30 may be synthesized, for example, by Reaction Scheme 3 below:

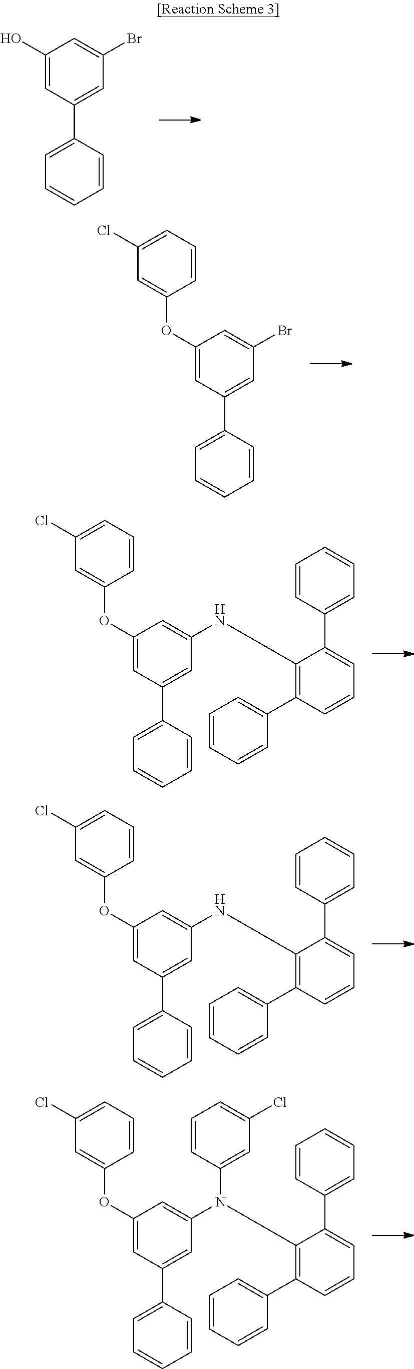

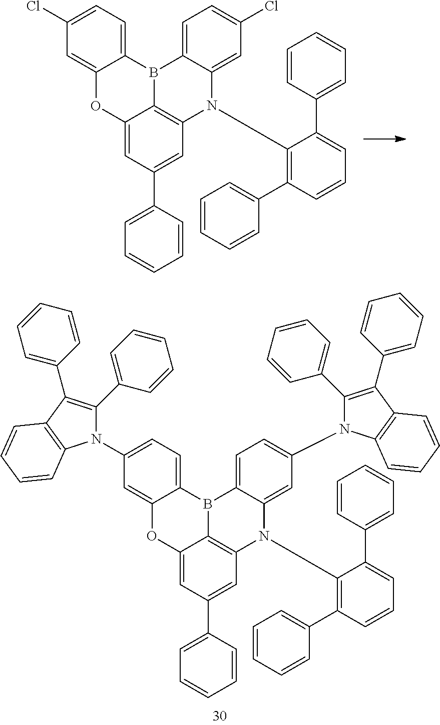 [SMILES: Clc1ccc2c(c1)Oc1cc(-c3ccccc3)cc3c1B2c1ccc(Cl)cc1N3c1c(-c2ccccc2)cccc1-c1ccccc1 ; c1ccc(-c2cc3c4c(c2)N(c2c(-c5ccccc5)cccc2-c2ccccc2)c2cc(-n5c(-c6ccccc6)c(-c6ccccc6)c6ccccc65)ccc2B4c2ccc(-n4c(-c5ccccc5)c(-c5ccccc5)c5ccccc54)cc2O3)cc1]

Reaction Scheme 3 above will be described in detail in Reaction Scheme 3-1 and Reaction Scheme 3-2 below:

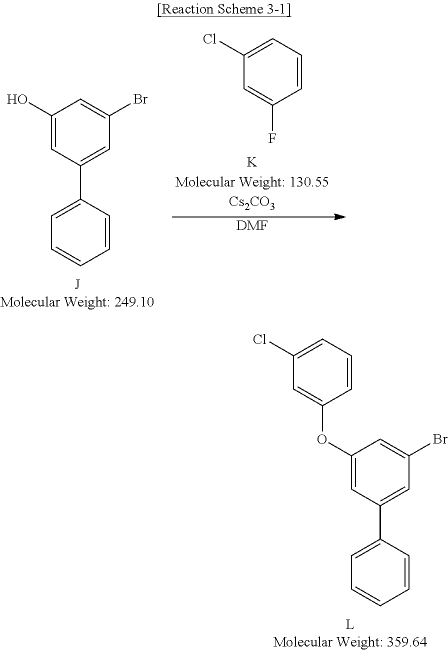

J (10.0 g, 40.1 mmol), K (5.24 g, 40.1 mmol), and Cs₂CO₃ (13.1 g, 40.1 mmol) were added to 500 mL of DMF, and the resultant mixture was heated and stirred at about 140° C. for about 12 hours. Water was added to the reactant, and the resultant mixture was subjected to Celite filtering and liquid separation to concentrate an organic layer. The organic layer was purified by silica gel column chromatography to obtain L.

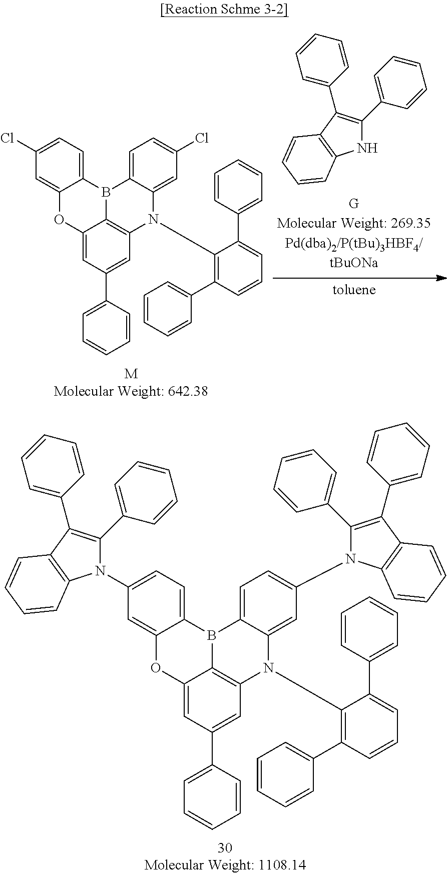

Synthesis was performed under the same conditions as Reaction Scheme 1-4 to obtain Compound 30. M was synthesized under the same conditions as Reaction Scheme 1-1 to Reaction Scheme 1-3 above.

### (4) Synthesis of Compound 40

Compound 40 may be synthesized, for example, by Reaction Scheme 4 below:

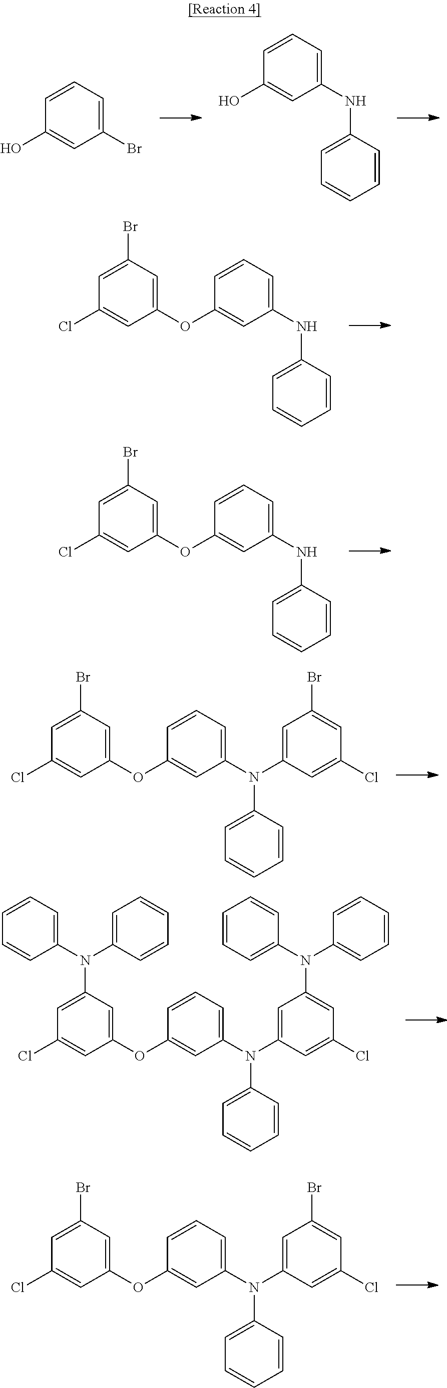

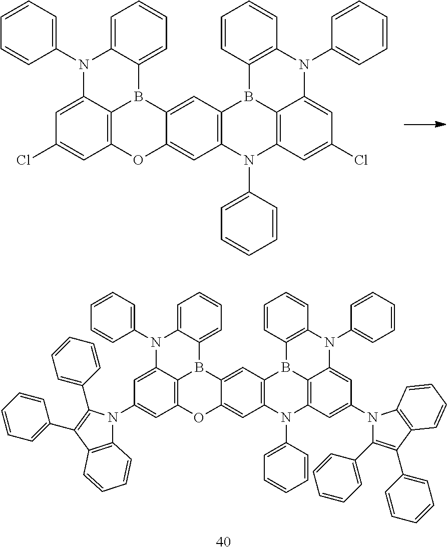 [SMILES: Clc1cc2c3c(c1)N(c1ccccc1)c1ccccc1B3c1cc3c(cc1O2)N(c1ccccc1)c1cc(Cl)cc2c1B3c1ccccc1N2c1ccccc1 ; c1ccc(-c2c(-c3ccccc3)n(-c3cc4c5c(c3)N(c3ccccc3)c3ccccc3B5c3cc5c(cc3O4)N(c3ccccc3)c3cc(-n4c(-c6ccccc6)c(-c6ccccc6)c6ccccc64)cc4c3B5c3ccccc3N4c3ccccc3)c3ccccc23)cc1]

Reaction Scheme 4 above will be described in detail in Reaction Scheme 4-1 below:

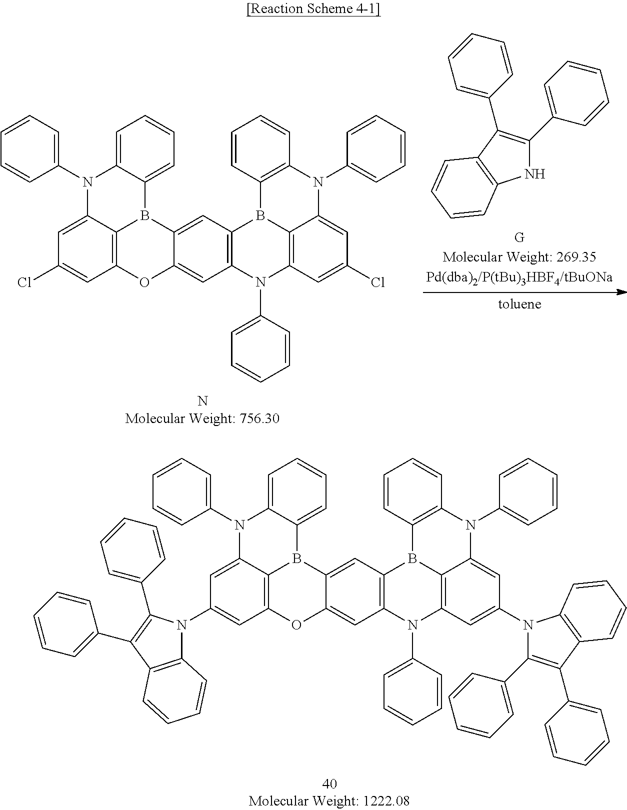

Synthesis was performed under the same conditions as Reaction Scheme 1-4 to obtain Compound 40. N was synthesized under the same conditions as Reaction Scheme 1-1 to Reaction Scheme 1-3 above and Reaction Scheme 3-1.

### 2. Manufacture and Evaluation of Light Emitting Devices Including Polycyclic Compound

### (1) Manufacture of Light Emitting Devices

The light emitting devices of the Examples which include the polycyclic compound according to an embodiment in the emission layer were manufactured as follows. Example Compounds 11, 16, 30, and 40 as described above were used as dopant materials for the emission layers to manufacture the light emitting devices of Examples 1 to 4, respectively. Comparative Examples 1 to 3 respectively correspond to the light emitting devices manufactured using Comparative Example Compounds C1 to C3 as dopant materials for the emission layers. The Example Compounds and the Comparative Example Compounds that are applied to the emission layers are as follows:

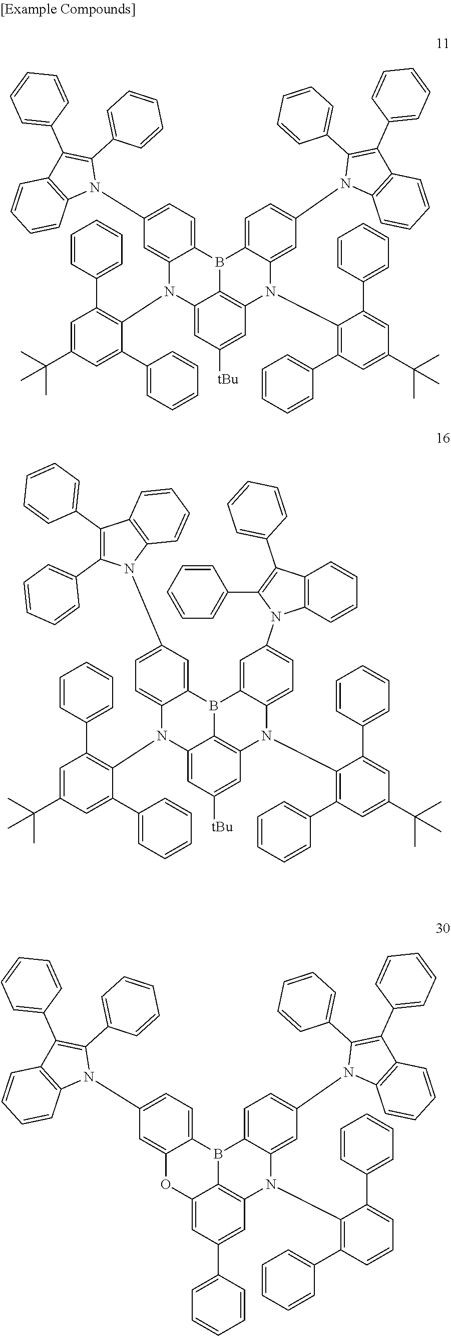

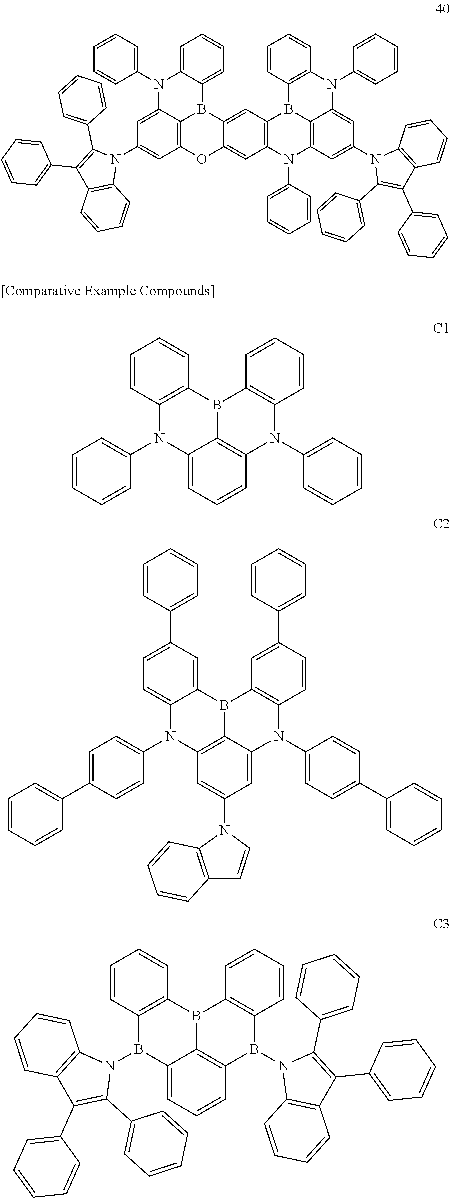 [SMILES: c1ccc(-c2c(-c3ccccc3)n(-c3cc4c5c(c3)N(c3ccccc3)c3ccccc3B5c3cc5c(cc3O4)N(c3ccccc3)c3cc(-n4c(-c6ccccc6)c(-c6ccccc6)c6ccccc64)cc4c3B5c3ccccc3N4c3ccccc3)c3ccccc23)cc1 ; c1ccc(N2c3ccccc3B3c4ccccc4N(c4ccccc4)c4cccc2c43)cc1 ; c1ccc(-c2ccc(N3c4ccc(-c5ccccc5)cc4B4c5cc(-c6ccccc6)ccc5N(c5ccc(-c6ccccc6)cc5)c5cc(-n6ccc7ccccc76)cc3c54)cc2)cc1 ; c1ccc(-c2c(-c3ccccc3)n(B3c4ccccc4B4c5ccccc5B(n5c(-c6ccccc6)c(-c6ccccc6)c6ccccc65)c5cccc3c54)c3ccccc23)cc1]

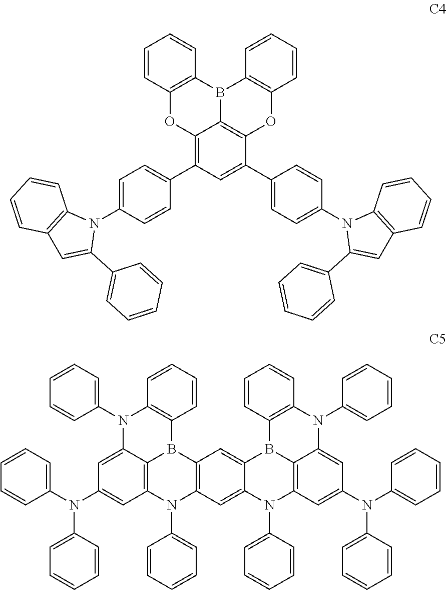 [SMILES: c1ccc(-c2cc3ccccc3n2-c2ccc(-c3cc(-c4ccc(-n5c(-c6ccccc6)cc6ccccc65)cc4)c4c5c3Oc3ccccc3B5c3ccccc3O4)cc2)cc1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1]

A 150 nm-thick first electrode was formed of ITO. On the first electrode, a 10 nm-thick hole injection layer was formed of dipyrazino[2,3-f:2′,3′-h]quinoxaline-2,3,6,7,10,11-hexacarbonitrile (HAT-CN). On the hole injection layer, an 80 nm-thick hole transport layer was formed of N,N′-bis(naphthalen-1-yl)-N,N′-bis(phenyl)-2,2′-dimethylbenzidine (α-NPD). On the hole transport layer, a 5 nm-thick emission auxiliary layer was formed of 1,3-bis(carbazol-9-yl)benzene (mCP). On the emission auxiliary layer, 3,3′-di(9H-carbazol-9-yl)-1,1′-biphenyl (mCBP) and an Example Compound were co-deposited in a weight ratio of about 99:1 to form a 20 nm-thick emission layer. For the devices of the Comparative Examples, the Comparative Example Compounds were applied instead of Example Compounds. On the emission layer, a 30 nm-thick electron transport layer was formed of 2,2′,2″-(1,3,5-benzinetriyl)-tris(1-phenyl-1-H-benzimidazole) (TPBi). On the electron transport layer, a 0.5 nm-thick electron injection layer was formed of LiF. On the electron injection layer, a 100 nm-thick second electrode was formed of Al. Each layer was formed by a vacuum deposition method.

Compounds for the functional layers that were used for manufacturing the light emitting devices of the Examples and the Comparative Examples are disclosed below. The compounds below are materials of the related art, and commercial products were subjected to sublimation purification and used to manufacture the devices.

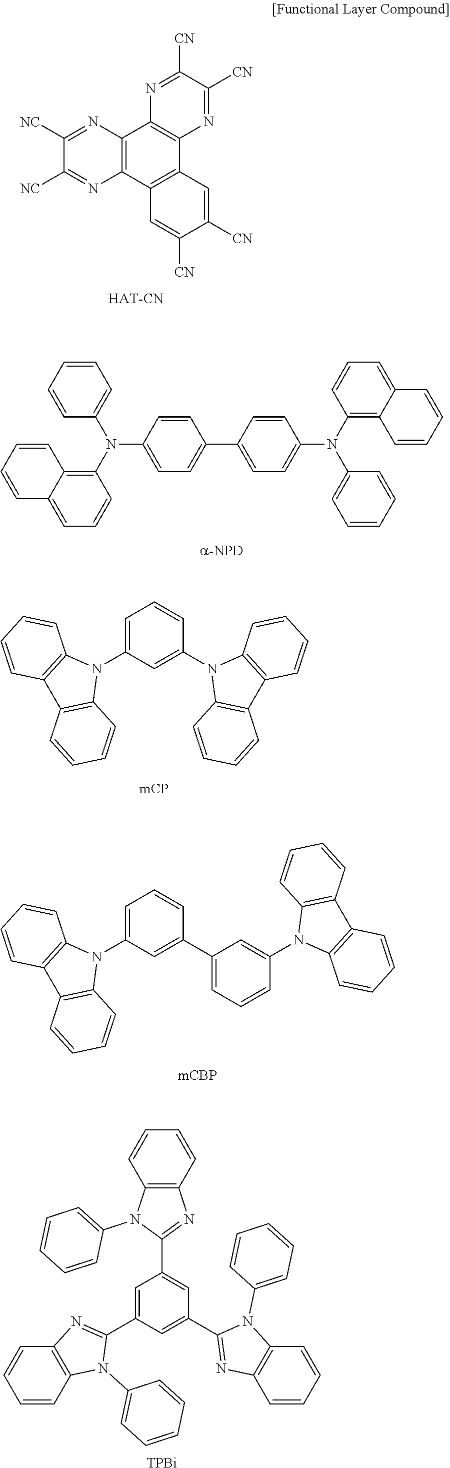

Measurements were taken by using I-V-L Test System Polaronix V7000 (manufacturer: dichloromethaneSience Inc.). λₘₐₓ is the maximum emission wavelength of the emission spectrum. Roll-off rate is calculated by {(external quantum efficiency at 1 cd/m³)-(1,000 cd/m³)}/(external quantum efficiency at 1 cd/m³)×100. EQEₘₐₓ is the external quantum efficiency at 1,000 cd/m². The service life (LT₅₀) of the light emitting device is the time taken to reach 50% brightness deterioration from an initial value when the light emitting device was continuously driven at a current density of 10 mA/cm², and is shown as a relative service life based on Comparative Example 1.

The characteristics of the light emitting devices of Examples 1 to 3 and Comparative Examples 1 to 4 were evaluated, and the results are listed in Table 1. The light emitting devices of Examples 1 to 3 and Comparative Examples 1 to 4 were manufactured according to the method for manufacturing a device as described above.

TABLE 1

| | Emission | | | Roll- | | |
|---|---|---|---|---|---|---|
| | layer dopant | FWHM | λₘₐₓ | off | EQEₘₐₓ | |
| | (1 wt %) | (nm) | (nm) | (%) | (%) | LT₅₀ |
| Example 1 | Compound 11 | 23 | 461 | 27.8 | 14.2 | 1.6 |
| Example 2 | Compound 16 | 24 | 465 | 28.9 | 13.2 | 1.5 |
| Example 3 | Compound 30 | 32 | 463 | 30.5 | 12.3 | 1.5 |
| Comparative | Comparative | 32 | 462 | 32.0 | 11.2 | 1.0 |
| Example 1 | Example | | | | | |
| | Compound C1 | | | | | |
| Comparative | Comparative | 32 | 459 | 35.4 | 10.9 | 1.2 |
| Example 2 | Example | | | | | |
| | Compound C2 | | | | | |
| Comparative | Comparative | 55 | 470 | 50.5 | 5.7 | 0.3 |
| Example 3 | Example | | | | | |
| | Compound C3 | | | | | |
| Comparative | Comparative | 38 | 440 | 40.2 | 6.7 | 0.4 |
| Example 4 | Example | | | | | |
| | Compound C4 | | | | | |

Referring to Table 1, Examples 1 to 3, which are light emitting devices to which the polycyclic compounds according to embodiments are applied, exhibit narrow FWHM, small roll-off, high luminous efficiency, and long service life characteristics, as compared with Comparative Examples 1 to 4.

The polycyclic compound according to embodiments has a core structure including a pentacyclic structure in which first to third aromatic rings are fused via one boron atom, one nitrogen atom, and one heteroatom. The first to third aromatic rings are substituted or unsubstituted benzene rings, and the core structure includes a phenyl group bonded to the nitrogen atom.

The polycyclic compound applied to the light emitting devices of Examples 1 to 3 has a structure in which an indole group is introduced into the core structure, and the indole group has a structure in which two phenyl groups are substituted. Accordingly, the polycyclic compound is stabilized, and thus the light emitting device exhibits narrow FWHM, small roll-off, high luminous efficiency, and long service life characteristics.

Comparative Example Compound C1 is a compound that does not contain an indole group, and therefore, it is thought that the compound is not stabilized and thus the characteristics of the light emitting device were evaluated as being low. Comparative Example Compound C2 is a compound that contains an indole group at which a phenyl group is not substituted, and therefore, it is thought that the compound is not stabilized and thus the characteristics of the light emitting device were evaluated as being low. Comparative Example Compound C3 is a compound in which an indole group is bonded to the boron atom, and therefore, it is thought that the compound has weak TADF characteristics and thus the characteristics of the light emitting device were evaluated as being low. Comparative Example Compound C4 is a compound in which an indole group is linked via a linker (phenylene group), and therefore, it is thought that the compound is not stabilized and thus the characteristics of the light emitting device were evaluated as being low.

The characteristics of the light emitting devices of Example 4 and Comparative Example 5 were evaluated, and the results are listed in Table 2. The light emitting devices of Example 4 and Comparative Example 5 were manufactured according to the method for manufacturing a device as described above.

TABLE 2

| | Emission | | | Roll- | | |
|---|---|---|---|---|---|---|
| | layer dopant | FWHM | λₘₐₓ | off | EQEₘₐₓ | |
| | (1 wt %) | (nm) | (nm) | (%) | (%) | LT₅₀ |
| Example 4 | Compound 40 | 18 | 467 | 11.2 | 19.5 | 1.9 |
| Comparative | Comparative | 18 | 468 | 13.2 | 18.5 | 1.5 |
| Example 5 | Example | | | | | |
| | Compound C5 | | | | | |

Referring to Table 2, Example 4, which is a light emitting device to which the polycyclic compound according to an embodiment is applied, exhibits small roll-off, high luminous efficiency, and long service life characteristics as compared with Comparative Example 5.

The polycyclic compound of Example 4 includes a core structure in which multiple aromatic rings are fused via one boron atom, one nitrogen atom, and one heteroatom, and a phenyl group is bonded to the nitrogen atom. Further, the compound of Example 4 has a structure in which substituents bonded to the core structure are bonded to an adjacent substituent to form a ring, and the structure may be considered an expanded core structure.

The polycyclic compound applied to the light emitting device of Example 4 has a structure in which an indole group is introduced into the expanded core structure, and the indole group has a structure in which two phenyl groups are substituted. Accordingly, the polycyclic compound is stabilized, and thus the light emitting device exhibits small roll-off, high luminous efficiency, and long service life characteristics.

By comparison, because Comparative Example Compound C5 is a compound that does not contain an indole group, it is thought that the compound is not stabilized and thus the characteristics of the light emitting device were evaluated as being low.

The light emitting device of an embodiment may exhibit improved device characteristics with high luminous efficiency and a long service life.

The polycyclic compound of an embodiment may be included in the emission layer of the light emitting device, thereby contributing to improving luminous efficiency and service life of the light emitting device.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting device comprising:
a first electrode;
a second electrode facing the first electrode; and
at least one functional layer disposed between the first electrode and the second electrode, wherein
the at least one functional layer comprises:
a first compound represented by Formula 1; and
at least one of a second compound represented by Formula HT and a third compound represented by Formula ET: 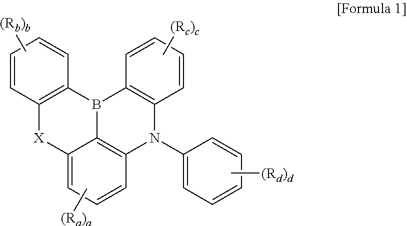
wherein in Formula 1,
X is O, S, or N(Ar),
Ar is a substituted or unsubstituted aryl group having 6 to 60 ring-forming carbon atoms,
a is an integer from 1 to 3,
b and c are each independently an integer from 1 to 4,
d is an integer from 1 to 5,
at least one of Rₐ to R_{d} is each independently a group represented by Formula 2, and
the remainder of Rₐ to R_{d} are each independently a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or are bonded to an adjacent group to form a ring, 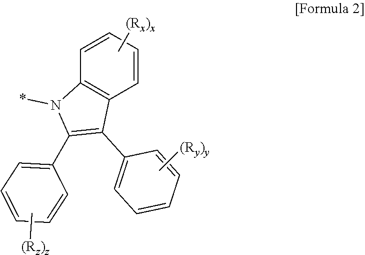
wherein in Formula 2,
Rₓ to R_{z} are each independently a hydrogen atom, a deuterium atom, or a substituted or unsubstituted alkyl group having 1 to 60 carbon atoms,
x is an integer from 0 to 4,
y and z are each independently an integer from 0 to 5, and 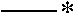 [SMILES: *C]
represents a bond to a neighboring atom in Formula 1, and
at least one hydrogen atom in Formula 1 and Formula 2 is optionally substituted with a deuterium atom, [Formula HT] 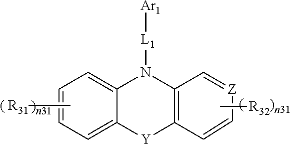
wherein in Formula HT,
L₁ is a direct linkage, a substituted or unsubstituted arylene group having 6 to 30 carbon atoms for forming a ring, or a substituted or unsubstituted heteroarylene group having 2 to 30 carbon atoms for forming a ring,
Ar₁ is a substituted or unsubstituted aryl group having 6 to 30 ring-forming carbon atoms or a substituted or unsubstituted heteroaryl group having 2 to 30 ring-forming carbon atoms,
Y is a direct linkage, C(R_{y1})(R_{y2}), or Si(R_{y3})(R_{y4}),
Z is C(R_{z}) or N,
R_{y1} to R_{y4}, R₃₁, R₃₂, and R_{z} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
n31 is an integer from 0 to 4, and
n32 is an integer from 0 to 3, 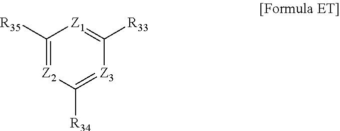
wherein in Formula ET,
Z₁ to Z₃ are each independently N or C(R₃₆),
at least one of Z₁ to Z₃ is each N, and
R₃₃ to R₃₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring.

2. The light emitting device of claim 1, wherein the at least one functional layer further comprises a fourth compound represented by Formula PS: 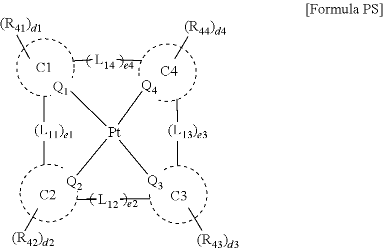
wherein in Formula PS,
Q₁ to Q₄ are each independently C or N,
C1 to C4 are each independently a substituted or unsubstituted hydrocarbon ring having 5 to 30 ring-forming carbon atoms or a substituted or unsubstituted heterocycle having 2 to 30 ring-forming carbon atoms,
L₁₁ to L₁₄ are each independently a direct linkage, 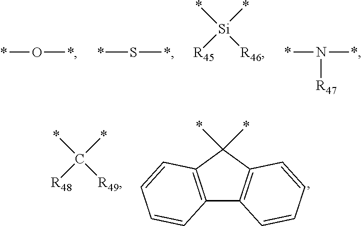
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, wherein in L₁ to L₁₄, 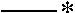 [SMILES: *C]
represents a bond to one of C1 to C4,
e1 to e4 are each independently 0 or 1,
R₄₁ to R₄₉ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
d1 to d4 are each independently an integer from 0 to 4.

3. The light emitting device of claim 1, wherein the first compound is represented by one of Formula 1-1a to Formula 1-1f: 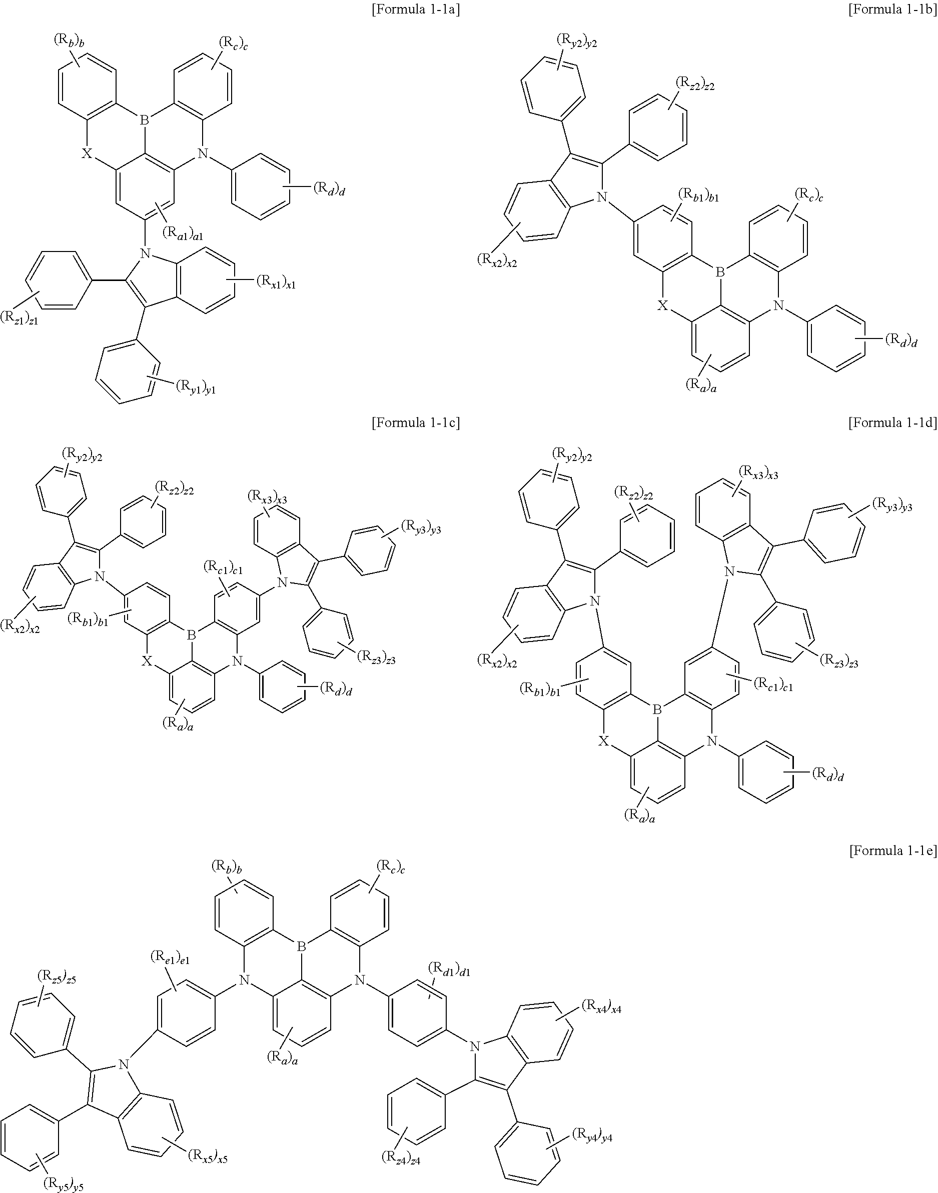 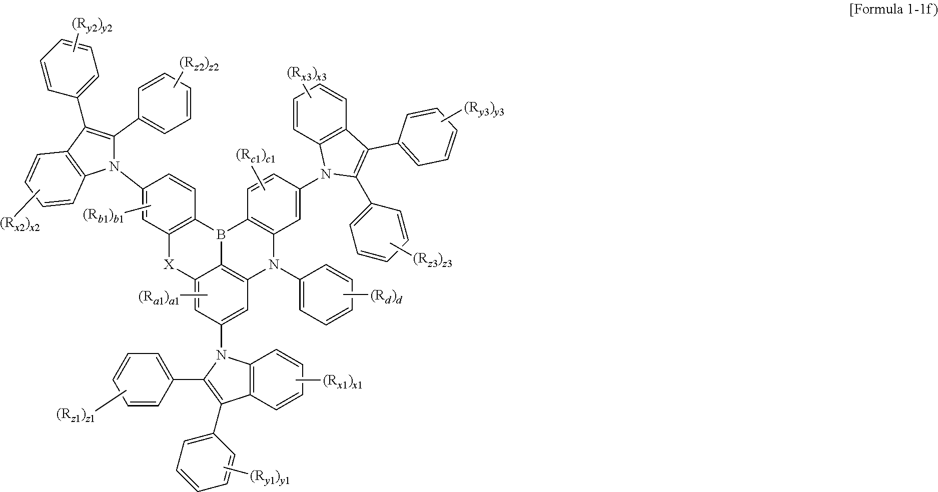
wherein in Formula 1-1a to Formula 1-1f,
Rₐ to Rₐ, Rₐ₁, R_{b1}, R_{c1}, R_{d1}, and Rₑ₁ are each independently a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or are bonded to an adjacent group to form a ring,
a1 is 1 or 2,
b1 and c1 are each independently an integer from 1 to 3,
d1 and e1 are each independently an integer from 1 to 4,
Rₓ₁ to Rₓ₅, R_{y1} to R_{y5}, and R_{z1} to R_{z5} are each independently a hydrogen atom, a deuterium atom, or a substituted or unsubstituted alkyl group having 1 to 60 carbon atoms,
x1 to x5 are each independently an integer from 0 to 4,
y1 to y5 and z1 to z5 are each independently an integer from 0 to 5,
X and a to d are the same as defined in Formula 1, and
at least one hydrogen atom in Formula 1-1a to Formula 1-1f is optionally substituted with a deuterium atom.

4. The light emitting device of claim 1, wherein the first compound is represented by Formula 1a or Formula 1b: 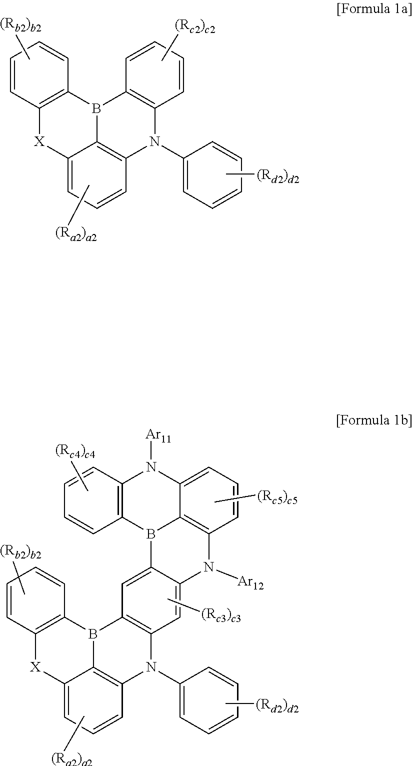
wherein in Formula 1a and Formula 1b,
a2 is an integer from 1 to 3,
b2 and c2 are each independently an integer from 1 to 4,
d2 is an integer from 1 to 5,
R_{c3} to R_{c5} are each independently a hydrogen atom, or a group represented by Formula 2,
c3 is 1 or 2,
c4 is an integer from 1 to 4,
c5 is an integer from 1 to 3,
Ar₁₁ and Ar₁₂ are each independently a substituted or unsubstituted aryl group having 6 to 60 ring-forming carbon atoms,
in Formula 1a, at least one of Rₐ₂, R_{b2}, R_{c2}, and R_{d2} is each independently a group represented by Formula 2, and the remainder of Rₐ₂, R_{b2}, R_{c2}, and R_{d2} are each independently a hydrogen atom, a deuterium atom, a substituted or unsubstituted alkyl group having 1 to 60 carbon atoms, or a substituted or unsubstituted aryl group having 6 to 60 ring-forming carbon atoms,
in Formula 1b, at least one of Rₐ₂, R_{b2}, and R_{d2} is each independently a group represented by Formula 2, and the remainder of Rₐ₂, R_{b2}, and R_{d2} are each independently a hydrogen atom, a deuterium atom, a substituted or unsubstituted alkyl group having 1 to 60 carbon atoms, or a substituted or unsubstituted aryl group having 6 to 60 ring-forming carbon atoms,
X is the same as defined in Formula 1, and
at least one hydrogen atom in Formula 1a, Formula 1b, and Formula 2 is optionally substituted with a deuterium atom.

5. The light emitting device of claim 1, wherein
at least one of Rₐ to R_{d} is each independently a group represented by Formula 2, and
the remainder of Rₐ to R_{d} are each independently a hydrogen atom, a deuterium atom, a substituted or unsubstituted oxy group, a substituted or unsubstituted thio group, a substituted or unsubstituted boron group, a substituted or unsubstituted amine group, an unsubstituted methyl group, an unsubstituted t-butyl group, or an unsubstituted phenyl group, or are bonded to an adjacent group to form a ring.

6. The light emitting device of claim 1, wherein Rₓ to R_{z} are each independently a hydrogen atom, a deuterium atom, an unsubstituted methyl group, or an unsubstituted t-butyl group.

7. The light emitting device of claim 1, wherein the at least one functional layer comprises at least one compound selected from Compound Group 1-1 and Compound Group 1-2: 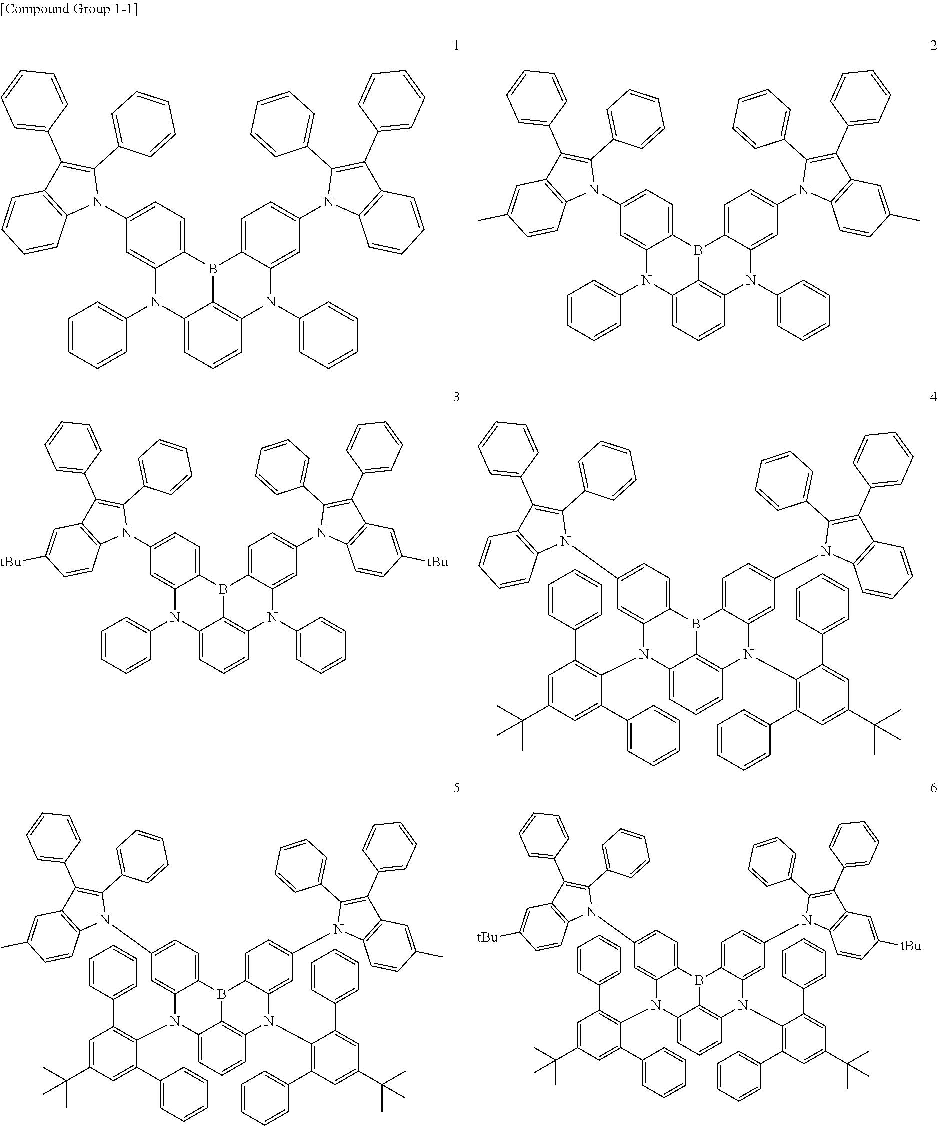 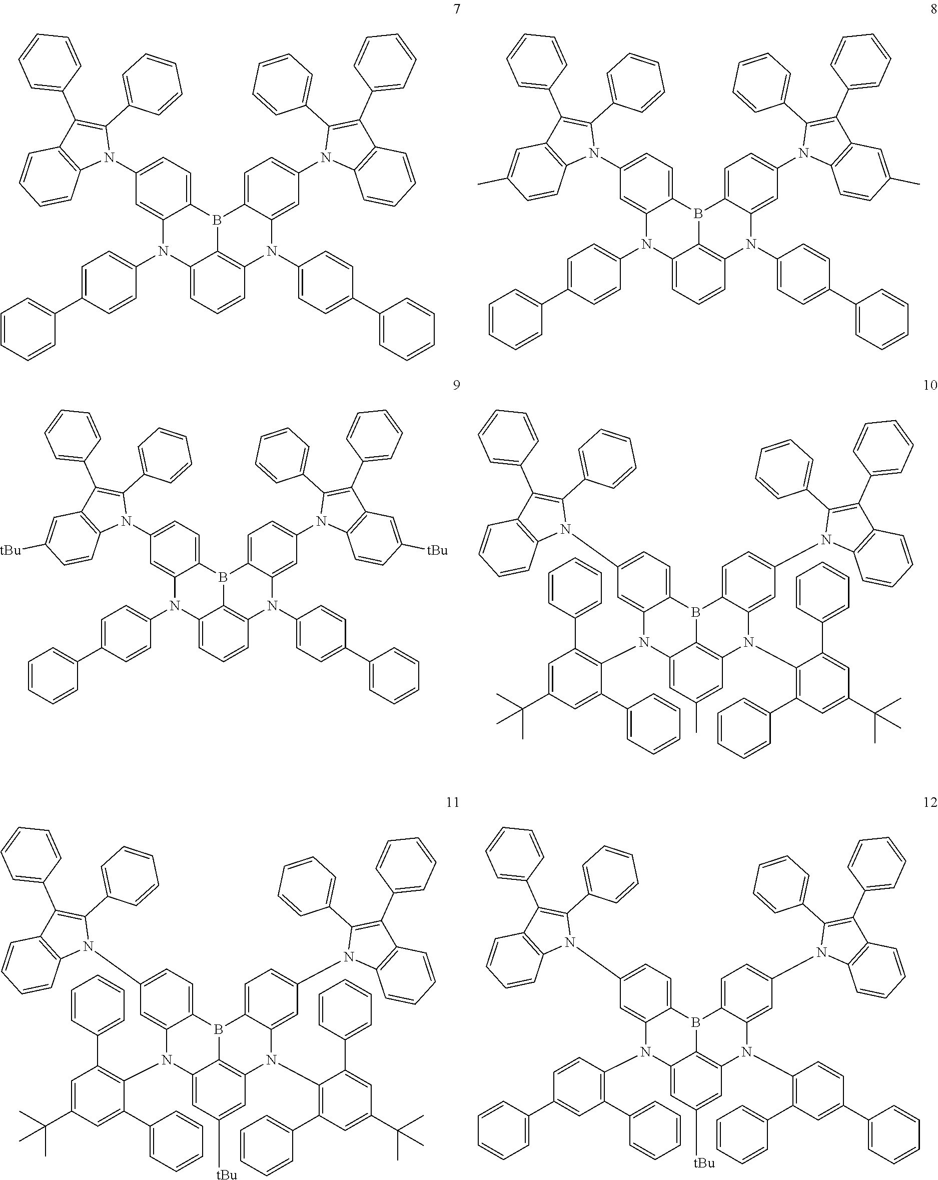 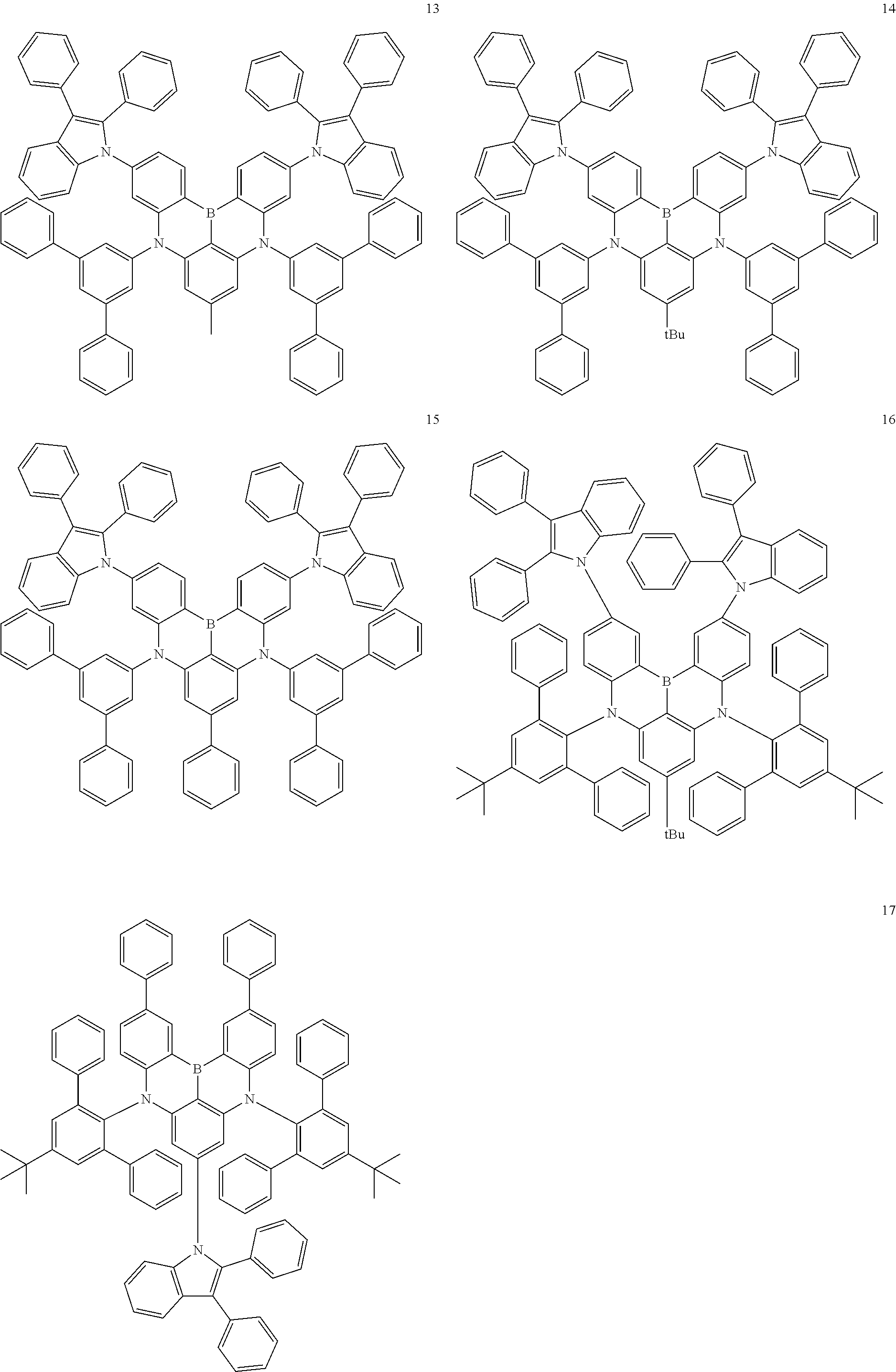 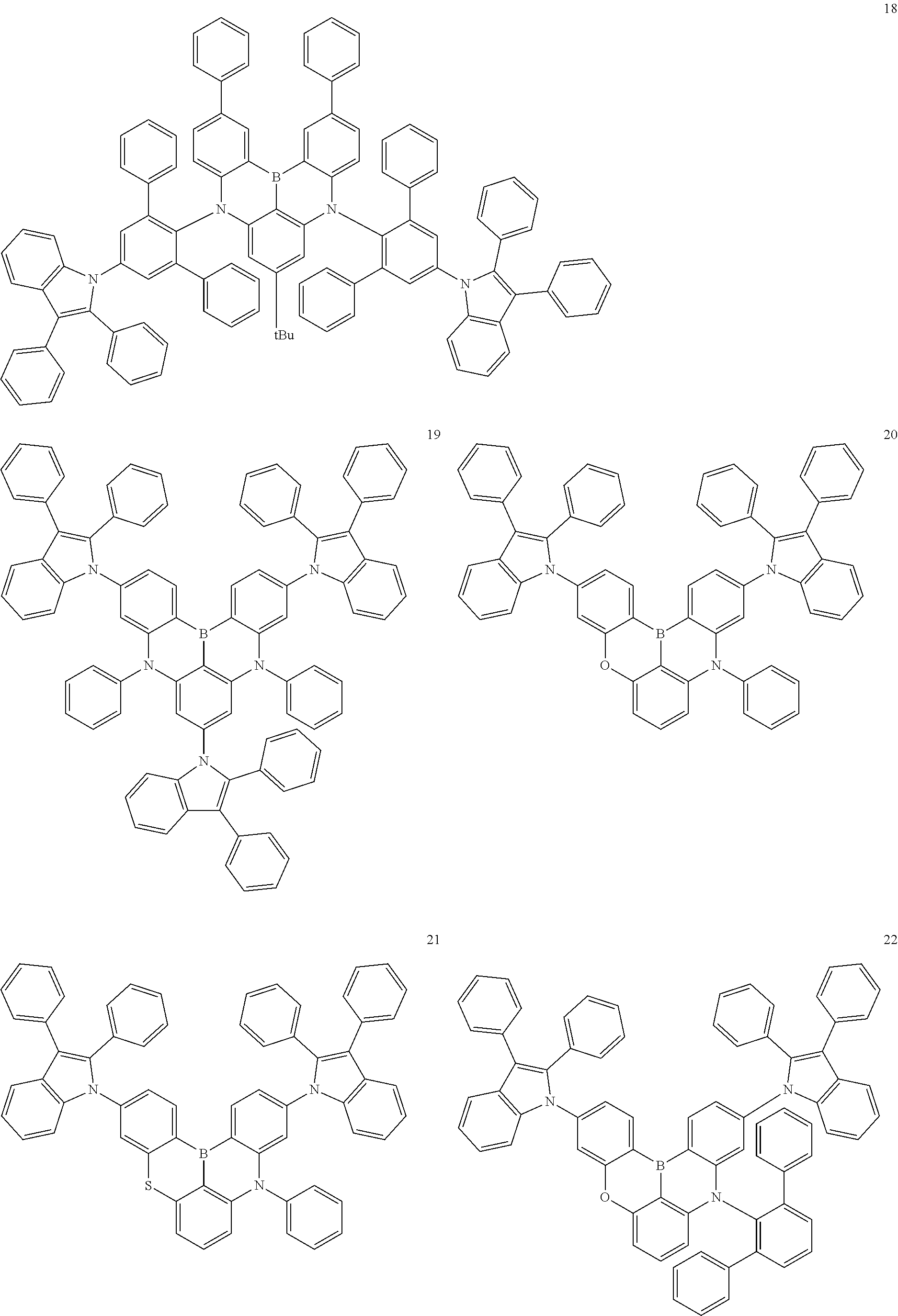 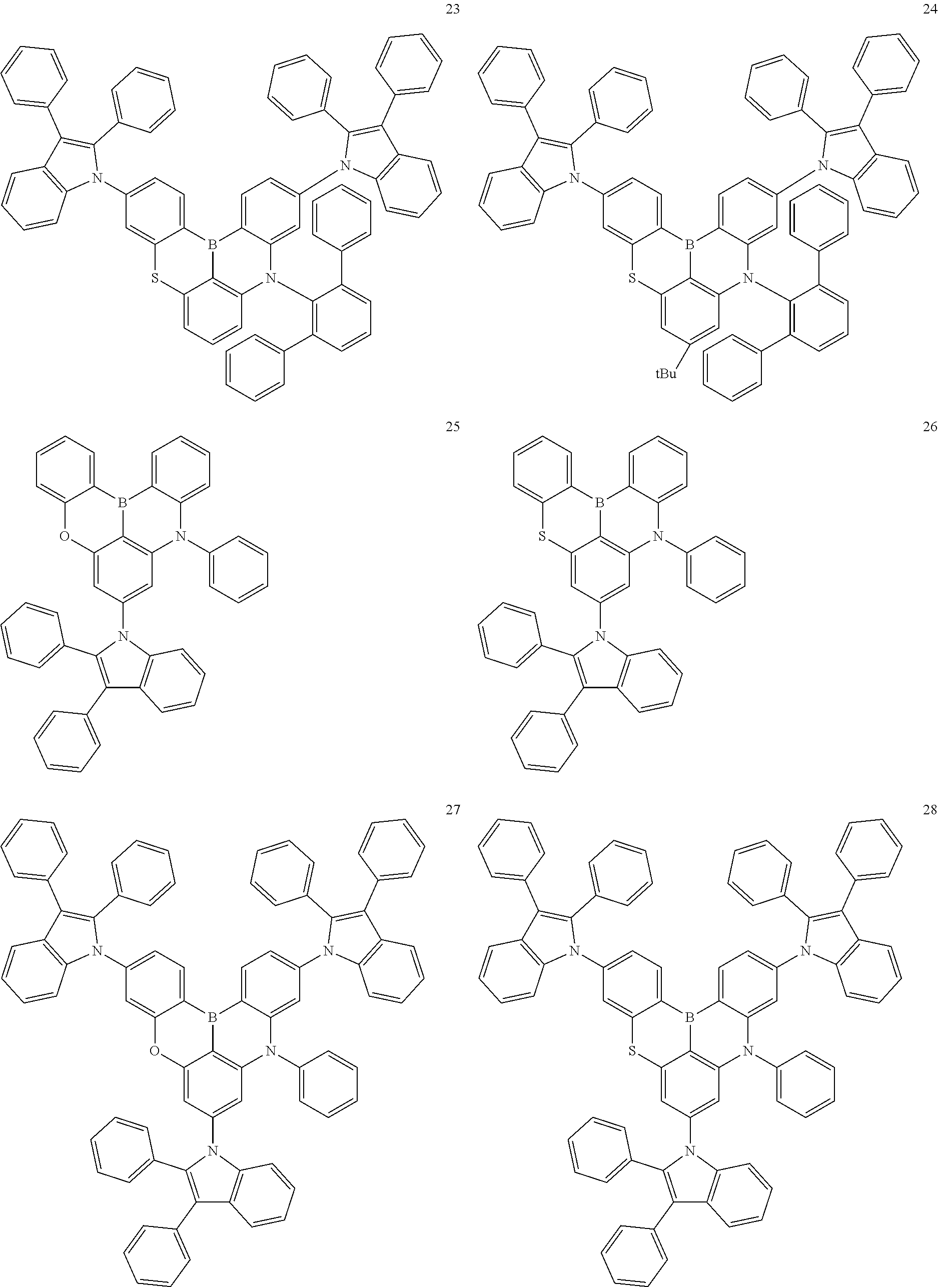 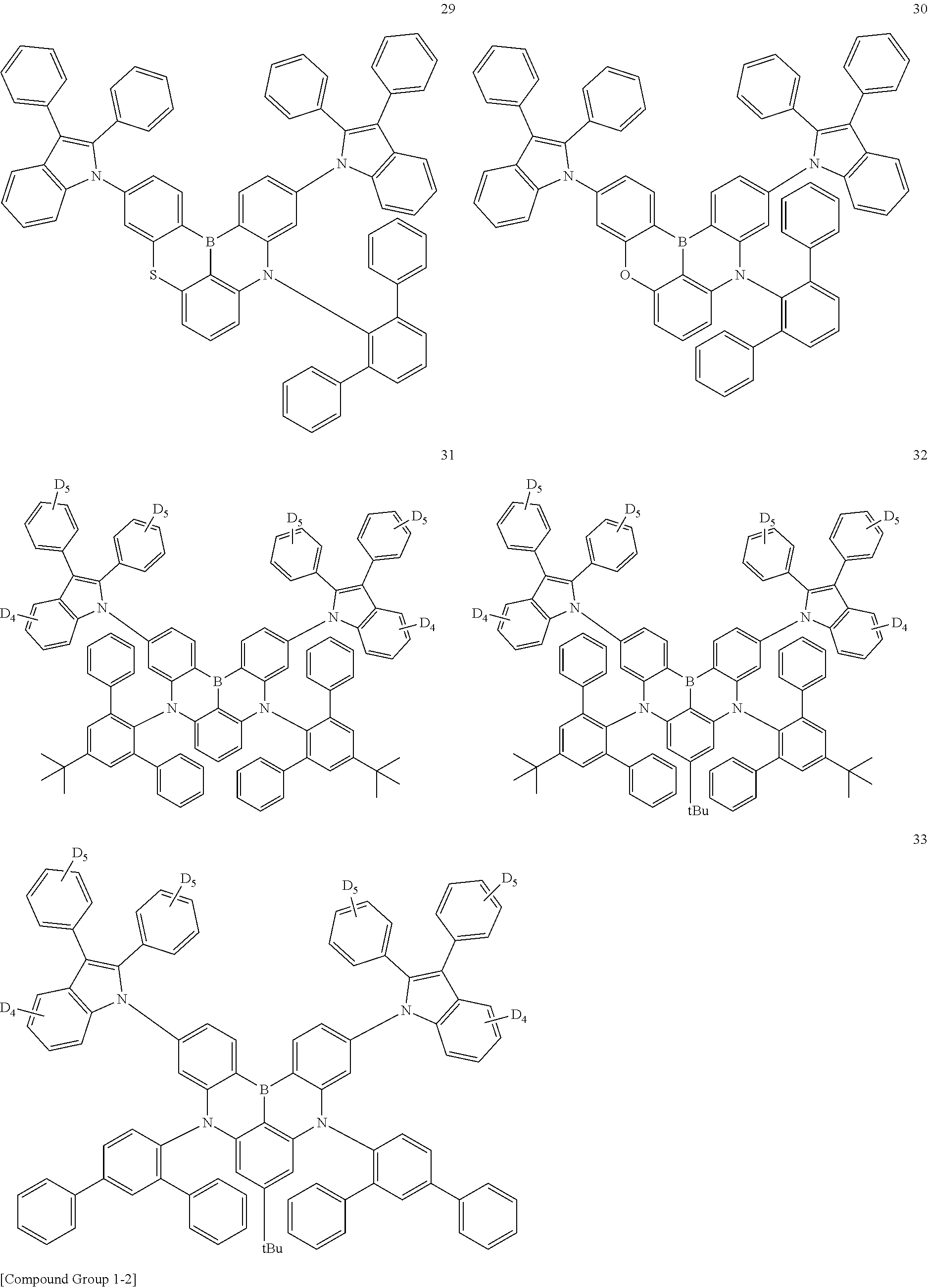 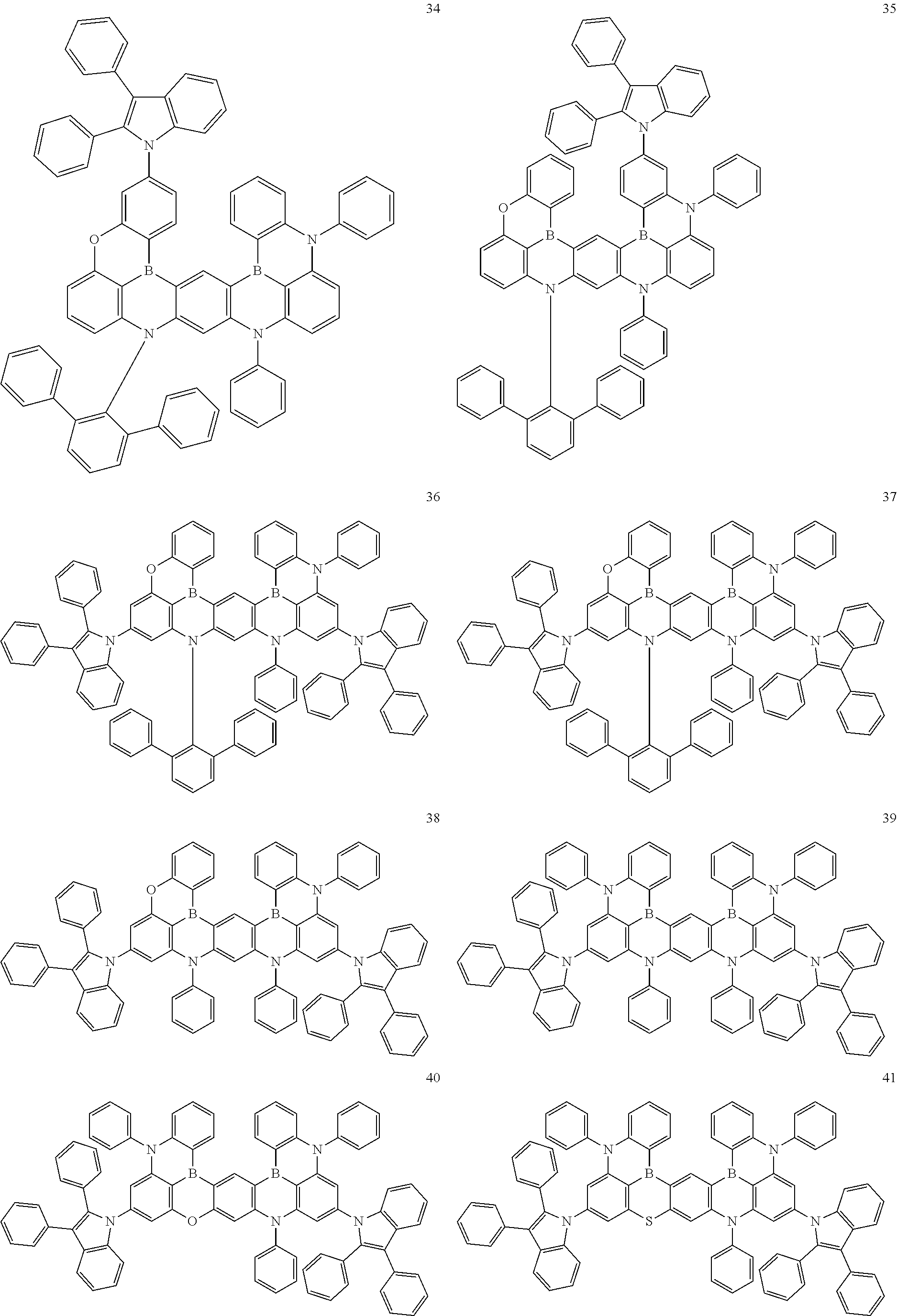 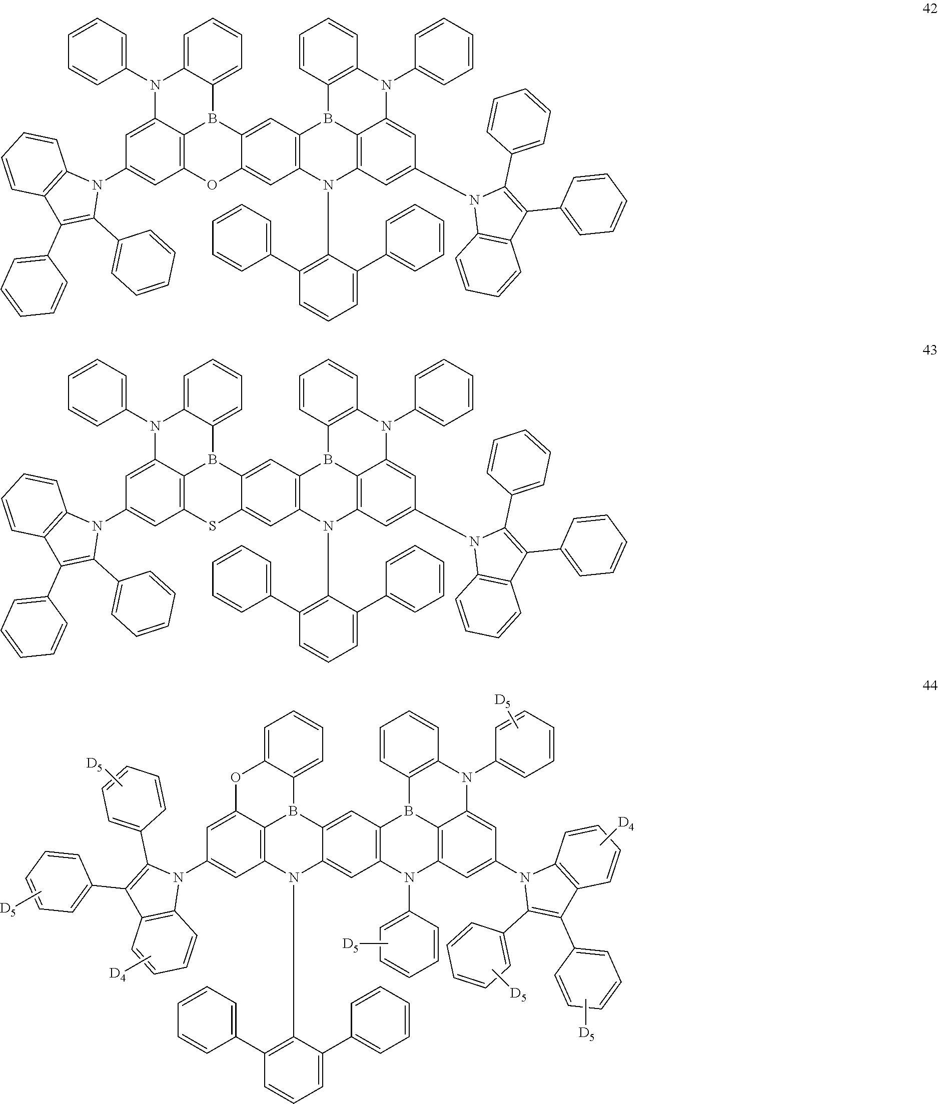 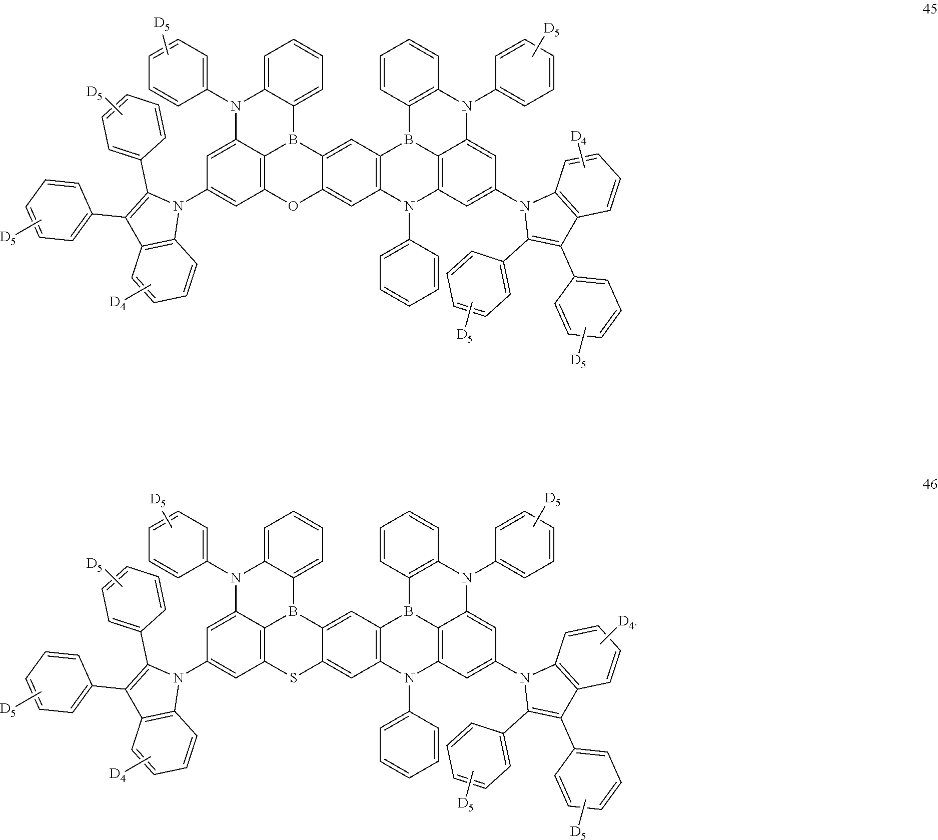
wherein in Compound Group 1-1 and Compound Group 1-2,
D represents a deuterium atom, and
tBu represents a t-butyl group.

8. The light emitting device of claim 1, wherein
the at least one functional layer comprises:
an emission layer;
a hole transport region disposed between the first electrode and the emission layer; and
an electron transport region disposed between the emission layer and the second electrode, and
the emission layer comprises:
the first compound; and
at least one of the second compound and the third compound.

9. The light emitting device of claim 8, wherein the emission layer emits delayed fluorescence.

10. The light emitting device of claim 8, wherein the emission layer emits blue light.

11. The light emitting device of claim 1, wherein the at least one functional layer comprises the first compound, the second compound, and the third compound.

12. The light emitting device of claim 2, wherein the at least one functional layer comprises the first compound, the second compound, the third compound, and the fourth compound.

13. A light emitting device comprising:
a first electrode;
a second electrode facing the first electrode; and
an emission layer disposed between the first electrode and the second electrode, wherein the emission layer comprises a polycyclic compound represented by Formula 1: 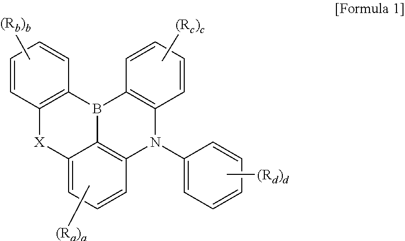
wherein in Formula 1,
X is O, S, or N(Ar),
Ar is a substituted or unsubstituted aryl group having 6 to 60 ring-forming carbon atoms,
a is an integer from 1 to 3,
b and c are each independently an integer from 1 to 4,
d is an integer from 1 to 5,
at least one of Rₐ to R_{d} is each independently a group represented by Formula 3, and
the remainder of Rₐ to R_{d} are each independently a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or are bonded to an adjacent group to form a ring, 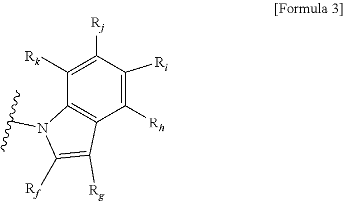
wherein in Formula 3,
two of R_{f} to Rₖ are each independently a substituted or unsubstituted aryl group having 6 to 60 carbon atoms,
the remainder of R_{f} to Rₖ are each independently a hydrogen atom, a deuterium atom, or a substituted or unsubstituted alkyl group having 1 to 60 carbon atoms, and 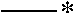 [SMILES: *C]
represents a bond to a neighboring atom in Formula 1, and
at least one hydrogen atom in Formula 1 and Formula 3 is optionally substituted with a deuterium atom.

14. The light emitting device of claim 13, wherein the polycyclic compound is represented by Formula 1-2a or Formula 1-2b: 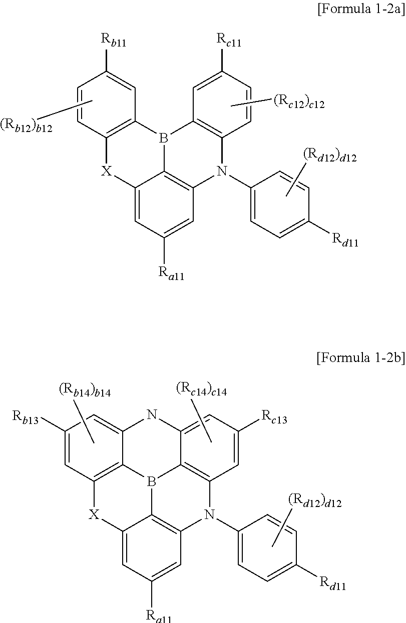
wherein in Formula 1-2a and Formula 1-2b,
R_{b12}, R_{b14}, R_{c12}, R_{c14}, and R_{d12} are each independently a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or are bonded to an adjacent group to form a ring,
b12, b14, c12, and c14 are each independently an integer from 1 to 3,
d12 is an integer from 1 to 4, and
X is the same as defined in Formula 1,
in Formula 1-2a, at least one of Rₐ₁₁, R_{b11}, R_{c11}, and R_{d11} is each independently a group represented by Formula 3, and the remainder of Rₐ₁₁, R_{b11}, R_{c11}, and R_{d11} are each independently a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or are bonded to an adjacent group to form a ring,
in Formula 1-2b, at least one of Rₐ₁₁, R_{b13}, R_{c13}, and R_{d11} is each independently a group represented by Formula 3, and the remainder of Rₐ₁₁, R_{b13}, R_{c13}, and R_{d11} are each independently a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or are bonded to an adjacent group to form a ring, and
in Formula 3, R_{f} and R_{g} are each independently a phenyl group unsubstituted or substituted with a deuterium atom, and Rₕ to Rₖ are each independently a hydrogen atom, a deuterium atom, an unsubstituted methyl group, or an unsubstituted t-butyl group.

15. A polycyclic compound represented by Formula 1: 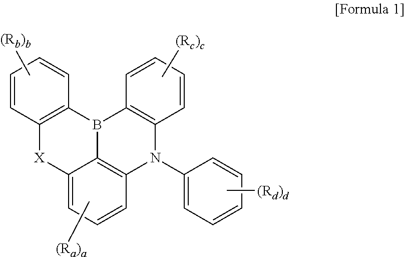
wherein in Formula 1,
X is O, S, or N(Ar),
Ar is a substituted or unsubstituted aryl group having 6 to 60 ring-forming carbon atoms,
a is an integer from 1 to 3,
b and c are each independently an integer from 1 to 4,
d is an integer from 1 to 5,
at least one of Rₐ to R_{d} is each independently a group represented by Formula 2, and
the remainder of Rₐ to R_{d} are each independently a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or are bonded to an adjacent group to form a ring, 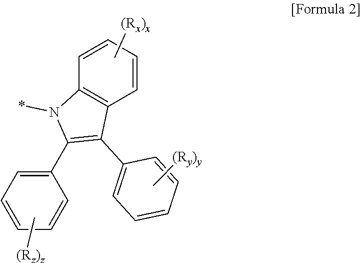
wherein in Formula 2,
Rₓ to R_{z} are each independently a hydrogen atom, a deuterium atom, or a substituted or unsubstituted alkyl group having 1 to 60 carbon atoms,
x is an integer from 0 to 4,
y and z are each independently an integer from 0 to 5, and 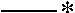 [SMILES: *C]
represents a bond to a neighboring atom in Formula 1, and
at least one hydrogen atom in Formula 1 and Formula 2 is optionally substituted with a deuterium atom.

16. The polycyclic compound of claim 15, wherein the polycyclic compound represented by Formula 1 is represented by one of Formula 1-1a to Formula 1-1f: 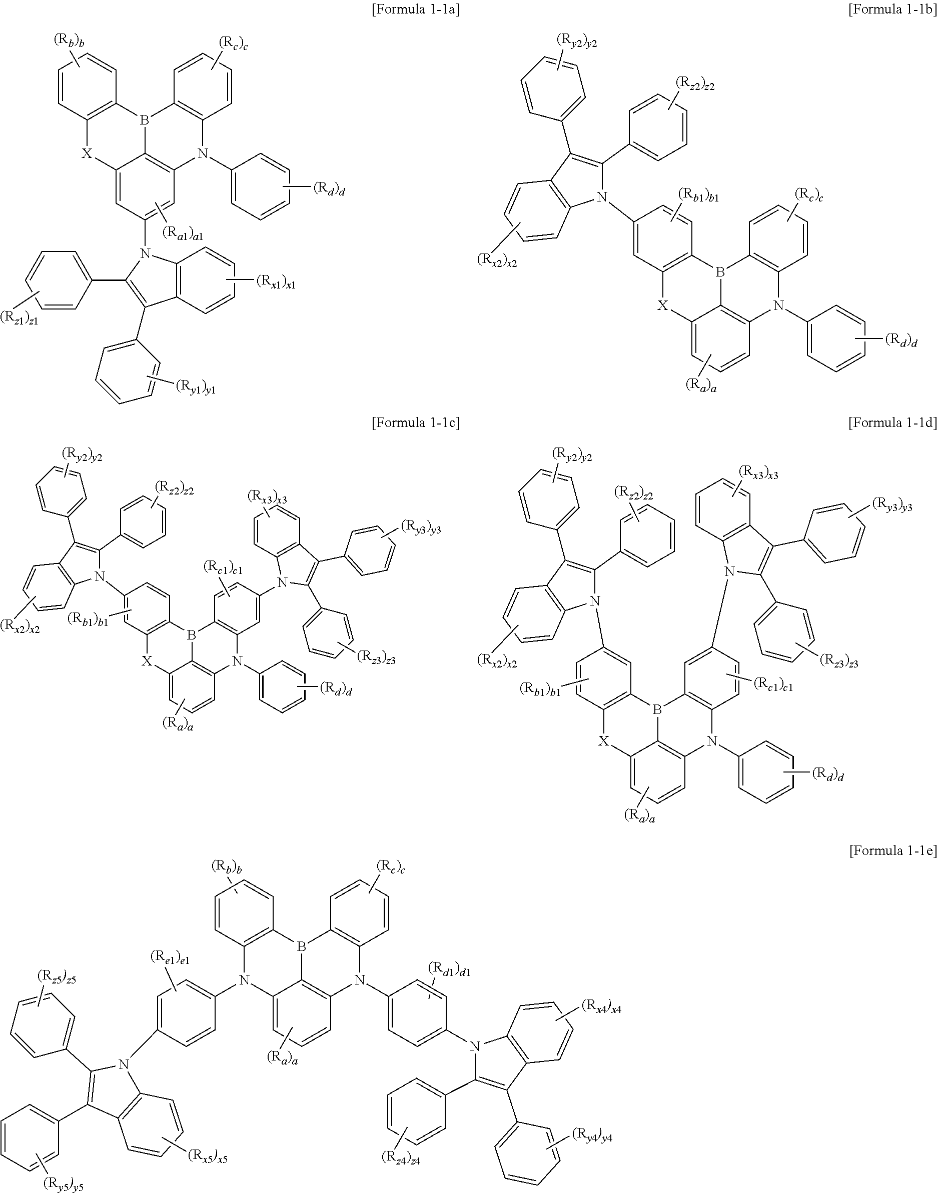 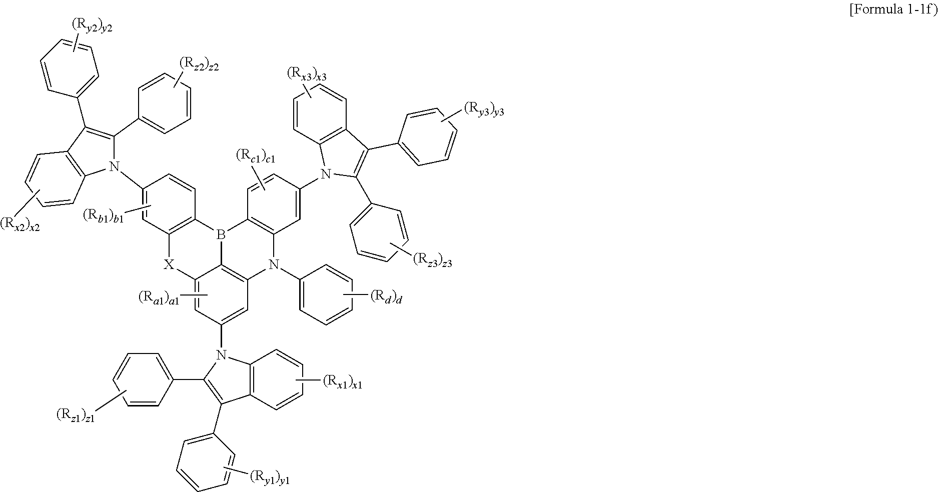
wherein in Formula 1-1a to Formula 1-1f,
Rₐ to R_{d}, Rₐ₁, R_{b1}, R_{c1}, R_{d1}, and Rₑ₁ are each independently a hydrogen atom, a deuterium atom, a substituted or unsubstituted oxy group, a substituted or unsubstituted thio group, a substituted or unsubstituted boron group, a substituted or unsubstituted amine group, a substituted or unsubstituted alkyl group having 1 to 60 carbon atoms, or a substituted or unsubstituted aryl group having 6 to 60 ring-forming carbon atoms, or are bonded to an adjacent group to form a ring,
a1 is 1 or 2,
b1 and c1 are each independently an integer from 1 to 3,
d1 and e1 are each independently an integer from 1 to 4,
Rₓ₁ to Rₓ₅, R_{y1} to R_{y5}, and R_{z1} to R_{z5} are each independently a hydrogen atom, a deuterium atom, or a substituted or unsubstituted alkyl group having 1 to 60 carbon atoms,
x1 to x5 are each independently an integer from 0 to 4,
y1 to y5 and z1 to z5 are each independently an integer from 0 to 5,
X and a to d are the same as defined in Formula 1, and
at least one hydrogen atom in Formula 1-1a to Formula 1-1f is optionally substituted with a deuterium atom.

17. The polycyclic compound of claim 15, wherein the polycyclic compound represented by Formula 1 is represented by Formula 1a or Formula 1b: 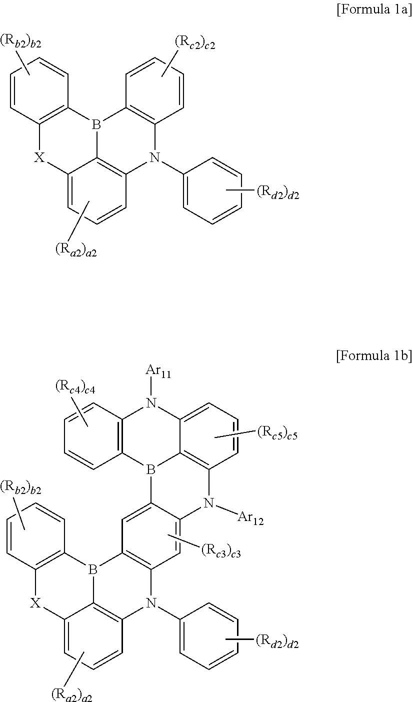
wherein in Formula 1a and Formula 1b,
a2 is an integer from 1 to 3,
b2 and c2 are each independently an integer from 1 to 4,
d2 is an integer from 1 to 5,
R_{c3} to R_{c}s are each independently a hydrogen atom, or a group represented by Formula 2,
c3 is 1 or 2,
c4 is an integer from 1 to 4,
c5 is an integer from 1 to 3,
Ar₁₁ and Ar₁₂ are each independently a substituted or unsubstituted aryl group having 6 to 60 ring-forming carbon atoms,
in Formula 1a, at least one of Rₐ₂, R_{b2}, R_{c2}, and R_{d2} is each independently a group represented by Formula 2, and the remainder of Rₐ₂, R_{b2}, R_{c2}, and R_{d2} are each independently a hydrogen atom, a deuterium atom, a substituted or unsubstituted alkyl group having 1 to 60 carbon atoms, or a substituted or unsubstituted aryl group having 6 to 60 ring-forming carbon atoms,
in Formula 1b, at least one of Rₐ₂, R_{b2}, and R_{d2} is each independently a group represented by Formula 2, and the remainder of Rₐ₂, R_{b2}, and R_{d2} are each independently a hydrogen atom, a deuterium atom, a substituted or unsubstituted alkyl group having 1 to 60 carbon atoms, or a substituted or unsubstituted aryl group having 6 to 60 ring-forming carbon atoms,
X is the same as defined in Formula 1, and
at least one hydrogen atom in Formula 1a, Formula 1b, and Formula 2 is optionally substituted with a deuterium atom.

18. The polycyclic compound of claim 15, wherein
at least one of Rₐ to R_{d} is each independently a group represented by Formula 2, and
the remainder of Rₐ to R_{d} are each independently a hydrogen atom, a deuterium atom, a substituted or unsubstituted oxy group, a substituted or unsubstituted thio group, a substituted or unsubstituted boron group, a substituted or unsubstituted amine group, an unsubstituted methyl group, an unsubstituted t-butyl group, or an unsubstituted phenyl group, or are bonded to an adjacent group to form a ring.

19. The polycyclic compound of claim 15, wherein Rₓ to R_{z} are each independently a hydrogen atom, a deuterium atom, an unsubstituted methyl group, or an unsubstituted t-butyl group.

20. The polycyclic compound of claim 15, wherein the polycyclic compound represented by Formula 1 is selected from Compound Group 1-1 and Compound Group 1-2: 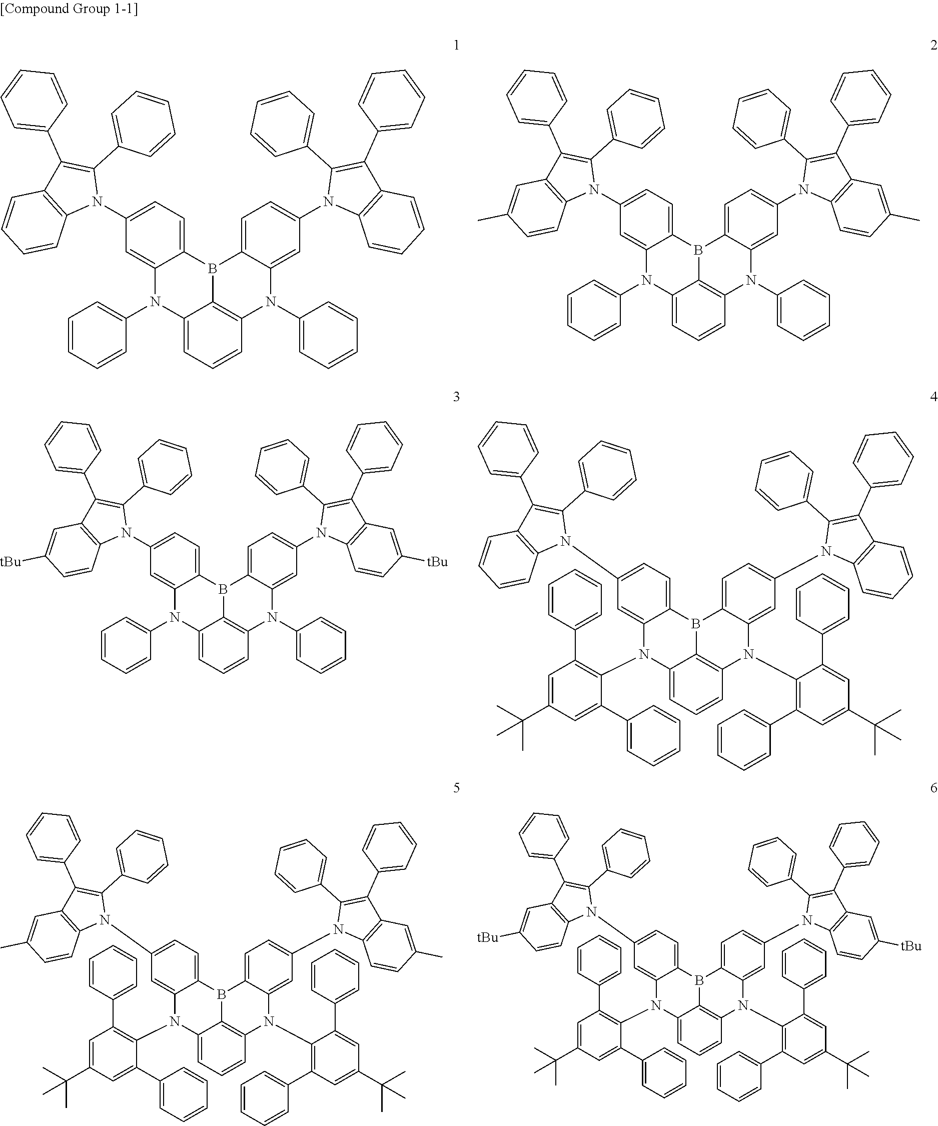 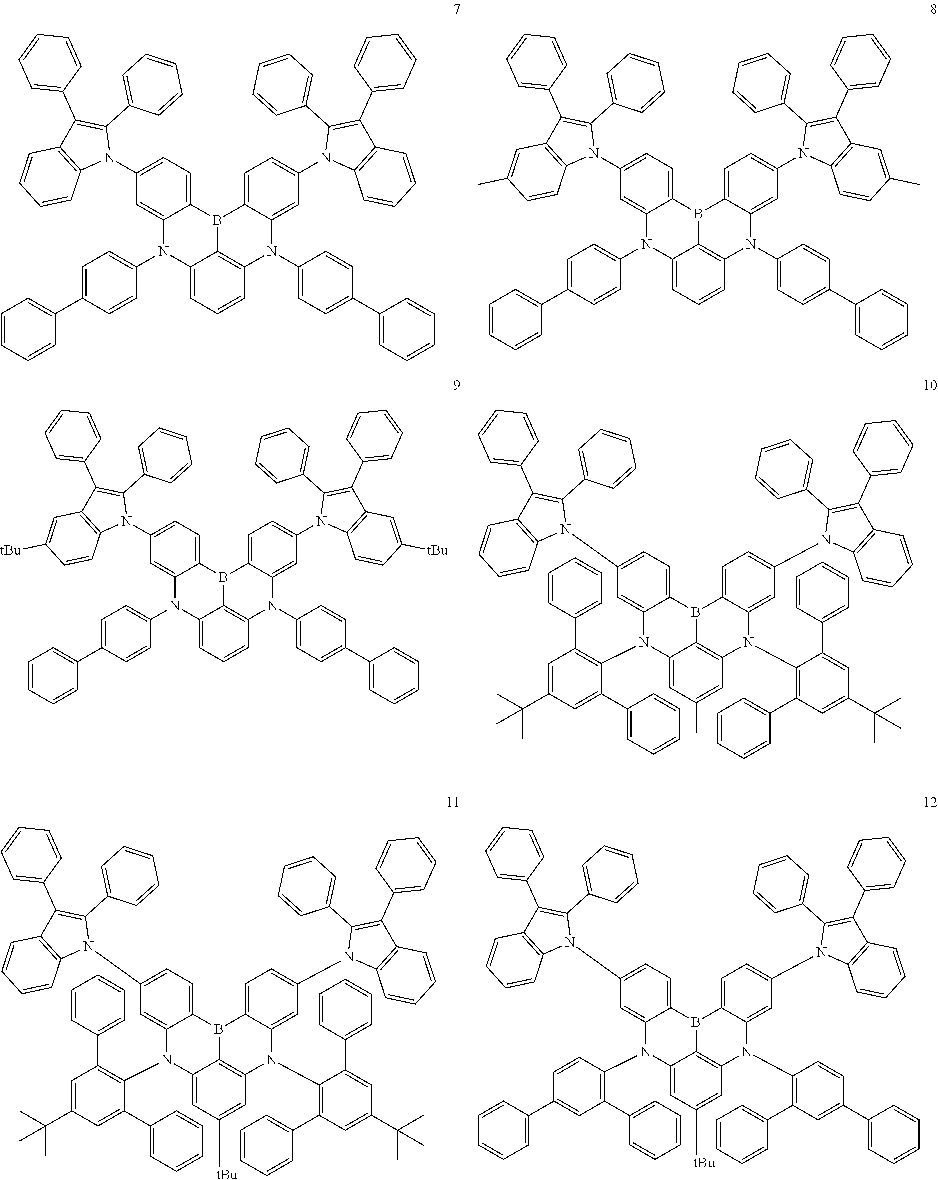 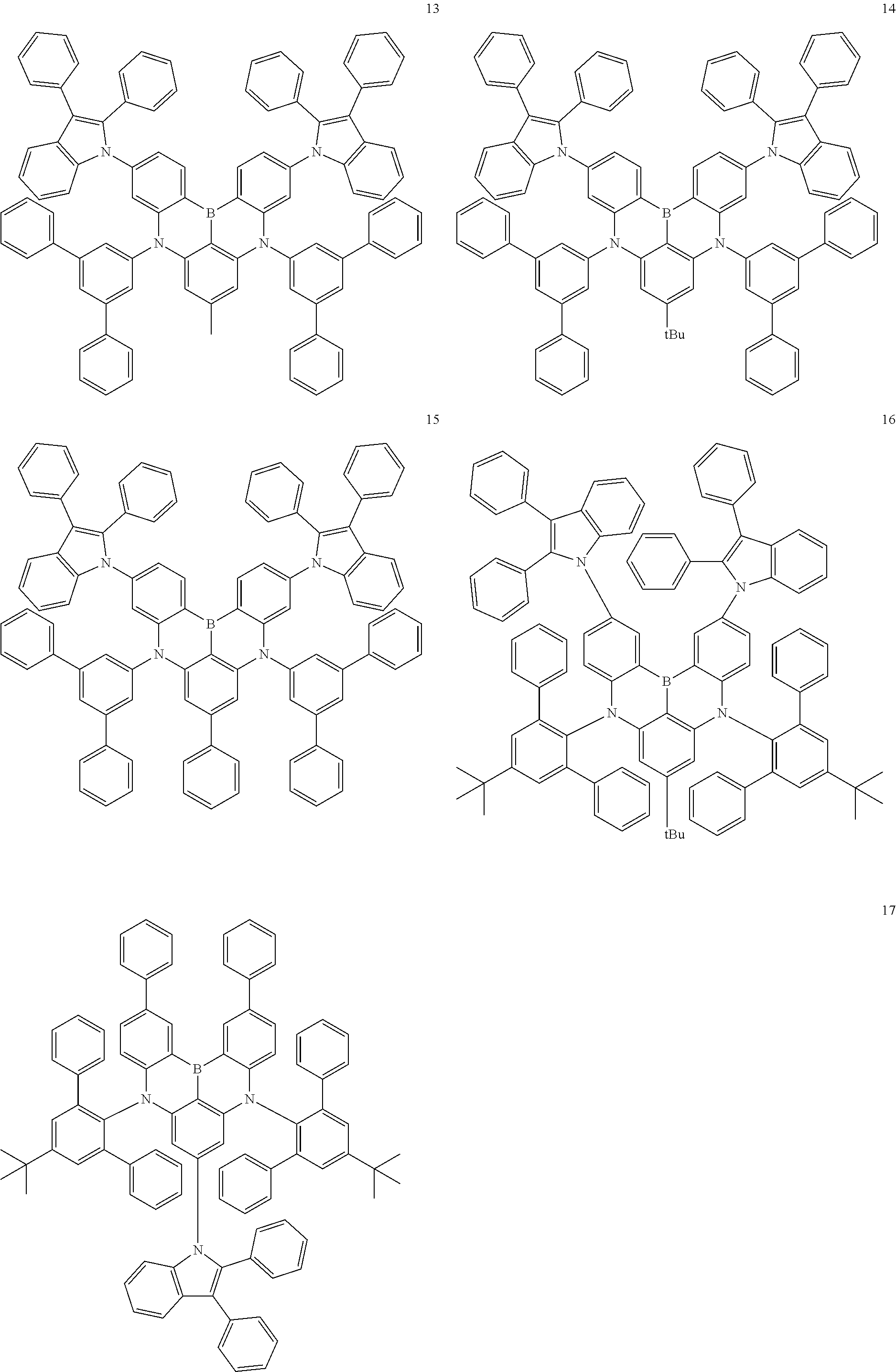 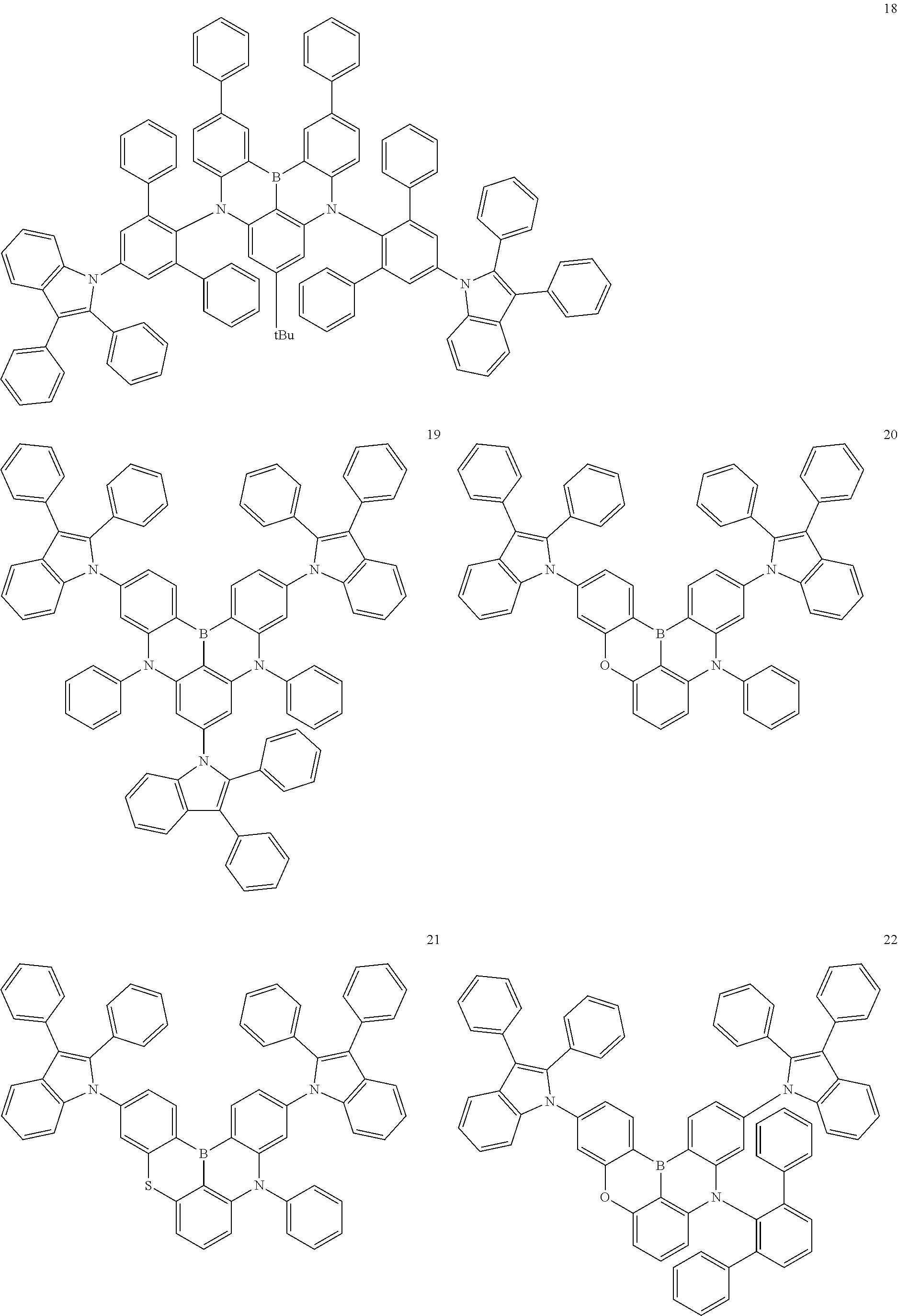 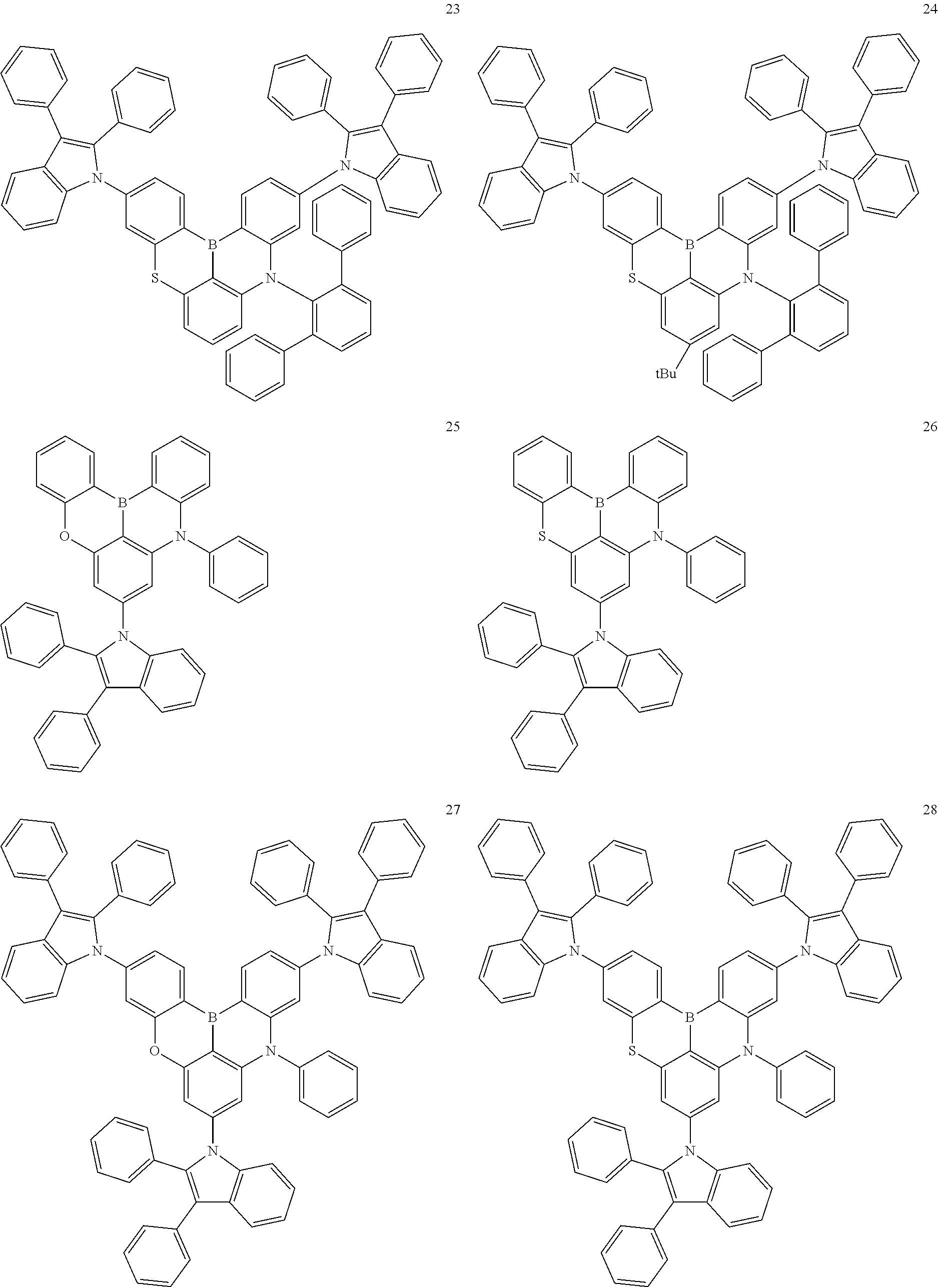 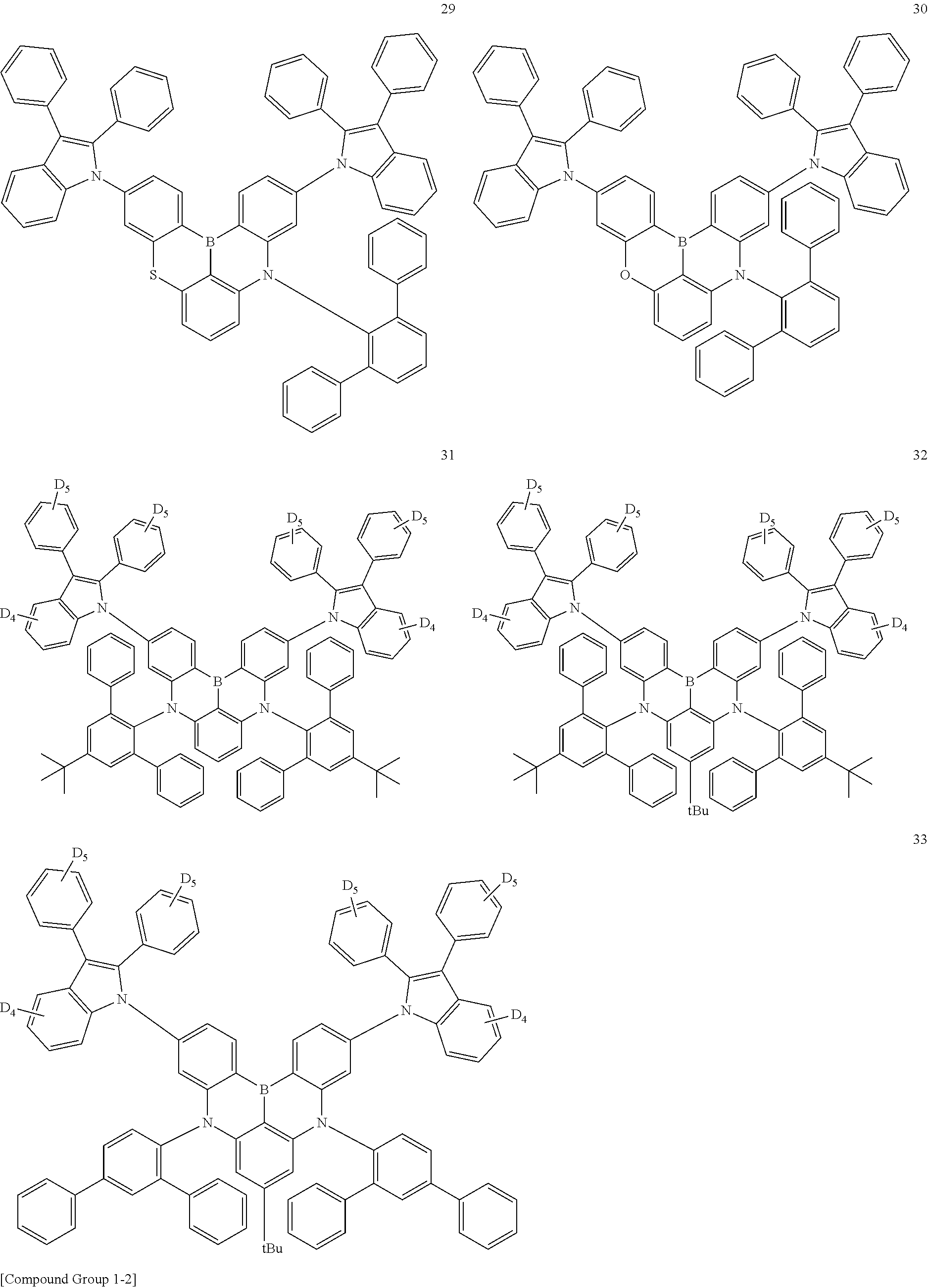 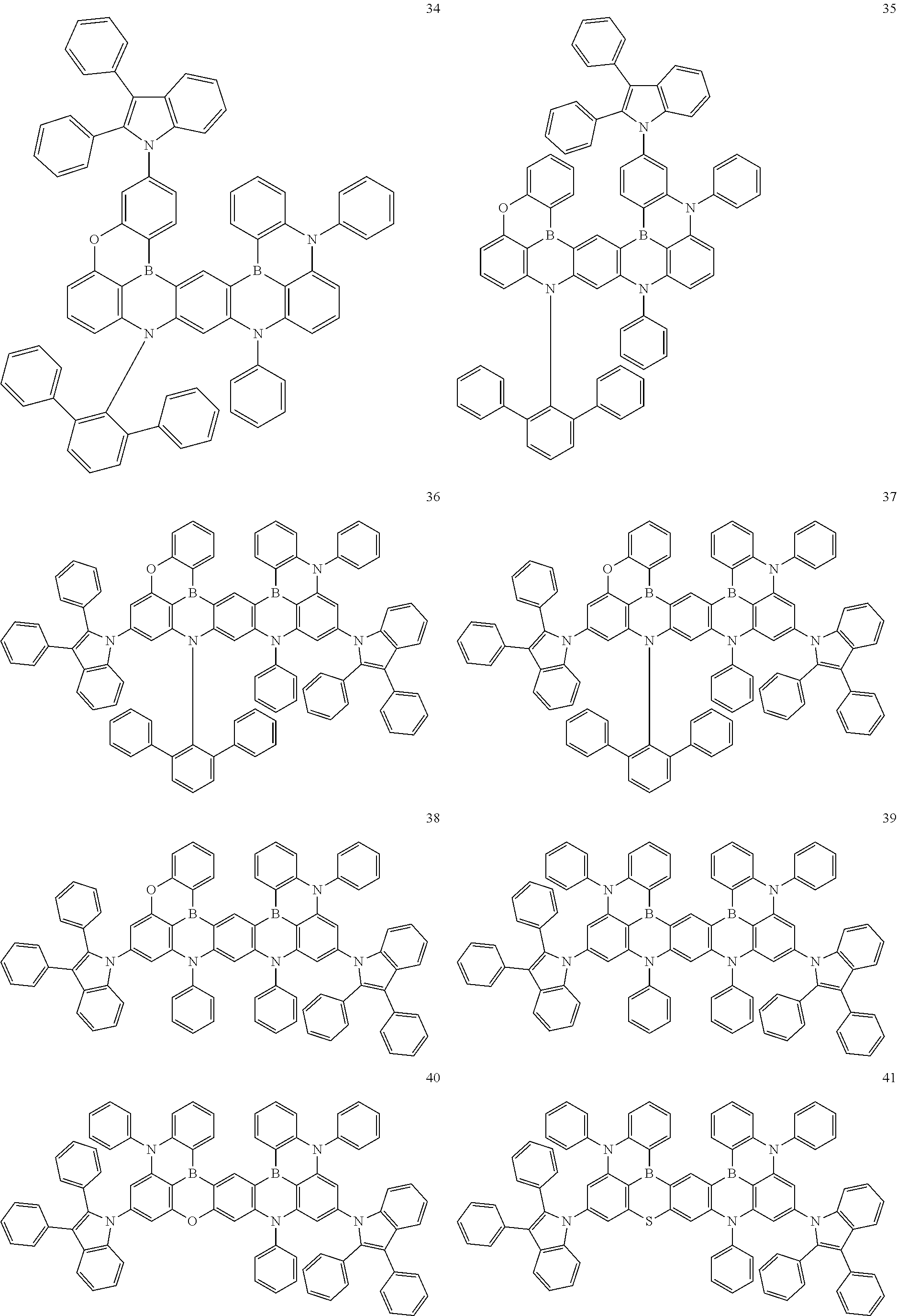 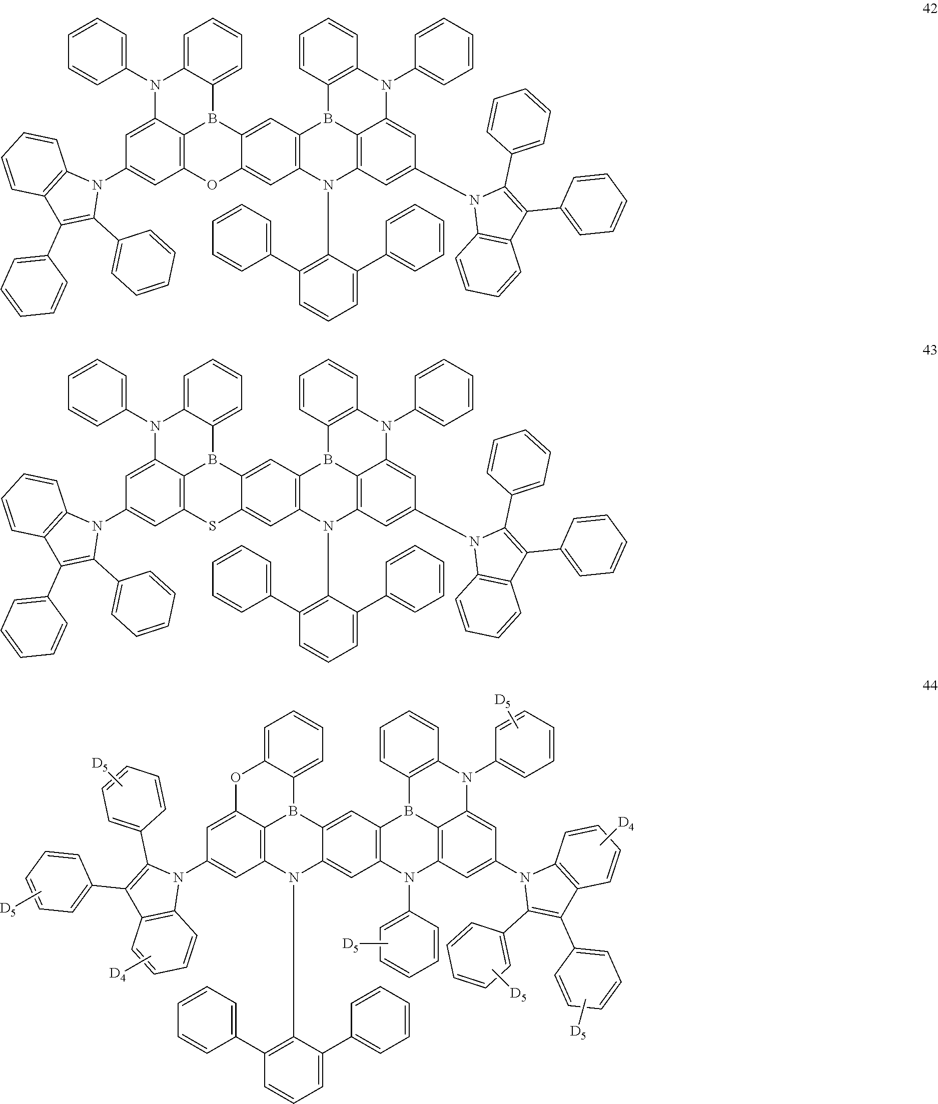 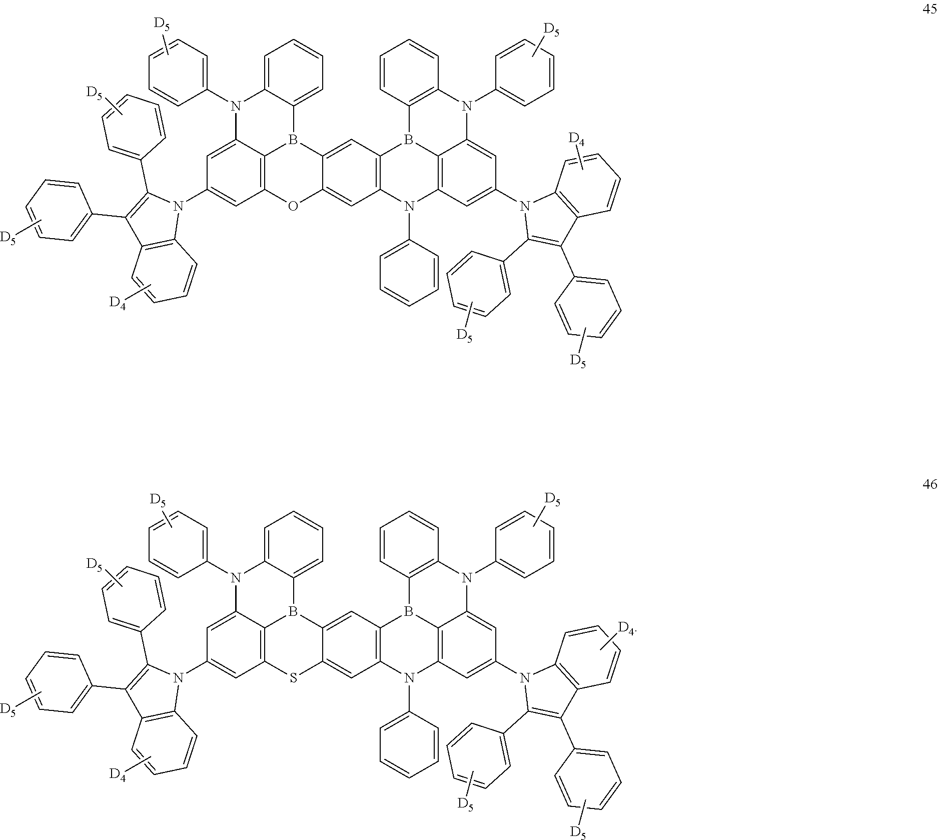
wherein in Compound Group 1-1 and Compound Group 1-2,
D represents a deuterium atom, and
tBu represents a t-butyl group.
